(19) United States
(12) Patent Application Publication
(10) Pub. No.: US 2024/0215286 A1
(43) Pub. Date: Jun. 27, 2024

(54) LIGHT EMITTING DEVICE AND DISPLAY DEVICE INCLUDING THE SAME

(71) Applicant: Samsung Display Co., LTD., Yongin-si (KR)

(72) Inventors: HYOSUP SHIN, Yongin-si (KR); TSUYOSHI NAIJO, Yongin-si (KR); YUNJEE PARK, Yongin-si (KR); SUNG-SOO BAE, Yongin-si (KR); HOJUNG SYN, Yongin-si (KR); JIYOUNG LEE, Yongin-si (KR); CHANGWOONG CHU, Yongin-si (KR)

(21) Appl. No.: 18/518,166

(22) Filed: Nov. 22, 2023

(30) Foreign Application Priority Data
Nov. 24, 2022 (KR) 10-2022-0159257
Nov. 21, 2023 (KR) 10-2023-0162197

(51) Int. Cl. H10K 50/12

(52) U.S. Cl. CPC H10K 50/121; H10K 2101/90

(57) ABSTRACT

A light emitting device of an embodiment includes a first light emitting unit including a first emission layer, and a second light emitting unit including a second emission layer. The first emission layer includes a first host, a phosphorescence sensitizer, a first fluorescence dopant, the second emission layer includes a second host which is different from the first host, and a second fluorescence dopant, the first fluorescence dopant has a highest occupied molecular orbital (HOMO) energy level of about −5.2 eV or less, and the second fluorescence dopant has a HOMO energy level of about −5.2 eV or more.

### CROSS-REFERENCE TO RELATED APPLICATION

This application claims priority to and the benefit of Korean Patent Application Nos. 10-2022-0159257, filed on Nov. 24, 2022, and 10-2023-0162197, filed Nov. 21, 2023, in the Korean Intellectual Property Office, the entire contents of both of which are hereby incorporated by reference.

### BACKGROUND

### 1. Field

Embodiments of the present disclosure herein relate to a light emitting device and a display device including the same, and, for example, to a light emitting device including a plurality of light emitting units, and a display device including the same.

### 2. Description of the Related Art

Various display devices used in multimedia devices such as televisions, mobile phones, tablet computers, navigations and game consoles are being developed. In such display devices, a so-called self-luminescent display device achieving display by illuminating a light emitting material including an organic compound or quantum dots in an emission layer between oppositely provided electrodes, is used.

In the application of a light emitting device to a display device, the improvement of emission efficiency and lifetime, or the like are desired or required, and development of materials and structures for a light emitting device, stably achieving the requirements is being consistently conducted.

### SUMMARY

Embodiments of the present disclosure provide a light emitting device having a low driving voltage and improved emission efficiency, and a display device including the same.

An embodiment of the present disclosure provides a light emitting device including: a first electrode; a first light emitting unit on the first electrode; a second light emitting unit on the first light emitting unit; a second electrode on the second light emitting unit; and a charge generation layer between the first light emitting unit and the second light emitting unit, wherein the first light emitting unit includes: a first hole transport region; a first electron transport region on the first hole transport region; and a first emission layer between the first hole transport region and the first electron transport region, and including a first host, a phosphorescence sensitizer, and a first fluorescence dopant, the second light emitting unit includes: a second hole transport region; a second electron transport region on the second hole transport region; and a second emission layer between the second hole transport region and the second electron transport region, and including a second host which is different from the first host, and a second fluorescence dopant, the first fluorescence dopant has a highest occupied molecular orbital (HOMO) energy level of about −5.2 eV or less, and the second fluorescence dopant has a HOMO energy level of about −5.2 eV or more.

In an embodiment, the first host may include a hole transport host and an electron transport host which is different from the hole transport host, an energy level of a triplet state of the hole transport host is lower than an energy level of a triplet state of the first fluorescence dopant, and an energy level of a singlet state of the electron transport host is lower than an energy level of a singlet state of the first fluorescence dopant.

In an embodiment, the hole transport host may be represented by Formula HT-1.

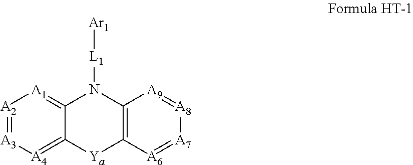

In Formula HT-1, A1 to A4, and A6 to A9 are each independently N or CR₄₁, L₁ is a direct linkage, a substituted or unsubstituted arylene group of 6 to 30 ring-forming carbon atoms, or a substituted or unsubstituted heteroarylene group of 2 to 30 ring-forming carbon atoms, Yₐ is a direct linkage, CR₄₂R₄₃, or SiR₄₄R₄₅, Ar₁ is a substituted or unsubstituted aryl group of 6 to 30 ring-forming carbon atoms, or a substituted or unsubstituted heteroaryl group of 2 to 30 ring-forming carbon atoms, and R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, R₄₁ to R₄₅ may be each independently combined with an adjacent group to form a ring.

In an embodiment, the electron transport host may be represented by Formula ET-1.

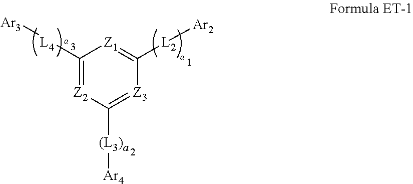

In Formula ET-1, at least one selected from among Z₁ to Z₃ is N, and the remainder are CRₐ₃, where Rₐ₃ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, a₁ to as are each independently an integer of 0 to 10, L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms, and Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the hole transport host and the electron transport host may form an exciplex.

In an embodiment, an energy level of a triplet state of the exciplex may be higher than an energy level of a triplet state of the phosphorescence sensitizer, and an energy level of a triplet state of the phosphorescence sensitizer may be higher than an energy level of a triplet state of the first fluorescence dopant.

In an embodiment, the phosphorescence sensitizer may be represented by Formula D-1.

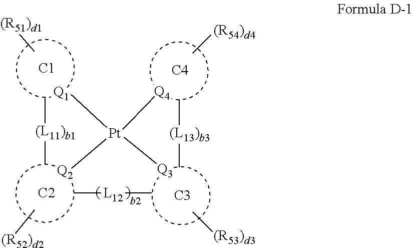

In Formula D-1, Q₁ to Q₄ are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms, L₁₁ to L₁₃ are each independently a direct linkage,

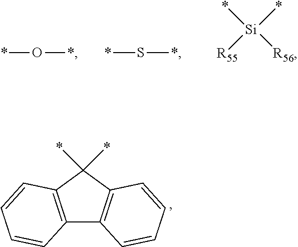

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, in L₁₁ to L₁₃, “—*” is a position connected with C1 to C4, b1 to b3 are each independently 0 or 1, R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring, and d1 to d4 are each independently an integer of 0 to 4.

In an embodiment, the first fluorescence dopant may include boron.

In an embodiment, the second host may be an anthracene-based compound.

In an embodiment, the first emission layer may emit blue light, and the second emission layer may emit blue light.

In an embodiment, the first fluorescence dopant may have a molar extinction coefficient of about 2×10⁵ M*cm⁻¹ or more.

In an embodiment, an energy level (T1_{P}) of a triplet state of the phosphorescence sensitizer and an energy level (T1_{F1}) of a triplet state of the first fluorescence dopant may satisfy Equation 1.

T1_{P}≥T1_{F1}−0.02 eV Equation 1

Another embodiment of the present disclosure provides a display device including a plurality of light emitting devices which emit light in different wavelength regions, wherein at least one selected from among the light emitting devices includes: a first electrode; a first light emitting unit on the first electrode; a second light emitting unit on the first light emitting unit; a second electrode on the second light emitting unit; and a charge generation layer between the first light emitting unit and the second light emitting unit, the first light emitting unit includes: a first hole transport region; a first electron transport region on the first hole transport region; and a first emission layer between the first hole transport region and the first electron transport region, and including a first host, a phosphorescence sensitizer, and a first fluorescence dopant, the second light emitting unit includes: a second hole transport region; a second electron transport region on the second hole transport region; and a second emission layer between the second hole transport region and the second electron transport region, and including a second host which is different from the first host, and a second fluorescence dopant, the first fluorescence dopant has HOMO energy of about −5.2 eV or less, and the second fluorescence dopant has HOMO energy of about −5.2 eV or more.

In an embodiment, the light emitting devices may include: a first light emitting device emitting red light; a second light emitting device emitting green light; and a third light emitting device emitting blue light.

In an embodiment, the first emission layer and the second emission layer may emit blue light, respectively.

In an embodiment, the first host may include a hole transport host and an electron transport host which is different from the hole transport host, a triplet energy of the hole transport host may be lower than a triplet energy of the first fluorescence dopant, and a singlet energy of the electron transport host may be lower than a singlet energy of the first fluorescence dopant.

In an embodiment, the hole transport host may be represented by Formula HT-1.

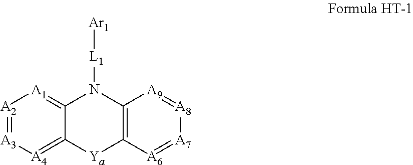

In Formula HT-1, A1 to A4, and A6 to A9 are each independently N or CR₄₁, L₁ is a direct linkage, a substituted or unsubstituted arylene group of 6 to 30 ring-forming carbon atoms, or a substituted or unsubstituted heteroarylene group of 2 to 30 ring-forming carbon atoms, Yₐ is a direct linkage, CR₄₂R₄₃, or SiR₄₄R₄₅, Ar₁ is a substituted or unsubstituted aryl group of 6 to 30 ring-forming carbon atoms, or a substituted or unsubstituted heteroaryl group of 2 to 30 ring-forming carbon atoms, and R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, R₄₁ to R₄₅ may be each independently combined with an adjacent group to form a ring.

In an embodiment, the electron transport host may be represented following Formula ET-1.

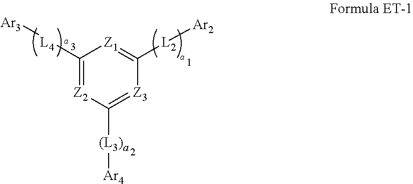

In Formula ET-1, at least one selected from among Z₁ to Z₃ is N, and the remainder are CRₐ₃, where Rₐ₃ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, a₁ to as are each independently an integer of 0 to 10, L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms, and Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the hole transport host and the electron transport host may form an exciplex.

In an embodiment, an energy level of a triplet state of the exciplex may be higher than an energy level of a triplet state of the phosphorescence sensitizer, and an energy level of a triplet state of the phosphorescence sensitizer may be higher than an energy level of a triplet state of the first fluorescence dopant.

In an embodiment, the phosphorescence sensitizer may be represented by Formula D-1.

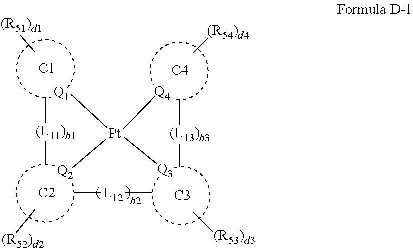

In Formula D-1, Q₁ to 04 are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms, L₁₁ to L₁₃ are each independently a direct linkage,

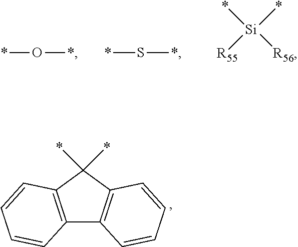

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, in L₁₁ to L₁₃, “—*” is a position connected with C1 to C4, b1 to b3 are each independently 0 or 1, R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring, and d1 to d4 are each independently an integer of 0 to 4.

In an embodiment, the first fluorescence dopant may include boron.

In an embodiment, the second host may be an anthracene-based compound.

### BRIEF DESCRIPTION OF THE DRAWINGS

The accompanying drawings are included to provide a further understanding of embodiments of the present disclosure and are incorporated in and constitute a part of this specification. The drawings illustrate embodiments of the present disclosure and, together with the description, serve to explain principles of embodiments of the present disclosure. In the drawings:

FIG. 1 is a plan view of a display device according to an embodiment;

FIG. 2 is a cross-sectional view of a display device according to an embodiment;

FIG. 3 is a cross-sectional view of a light emitting device according to an embodiment;

FIG. 4 is a cross-sectional view of a light emitting device according to an embodiment;

FIG. 5 is a cross-sectional view of a light emitting device according to an embodiment;

FIG. 6 is a cross-sectional view of a light emitting device according to an embodiment;

FIG. 7 is a cross-sectional view on a display device according to an embodiment;

FIG. 8 is a cross-sectional view on a display device according to an embodiment;

FIG. 9 is a cross-sectional view showing a display device according to an embodiment;

FIG. 10 is a cross-sectional view showing a display device according to an embodiment; and

FIG. 11 is a perspective view schematically showing an electronic device including a display device according to an embodiment.

### DETAILED DESCRIPTION

The subject matter of the present disclosure may have various modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in embodiments of the present disclosure.

In the present description, it will be understood that when an element (or region, layer, part, etc.) is referred to as being “on”, “connected to” or “coupled to” another element, it can be directly on, connected or coupled to the other element or a third intervening elements may be present.

In the present description, “directly on” may mean that there are no additional layers, films, regions, plates, etc., between a layer, a film, a region, a plate, etc. and the other part. For example, “directly on” may mean two layers or two members are provided without using an additional member such as an adhesive member therebetween.

Like reference numerals refer to like elements throughout. In addition, in the drawings, the thickness, the ratio, and the dimensions of constituent elements may be exaggerated for effective explanation of technical contents herein.

The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the spirit or scope of the present disclosure. Similarly, a second element could be termed a first element. As used herein, the singular forms are intended to include the plural forms as well, unless the context clearly indicates otherwise.

In addition, the terms “below”, “beneath”, “on” and “above” are used for explaining the relation of elements shown in the drawings, and these terms are relative concepts and are explained based on the direction shown in the drawing. In the present description, when an element is referred to as being “on” another element, it can be over or under the other element.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the present description, the term “substituted or unsubstituted” corresponds to substituted or unsubstituted with at least one substituent selected from the group consisting of deuterium, a halogen, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the present description, the term “forming a ring via the combination with an adjacent group” or the similar may refer to forming a substituted or unsubstituted hydrocarbon ring, or a substituted or unsubstituted heterocycle via the combination with an adjacent group. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may be monocycles or polycycles. In some embodiments, the ring formed via the combination with an adjacent group may be combined with another ring to form a spiro structure.

In the present description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups thereof may be interpreted as “adjacent groups” to each other, and in 1,1-diethylcyclopentane, two ethyl groups thereof may be interpreted as “adjacent groups” to each other. In some embodiments, in 4,5-dimethylphenanthrene, two methyl groups thereof may be interpreted as “adjacent groups” to each other.

In the present description, a halogen may be fluorine, chlorine, bromine, or iodine.

In the present description, an alkyl group may be a linear or branched type or kind. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl, n-triacontyl, etc., without limitation. In the present description, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the inventive concept is not limited thereto.

In the present description, a cycloalkyl group may refer to a ring-type or kind alkyl group. The carbon number of the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the present description, an alkenyl group may refer to a hydrocarbon group including one or more carbon-carbon double bonds in the middle or at the terminal of an alkyl group having a carbon number of 2 or more. The alkenyl group may be a linear chain or a branched chain. The carbon number of the alkenyl is not specifically limited, for example, may be 2 to 30, 2 to 20, or 2 to 10. Examples of the alkenyl group may include a vinyl group, a 1-butenyl group, a 1-pentenyl group, a 1,3-butadienyl group, a styrenyl group, a styrylvinyl group, etc., without limitation.

In the present description, an alkynyl group may refer to a hydrocarbon group including one or more carbon-carbon triple bonds in the middle or at the terminal of an alkyl group having a carbon number of 2 or more. The alkynyl group may be a linear chain or a branched chain. The carbon number of the alkynyl group is not specifically limited, for example, may be 2 to 30, 2 to 20, or 2 to 10. Examples of the alkynyl group may include an ethynyl group, a propynyl group, etc., without limitation.

In the present description, a hydrocarbon ring group may refer to an optional functional group or substituent derived from an aliphatic hydrocarbon ring. The hydrocarbon ring group may be a saturated hydrocarbon ring group of 5 to 20 ring-forming carbon atoms.

In the present description, an aryl group may refer to an optional functional group or substituent derived from an aromatic hydrocarbon ring. The aryl group may be a monocyclic aryl group or a polycyclic aryl group. The number of carbon atoms forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the present description, a fluorenyl group may be substituted, and two substituents may be combined with each other to form a spiro structure. Examples of a substituted fluorenyl group are as follows, but embodiments of the present disclosure are not limited thereto.

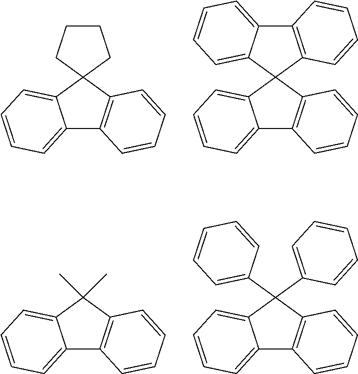

In the present description, a heterocyclic group may refer to an optional functional group or substituent derived from a ring including one or more selected from among B, O, N, P, Si, and S as heteroatoms. The heterocyclic group may include an aliphatic heterocyclic group and/or an aromatic heterocyclic group. The aromatic heterocyclic group may be a heteroaryl group. The aliphatic heterocyclic group and the aromatic heterocyclic group may be a monocycle or a polycycle.

In the present description, a heterocyclic group may include one or more selected from among B, O, N, P, Si and S as heteroatoms. When the heterocyclic group includes two or more heteroatoms, the two or more heteroatoms may be the same or different. The heterocyclic group may be a monocyclic heterocyclic group or a polycyclic heterocyclic group, and has the concept including a heteroaryl group. The number of carbon atoms forming rings of the heterocyclic group may be 2 to 30, 2 to 20, and 2 to 10.

In the present description, an aliphatic heterocyclic group may include one or more selected from among B, O, N, P, Si, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the present description, a heteroaryl group may include one or more selected from among B, O, N, P, Si, and S as heteroatoms. When the heteroaryl group includes two or more heteroatoms, the two or more heteroatoms may be the same or different. The heteroaryl group may be a monocyclic heterocyclic group or polycyclic heterocyclic group. The number of carbon atoms forming rings of the heteroaryl group may be 2 to 30, 2 to 20, or 2 to 10. Examples of the heteroaryl group may include thiophene group, furan group, pyrrole group, imidazole group, pyridine group, bipyridine group, pyrimidine group, triazine group, triazole group, acridyl group, pyridazine group, pyrazinyl group, quinoline group, quinazoline group, quinoxaline group, phenoxazine group, phthalazine group, pyrido pyridine group, pyrido pyrazine group, pyrazino pyrazine group, isoquinoline group, indole group, carbazole group, N-arylcarbazole group, N-heteroarylcarbazole group, N-alkylcarbazole group, benzoxazole group, benzimidazole group, benzothiazole group, benzocarbazole group, benzothiophene group, dibenzothiophene group, thienothiophene group, benzofuran group, phenanthroline group, thiazole group, isooxazole group, oxazole group, oxadiazole group, thiadiazole group, phenothiazine group, dibenzosilole group, dibenzofuran group, etc., without limitation.

In the present description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the present description, a silyl group may include an alkyl silyl group and/or an aryl silyl group. The alkyl group in the alkylsilyl group may be a linear chain, a branched chain, or a ring chain. The number of carbon atoms in the alkylsilyl group is not specifically limited, but may be, for example, 1 to 20 or 1 to 10. The number of carbon atoms in the arylsilyl group is not specifically limited, but may be, for example, 6 to 30, 6 to 20, or 6 to 15. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the present description, the carbon number of a carbonyl group is not specifically limited, for example, the carbon number thereof may be 1 to 40, 1 to 30, or 1 to 20. For example, the carbonyl group may have the following structures, but embodiments of the present disclosure are not limited thereto.

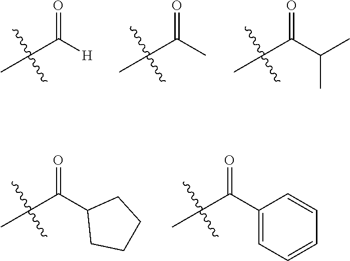

In the present description, the carbon number of a sulfinyl group or a sulfonyl group is not specifically limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present description, a thio group may include an alkyl thio group and/or an aryl thio group. The thio group may refer to the above-defined alkyl group or aryl group combined with a sulfur atom. The alkyl group in the alkylthio group may be a linear chain, a branched chain, or a ring chain. The number of carbon atoms in the alkylthio group is not specifically limited, but may be, for example, 1 to 20 or 1 to 10. The number of carbon atoms in the arylthio group is not specifically limited, but may be, for example, 6 to 30, 6 to 20, or 6 to 15. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the present description, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the inventive concept is not limited thereto.

In the present description, a boron group may refer to the above-defined alkyl group or aryl group, combined with a boron atom. The boron group may include an alkyl boron group and/or an aryl boron group. The alkyl group in the alkyl boron group may be a linear chain, a branched chain, or a ring chain. The number of carbon atoms in the alkyl boron group is not specifically limited, but may be, for example, 1 to 20 or 1 to 10. The number of carbon atoms in the aryl boron group is not specifically limited, but may be, for example, 6 to 30, 6 to 20, or 6 to 15. Examples of the boron group may include a dimethylboron group, a diethylboron group, a t-butylmethylboron group, a diphenylboron group, a phenylboron group, etc., without limitation.

In the present description, the carbon number of an amine group is not specifically limited, for example, may be 1 to 30. The amine group may include an alkyl amine group and/or an aryl amine group. The alkyl group in the alkyl amine group may be a linear chain, a branched chain, or a ring chain. The number of carbon atoms in the alkyl amine group is not specifically limited, but may be, for example, 1 to 20 or 1 to 10. The number of carbon atoms in the aryl amine group is not specifically limited, but may be, for example, 6 to 30, 6 to 20, or 6 to 15. Examples of the amine group may include a methylamine group, a dimethylamine group, a phenylamine group, a diphenylamine group, a naphthylamine group, a 9-methyl-anthracenylamine group, etc., without limitation.

In the present description, alkyl groups in an alkoxy group, alkylthio group, alkylsulfoxy group, alkylsulfinyl group, alkylaryl group, alkylamino group, alkyl boron group, alkyl silyl group, alkyl phosphine oxide group, alkyl phosphine sulfide group, and alkyl amine group may be the same as the examples of the above-described alkyl group.

In the present description, aryl groups in an aryloxy group, arylthio group, arylsulfoxy group, arylsulfonyl group, arylamino group, aryl boron group, aryl silyl group, aryl phosphine oxide group, aryl phosphine sulfide group, and aryl amine group may be the same as the examples of the above-described aryl group.

In the present description, a direct linkage may refer to a single bond.

Meanwhile, In the present description,

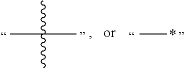

may refer to a position to be connected.

Hereinafter, a light emitting device according to an embodiment of the present disclosure and a display device including the same will be explained referring to the drawings.

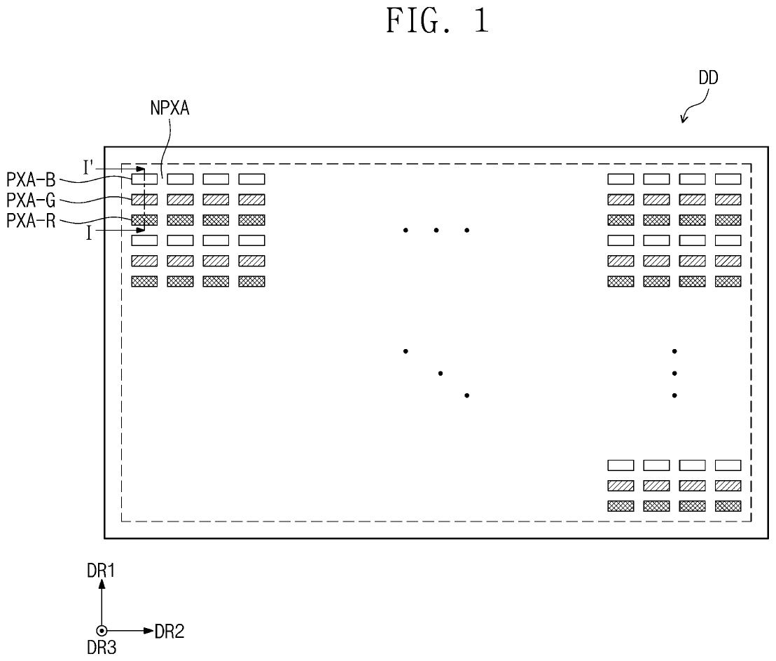

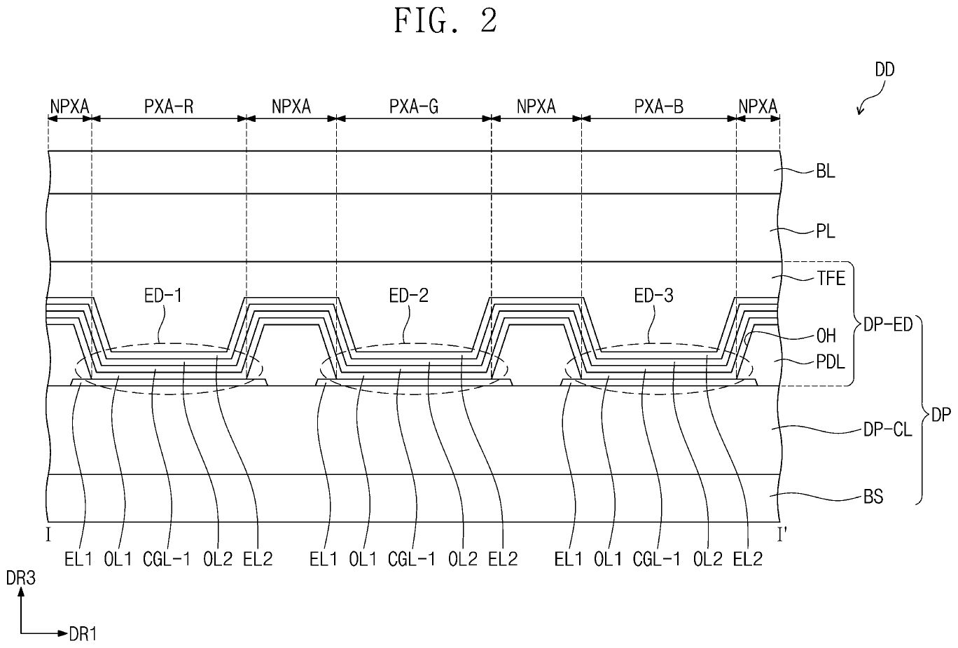

FIG. 1 is a plan view showing an embodiment of a display device DD. FIG. 2 is a cross-sectional view of a display device DD of an embodiment. FIG. 2 is a cross-sectional view showing a part corresponding to line I-I′ in FIG. 1.

The display device DD may include a display panel DP and an optical layer PL on the display panel DP. The display panel DP includes light emitting devices ED-1, ED-2 and ED-3. The display device DD may include a plurality of light emitting devices ED-1, ED-2 and ED-3. The optical layer PL may be on the display panel DP and control reflected light by external light at the display panel DP. The optical layer PL may include, for example, a polarization layer and/or a color filter layer. Different from the drawings, the optical layer PL may be omitted in the display device DD of an embodiment.

On the optical layer PL, a base substrate BL may be provided. The base substrate BL may be a member providing a base surface where the optical layer PL is provided. The base substrate BL may be a glass substrate, a metal substrate, a plastic substrate, etc. However, an embodiment of the present disclosure is not limited thereto, and the base substrate BL may be an inorganic layer, an organic layer, or a composite material layer. In addition, different from the drawings, the base substrate BL may be omitted in an embodiment.

The display device DD according to an embodiment may further include a plugging layer. The plugging layer may be between a display device layer DP-ED and the base substrate BL. The plugging layer may be an organic material layer. The plugging layer may include at least one selected from among an acrylic resin, a silicon-based resin, and an epoxy-based resin.

The display panel DP may include a base layer BS, a circuit layer DP-CL on the base layer BS, and a display device layer DP-ED. The display device layer DP-ED may include a pixel definition layer PDL, light emitting devices ED-1, ED-2 and ED-3 in the pixel definition layer PDL, and an encapsulation layer TFE on the light emitting devices ED-1, ED-2 and ED-3.

The base layer BS may be a member providing a base surface where the display device layer DP-ED is provided. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include switching transistors and driving transistors for driving the light emitting devices ED-1, ED-2 and ED-3 of the display device layer DP-ED.

Each of the light emitting devices ED-1, ED-2 and ED-3 may have the structure of the light emitting device ED according to an embodiment, which will be further explained herein below. Each of the light emitting devices ED-1, ED-2 and ED-3 may include a first electrode EL1, a first light emitting unit OL1, a charge generation layer CGL-1, a second light emitting unit OL₂, and a second electrode EL2. In some embodiments, each of the light emitting devices ED-1, ED-2 and ED-3 may have a tandem structure. FIG. 2 shows an embodiment in which the first light emitting unit OL1, the charge generation layer CGL-1, and the second light emitting unit OL2 are provided as common layers, and all light emitting devices ED-1, ED-2 and ED-3 have the tandem structure. However, an embodiment of the present disclosure is not limited thereto. Different from FIG. 2, only at least one light emitting device may have the tandem structure including the first light emitting unit OL1, the charge generation layer CGL-1, and the second light emitting unit OL₂, and the remainder may include one emission layer. In some embodiments, only the third light emitting device ED-3 may emit blue light may have a tandem structure, and the remainder may have a structure including one emission layer.

An encapsulation layer TFE may cover the light emitting devices ED-1, ED-2 and ED-3. The encapsulation layer TFE may encapsulate the light emitting devices ED-1, ED-2 and ED-3 of the display device layer DP-ED. The encapsulation layer TFE may be a thin film encapsulation layer. The encapsulation layer TFE may be one layer or a stacked layer of a plurality of layers. The encapsulation layer TFE includes at least one insulating layer. The encapsulation layer TFE according to an embodiment may include at least one inorganic layer (hereinafter, inorganic encapsulation layer). In addition, the encapsulation layer TFE according to an embodiment may include at least one organic layer (hereinafter, organic encapsulation layer) and at least one inorganic encapsulation layer.

The inorganic encapsulation layer protects the display device layer DP-ED from moisture/oxygen, and the organic encapsulation layer protects the display device layer DP-ED from foreign materials such as dust particles. The inorganic encapsulation layer may include silicon nitride, silicon oxy nitride, silicon oxide, titanium oxide, and/or aluminum oxide, without specific limitation. The organic encapsulation layer may include an acrylic compound, an epoxy-based compound, etc. The organic encapsulation layer may include a photopolymerizable organic material, without specific limitation.

The encapsulation layer TFE may be on the second electrode EL2 and may be provided while filling the opening portion OH.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting light produced from the light emitting devices ED-1, ED-2 and ED-3, respectively. The luminous areas PXA-R, PXA-G and PXA-B may be separated (e.g., spaced apart) from each other on a plane.

The luminous areas PXA-R, PXA-G and PXA-B may be areas separated (e.g., spaced apart) by the pixel definition layer PDL. The non-luminous areas NPXA may be areas between neighboring luminous areas PXA-R, PXA-G and PXA-B and may be areas corresponding to the pixel definition layer PDL. In the present disclosure, each of the luminous areas PXA-R, PXA-G and PXA-B may correspond to each pixel. The pixel definition layer PDL may divide the light emitting devices ED-1, ED-2 and ED-3. The emission layers EML-R, EML-G and EML-B of the light emitting devices ED-1, ED-2 and ED-3 may be provided and divided in the opening portions OH defined in the pixel definition layer PDL.

The luminous areas PXA-R, PXA-G and PXA-B may be divided into a plurality of groups according to the color of light produced from the light emitting devices ED-1, ED-2 and ED-3. In the display device DD of an embodiment, shown in FIG. 1 and FIG. 2, three luminous areas PXA-R, PXA-G and PXA-B, emitting red light, green light and blue light are illustrated. For example, the display device DD of an embodiment may include a red luminous area PXA-R, a green luminous area PXA-G and a blue luminous area PXA-B, which are divided (e.g., spaced apart) from each other.

In the display device DD according to an embodiment, a plurality of light emitting devices ED-1, ED-2 and ED-3 may emit light having different wavelength regions. For example, in an embodiment, the display device DD may include a first light emitting device ED-1 emitting red light, a second light emitting device ED-2 emitting green light, and a third light emitting device ED-3 emitting blue light. In some embodiments, the red luminous area PXA-R, the green luminous area PXA-G, and the blue luminous area PXA-B of the display device DD may correspond to the first light emitting device ED-1, the second light emitting device ED-2, and the third light emitting device ED-3, respectively.

However, an embodiment of the present disclosure is not limited thereto, and the first to third light emitting devices ED-1, ED-2 and ED-3 may emit light in the same wavelength region, or at least one thereof may emit light in a different wavelength region. For example, all the first to third light emitting devices ED-1, ED-2 and ED-3 may emit blue light.

The luminous areas PXA-R, PXA-G and PXA-B in the display device DD according to an embodiment may be arranged in a stripe shape. Referring to FIG. 1, a plurality of red luminous areas PXA-R, a plurality of green luminous areas PXA-G and a plurality of blue luminous areas PXA-B may be arranged along a second directional axis DR2. In addition, the red luminous areas PXA-R, the green luminous areas PXA-G and the blue luminous areas PXA-B may be arranged by turns along a first directional axis DR1.

In FIG. 1 and FIG. 2, the areas of the luminous areas PXA-R, PXA-G and PXA-B are shown similar, but an embodiment of the present disclosure is not limited thereto. The areas of the luminous areas PXA-R, PXA-G and PXA-B may be different from each other according to the wavelength region of light emitted. the areas of the luminous areas PXA-R, PXA-G and PXA-B may mean areas on a plane defined by the first directional axis DR1 and the second directional axis DR2.

The arrangement type (or kind) of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required for the display device DD. For example, the arrangement type (or kind) of the luminous areas PXA-R, PXA-G and PXA-B may be a pentile (PENTILE®) arrangement structure (e.g., an RGBG matrix, RGBG structure, or RGBG matrix structure), or a diamond (DIAMOND PIXEL™) arrangement structure. PENTILE® is a duly registered trademark of Samsung Display Co., Ltd., and DIAMOND PIXEL™ is a trademark of Samsung Display Co., Ltd.

In addition, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

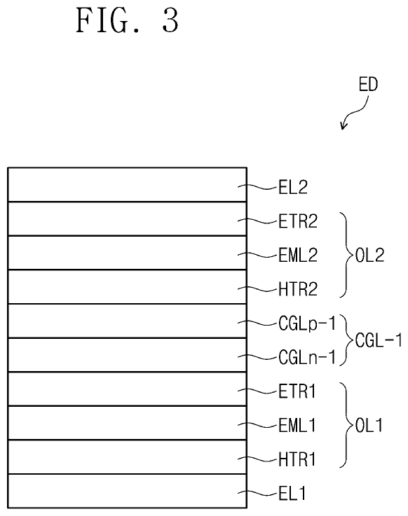

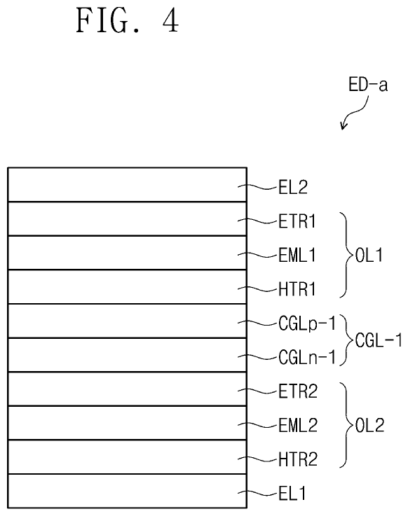

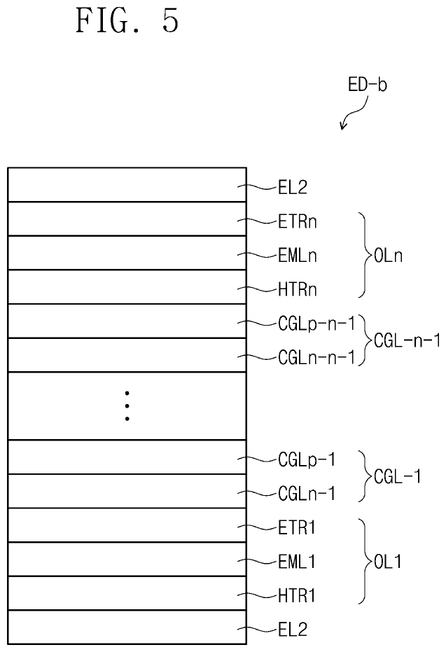

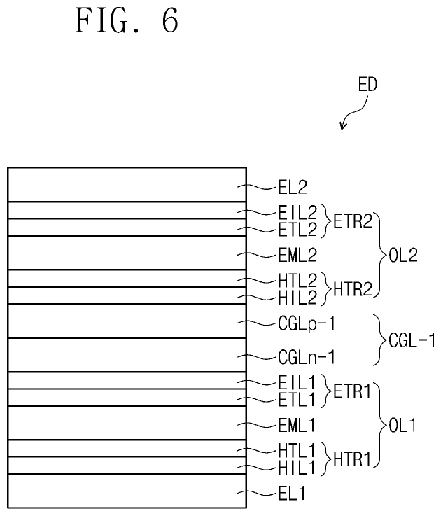

FIG. 3 is a cross-sectional view schematically showing a light emitting device according to an embodiment. FIG. 4 is a cross-sectional view schematically showing a light emitting device according to an embodiment. FIG. 5 is a diagram schematically showing a light emitting unit. FIG. 6 is a diagram schematically showing a light emitting unit.

Referring to FIG. 3 and FIG. 4, light emitting devices ED and ED-a according to embodiments may include a first electrode EL1, a first light emitting unit OL1, a charge generation layer CGL-1, a second light emitting unit OL2, and a second electrode EL2. The first light emitting unit OL1 may be on the first electrode EL1. The second electrode EL2 may be on the first light emitting unit OL1. The second light emitting unit OL2 may be between the first light emitting unit OL1 and the second electrode EL2, as shown in FIG. 3, or between the first light emitting unit OL1 and the first electrode EL1, as shown in FIG. 4.

The charge generation layer CGL-1 may be between the first light emitting unit OL1 and the second light emitting unit OL2. In FIG. 3 and FIG. 4, the light emitting devices ED and ED-a include two light emitting units OL1 and OL2, and one charge generation layer CGL-1 therebetween, but an embodiment of the present disclosure is not limited thereto. For example, as shown in FIG. 5, a light emitting device ED-b of an embodiment may include n light emitting units OL1 to OLn and n−1 charge generation layers CGL-1 to CGLn−1 between n light emitting units OL1 to OLn. Here, n is an integer of 3 or more. The explanation hereinafter will be based on the light emitting device ED shown in FIG. 3, and the same explanation of the light emitting device ED based on FIG. 3 may be applied to light emitting devices ED-a and ED-b of FIG. 4 and FIG. 5, respectively.

The first electrode EL1 has conductivity (e.g., electrical conductivity). The first electrode EL1 may be formed using a metal material, a metal alloy and/or a conductive compound. The first electrode EL1 may be an anode or a cathode.

However, an embodiment of the present disclosure is not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and/or oxides thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Otherwise, the first electrode EL1 may have a structure of a plurality of layers including a reflective layer or a transflective layer formed using the above materials, and a transmissive conductive layer formed using ITO, IZO, ZnO, and/or ITZO. For example, the first electrode EL1 may have a three-layer structure of ITO/Ag/ITO. However, an embodiment of the present disclosure is not limited thereto. In addition, the first electrode EL1 may include the above-described metal materials, combinations of two or more metal materials selected from the above-described metal materials, and/or oxides of the above-described metal materials, without limitation. The thickness of the first electrode EL1 may be from about 700 Å to about 10,000 Å. For example, the thickness of the first electrode EL1 may be from about 1,000 Å to about 3,000 Å.

The first light emitting unit OL1 may include a first hole transport region HTR1, a first emission layer EML1, and a first electron transport region ETR1. The second light emitting unit OL2 may include a second hole transport region HTR2, a second emission layer EML2, and a second electron transport region ETR2. The first hole transport region HTR1 may be provided closer to the first electrode EL1 than the first electron transport region ETR1. The second hole transport region HTR2 may be provided closer to the first electrode EL1 than the second electron transport region ETR2.

Hereinafter, the first hole transport region HTR1 and the second hole transport region HTR2 will be explained together, and the first electron transport region ETR1 and the second electron transport region ETR2 will be explained together. In addition, the first emission layer EML1 and the second emission layer EML2 have a difference in configuration, and will be explained separately.

Each of the first hole transport region HTR1 and the second hole transport region HTR2 may have a single layer formed using a single material, a single layer formed using a plurality of different materials or a multilayer structure having a plurality of layers formed using a plurality of different materials.

Referring to FIG. 6, the same explanation of the light emitting device ED based on FIG. 3 may be applied to light emitting device ED of FIG. 6. The first hole transfer region HTR1 may comprise a first hole injection layer HIL1 and a first hole transfer layer HTL1, the first electron transfer region ETR1 may comprise a first electron injection layer EIL1 and a first electron transfer layer ETL1, the first hole transfer region HTR2 may comprise a second hole injection layer HIL2 and a second hole transfer layer HTL2, and the first electron transfer region ETR2 may comprise a second electron injection layer EIL2 and a second electron transfer layer ETL2. The first hole injection layer HIL1 may be on the first electrode EL1. The first emission layer EML1 may be between the first electron transport layer ETL1 and the first hole transport layer HTL1. The second emission layer EML2 may be between the second electron transport layer ETL2 and the second hole transport layer HTL2. The second electrode EL2 may be on the first electron injection layer EIL1.

Each of the first hole transport region HTR1 and the second hole transport region HTR2 may have a single layer structure of a hole injection layer HIL1 and HIL2 or a hole transport layer HTL1 and HTL2 or a single layer structure formed using a hole injection material and a hole transport material. In addition, each of the first hole transport region HTR1 and the second hole transport region HTR2 may have a single layer structure formed using a plurality of different materials, or a structure stacked in order in a thickness direction of hole injection layer HIL1 and HIL2/hole transport layer HTL1 and HTL2, hole injection layer HIL1 and HIL2/hole transport layer HTL1 and HTL2/buffer layer, hole injection layer HIL1 and HIL2/buffer layer, hole transport layer HTL1 and HTL2/buffer layer, or hole injection layer HIL1 and HIL2/hole transport layer HTL1 and HTL2/electron blocking layer, without limitation.

Each of the first hole transport region HTR1 and the second hole transport region HTR2 may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

Each of the first hole transport region HTR1 and the second hole transport region HTR2 may include a compound represented by Formula H-2 below.

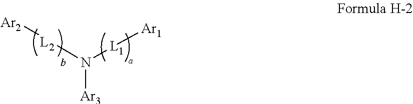

In Formula H-2 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. If “a” or “b” is an integer of 2 or more, a plurality of L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-2, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-2, Ar₃ may be a substituted or unsubstituted aryl group of 6 to 30 ring-forming carbon atoms, or a substituted or unsubstituted heteroaryl group of 2 to 30 ring-forming carbon atoms.

The compound represented by Formula H-2 may be a monoamine compound. Otherwise, the compound represented by Formula H-2 may be a diamine compound in which at least one selected from among Ar₁ to Ar₃ includes an amine group as a substituent. In addition, the compound represented by Formula H-2 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-2 may be represented by any one selected from among the compounds in Compound Group H below. However, the compounds shown in Compound Group H are only illustrations, and the compound represented by Formula H-2 is not limited to the compounds represented in Compound Group H below.

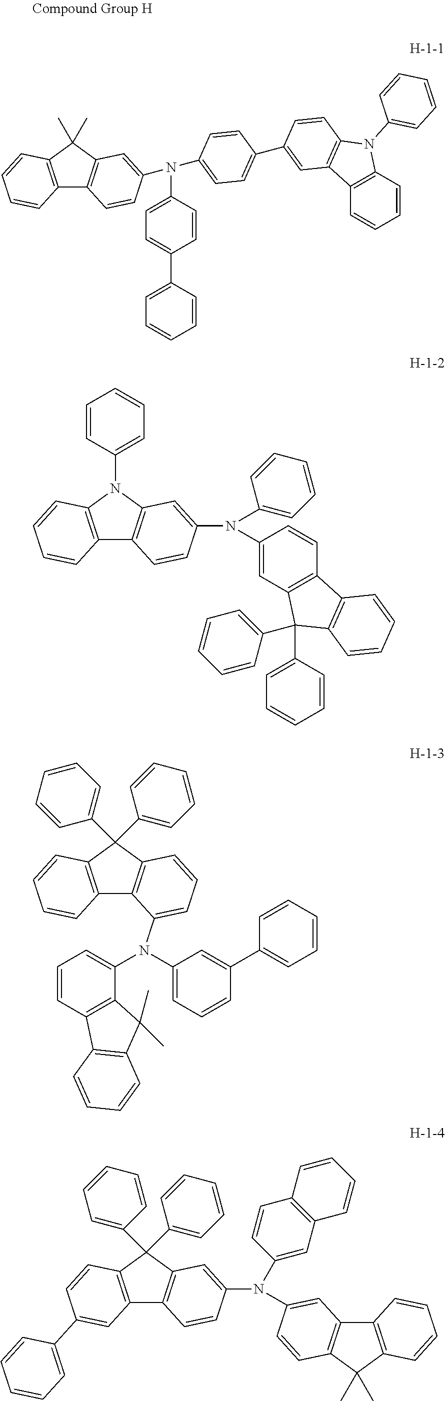 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

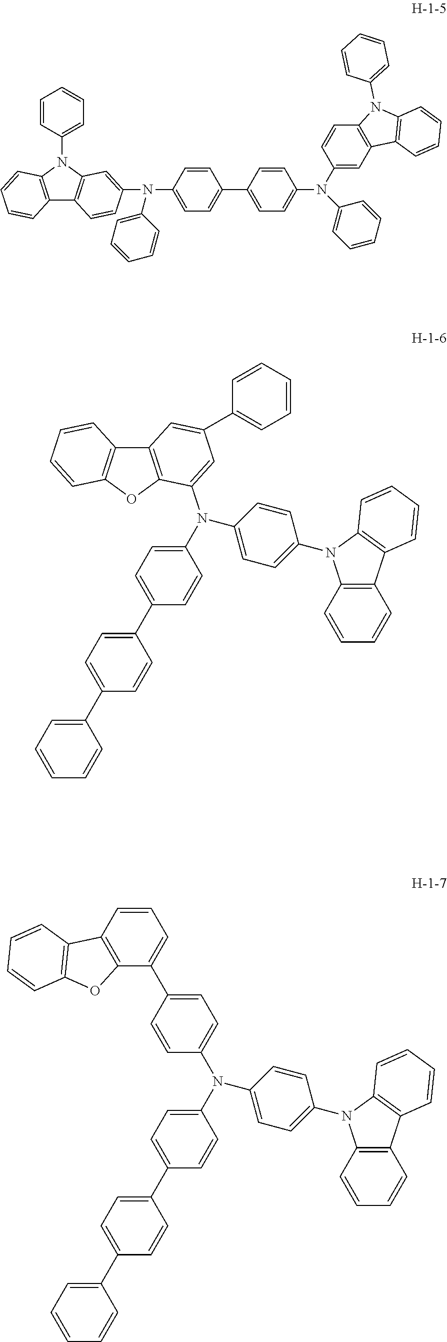 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

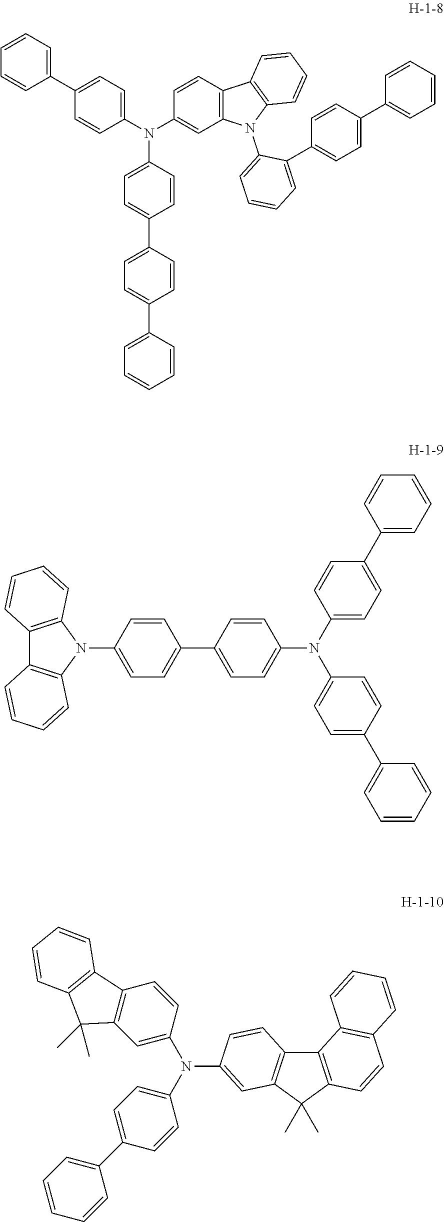 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

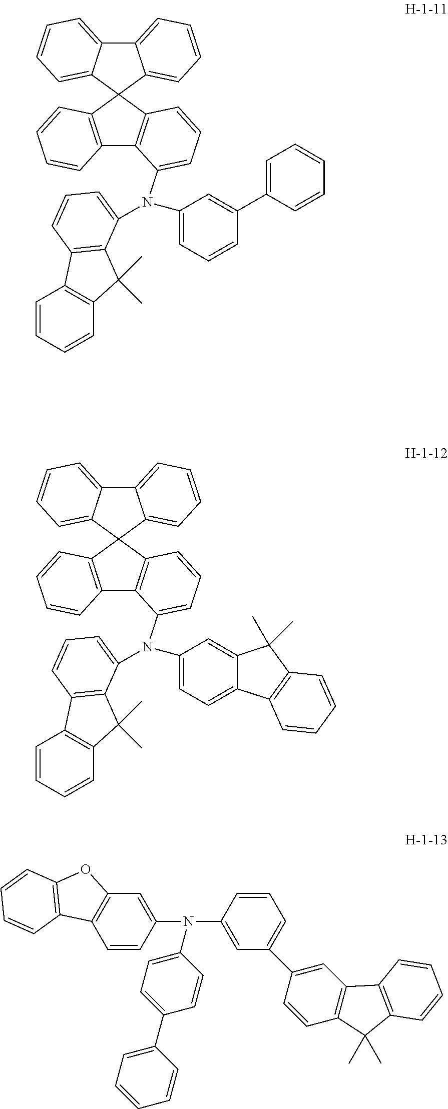 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

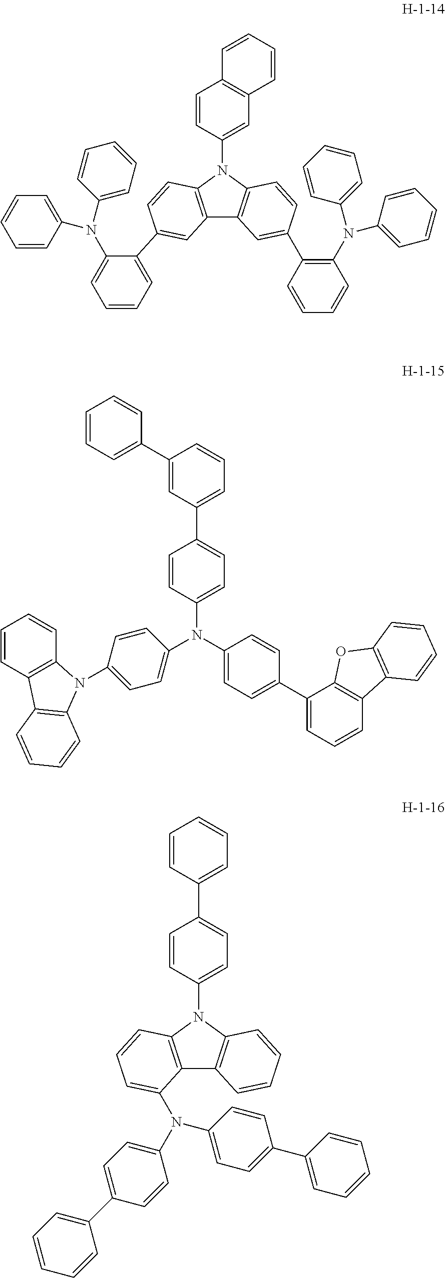 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

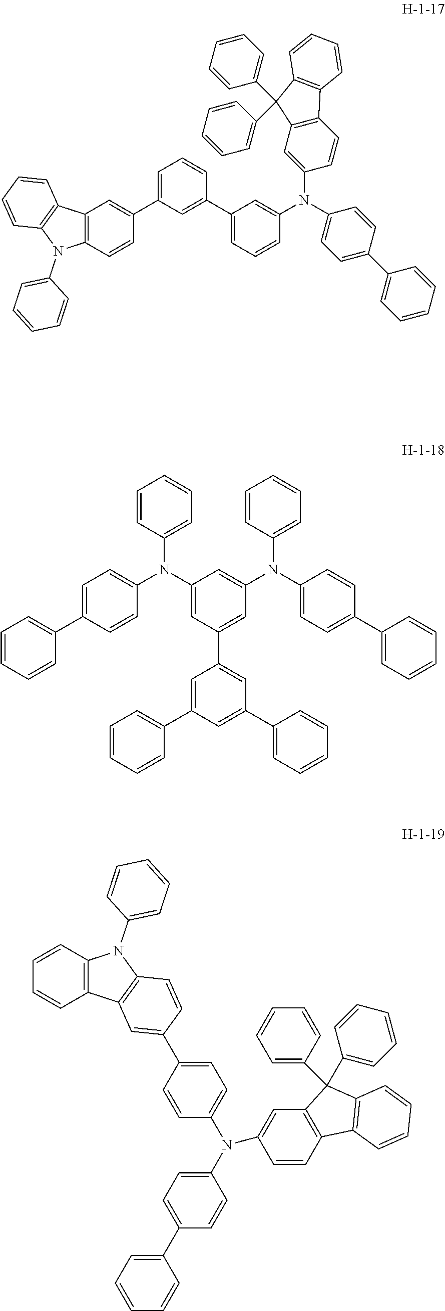 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

Each of the first hole transport region HTR1 and the second hole transport region HTR2 may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HATCN).

Each of the first hole transport region HTR1 and the second hole transport region HTR2 may include carbazole derivatives such as N-phenylcarbazole and/or polyvinylcarbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In addition, each of the first hole transport region HTR1 and the second hole transport region HTR2 may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

Each of the first hole transport region HTR1 and the second hole transport region HTR2 may include the above-described compounds of the hole transport region in at least one selected from among the hole injection layer HIL1 and HIL2, hole transport layer HTL1 and HTL2, and the electron blocking layer.

The thickness of each of the first hole transport region HTR1 and the second hole transport region HTR2 may be from about 100 Å to about 10,000 Å. For example, from about 100 Å to about 5,000 Å. In case where each of the first hole transport region HTR1 and the second hole transport region HTR2 includes a hole injection layer HIL1 and HIL2, the thickness of the hole injection region HIL1 and HIL2 may be, for example, from about 30 Å to about 1,000 Å. In case where each of the first hole transport region HTR1 and the second hole transport region HTR2 includes a hole transport layer HTL1 and HTL2, the thickness of the hole transport layer HTL1 and HTL2 may be from about 30 Å to about 1,000 Å. For example, in case where each of the first hole transport region HTR1 and the second hole transport region HTR2 includes an electron blocking layer, the thickness of the electron blocking layer may be from about 10 Å to about 1,000 Å. If the thicknesses of the hole transport region HTR1 and HTR2, the hole injection layer HIL1 and HIL2, the hole transport layer HTL1 and HTL2 and the electron blocking layer satisfy the above-described ranges, suitable or satisfactory hole transport properties may be achieved without substantial increase of a driving voltage.

Each of the first hole transport region HTR1 and the second hole transport region HTR2 may further include a charge generating material to increase conductivity (e.g., electrical conductivity) in addition to the above-described materials. The charge generating material may be dispersed uniformly or non-uniformly in each of the first hole transport region HTR1 and the second hole transport region HTR2. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, each of the first hole transport region HTR1 and the second hole transport region HTR2 may further include at least one selected from among a buffer layer and an electron blocking layer in addition to the hole injection layer HIL1 and HIL2 and the hole transport layer HTL1 and HTL2. The buffer layer may compensate for a resonance distance according to the wavelength of light emitted from the emission layers EML1 and EML2, and may increase light emission efficiency. As materials included in the buffer layer, materials which may be included in each of the first hole transport region HTR1 and the second hole transport region HTR2 may be used. The electron blocking layer is a layer that plays role of preventing or reducing the injection of electrons from the first electron transport region ETR1 and the second electron transport region ETR2 to the first hole transport region HTR1 and the second hole transport region HTR2, respectively.

The first emission layer EML1 may include a first host, a phosphorescence sensitizer, and a first fluorescence dopant. In the first emission layer EML1, energy transfer may occur from the first host to the phosphorescence sensitizer, and energy transfer may occur from the phosphorescence sensitizer to the first fluorescence dopant. As described above, in the first emission layer EML1, energy transfer may occur in the order of the first host, the phosphorescence sensitizer, and the first fluorescence dopant, and hyper fluorescence may be emitted. In some embodiments, the first emission layer EML1 may emit blue light.

The first host may include an electron transport host and a hole transport host. The energy level of the triplet state of the hole transport host may be higher than the energy level of the triplet state of the first fluorescence dopant. The energy level of the singlet state of the electron transport host may be lower than the energy level of the singlet state of the first fluorescence dopant. In the first emission layer EML1, an exciplex may be formed by the hole transport host and the electron transport host. In this case, the triplet energy of the exciplex formed by the hole transport host and the electron transport host may correspond to the difference between a lowest unoccupied molecular orbital (LUMO) energy level of the electron transport host and a highest occupied molecular orbital (HOMO) energy level of the hole transport host.

For example, the absolute value of the triplet energy level (T1) of the exciplex formed by the hole transport host and the electron transport host may be about 2.4 eV to about 3.0 eV. In addition, the triplet energy of the exciplex may be a value smaller than the energy gap between the host materials. The exciplex may have triplet energy of about 3.0 eV or less, which is the energy gap between the hole transport host and the electron transport host.

The energy level of the triplet state of the exciplex may be higher than the energy level of the triplet state of the phosphorescence sensitizer. Accordingly, energy transfer may occur from the exciplex to the phosphorescence sensitizer.

The hole transport host may be represented by Formula HT-1.

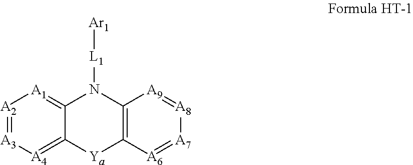

In Formula HT-1, A1 to A4, and A6 to A9 may be each independently N or CR₄₁. For example, A1 to A9 may be all CR₄₁. Otherwise, any one selected from among A1 to A9 may be N, and the remainder may be CR₄₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but an embodiment of the present disclosure is not limited thereto.

In Formula HT-1, Yₐ may be a direct linkage, CR₄₂R₄₃, or SiR₄₄R₄₅. For example, the foregoing may mean that two benzene rings connected with the nitrogen atom of Formula HT-1 are connected via a direct linkage,

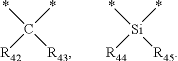

In Formula HT-1, if Yₐ is a direct linkage, the substituent represented by Formula HT-1 may include a carbazole moiety.

In Formula HT-1, Ar₁ may be a substituted or unsubstituted aryl group of 6 to 30 ring-forming carbon atoms, or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but an embodiment of the present disclosure is not limited thereto.

In Formula HT-1, R₄₁ to R₄₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. Otherwise, R₄₁ to R₄₅ may be each independently combined with an adjacent group to form a ring. For example, R₄₁ to R₄₅ may be each independently a hydrogen atom, or a deuterium atom. R₄₁ to R₄₅ may be each independently an unsubstituted methyl group or an unsubstituted phenyl group.

The hole transport host may include at least one selected from among the compounds in Compound Group 1. For example, the hole transport host may include Compound HT6. However, this is only an illustration, and an embodiment of the present disclosure is not limited thereto.

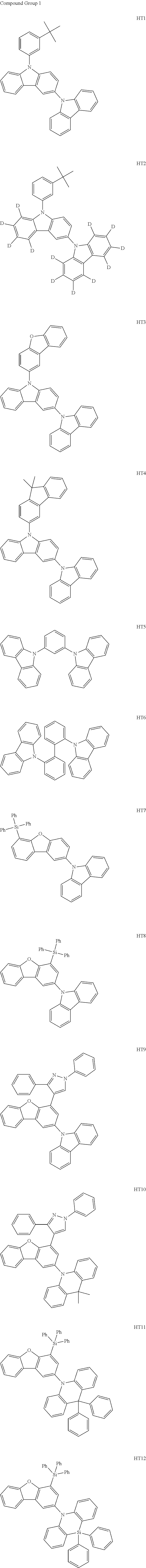

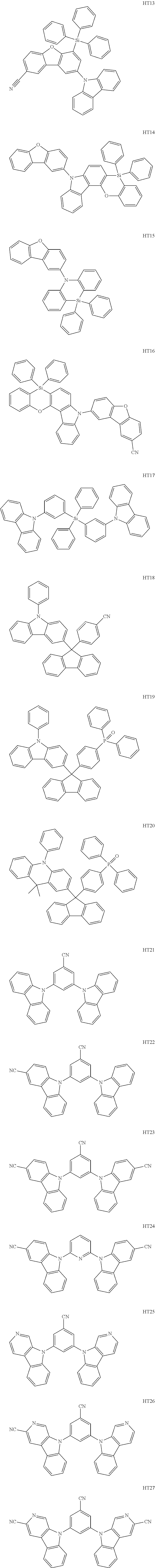

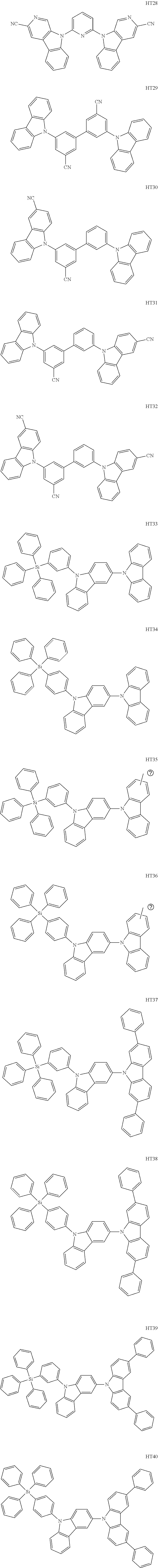

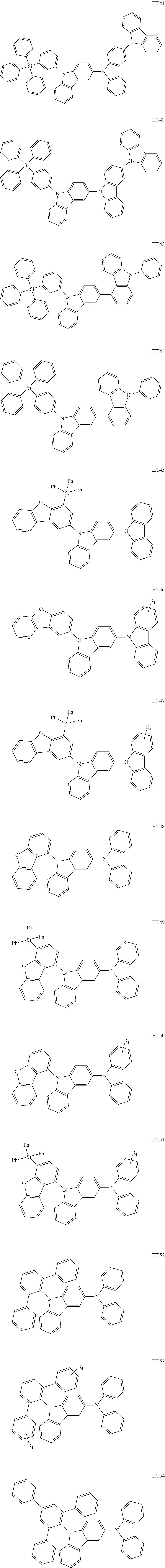

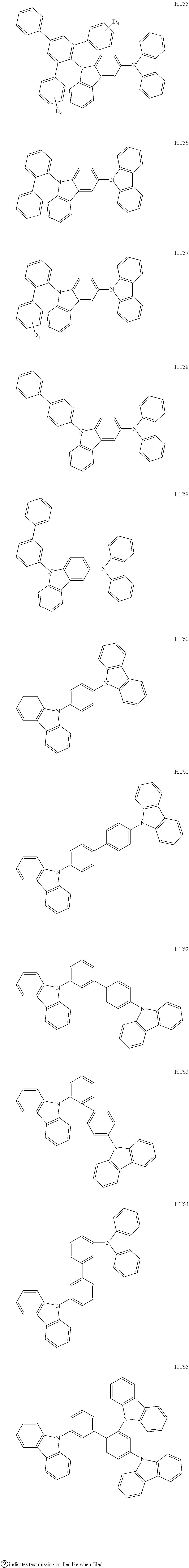

The electron transport host may be represented by Formula ET-1.

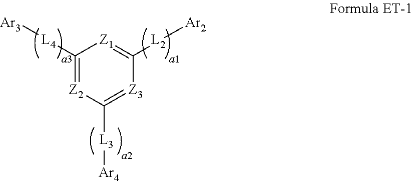

In Formula ET-1, at least one selected from among Z₁ to Z₃ may be N, and the remainder may be CRₐ₃, where Rₐ₃ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

a₁ to a₃ are each independently an integer of 0 to 10.

L₂ to L₄ may be each independently a direct linkage, a substituted or unsubstituted arylene group of 6 to 30 ring-forming carbon atoms, or a substituted or unsubstituted heteroarylene group of 2 to 30 ring-forming carbon atoms. In cases where a₁ to a₃ are integers of 2 or more, L₂ to L₄ may be each independently a substituted or unsubstituted arylene group of 6 to 30 ring-forming carbon atoms, or a substituted or unsubstituted heteroarylene group of 2 to 30 ring-forming carbon atoms.

Ar₂ to Ar₄ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may be substituted or unsubstituted phenyl groups or substituted or unsubstituted carbazole groups.

The electron transport host may include at least one selected from among the compounds in Compound Group 2. For example, the electron transport host may include Compound ETH95. However, this is only an illustration, and an embodiment of the present disclosure is not limited thereto.

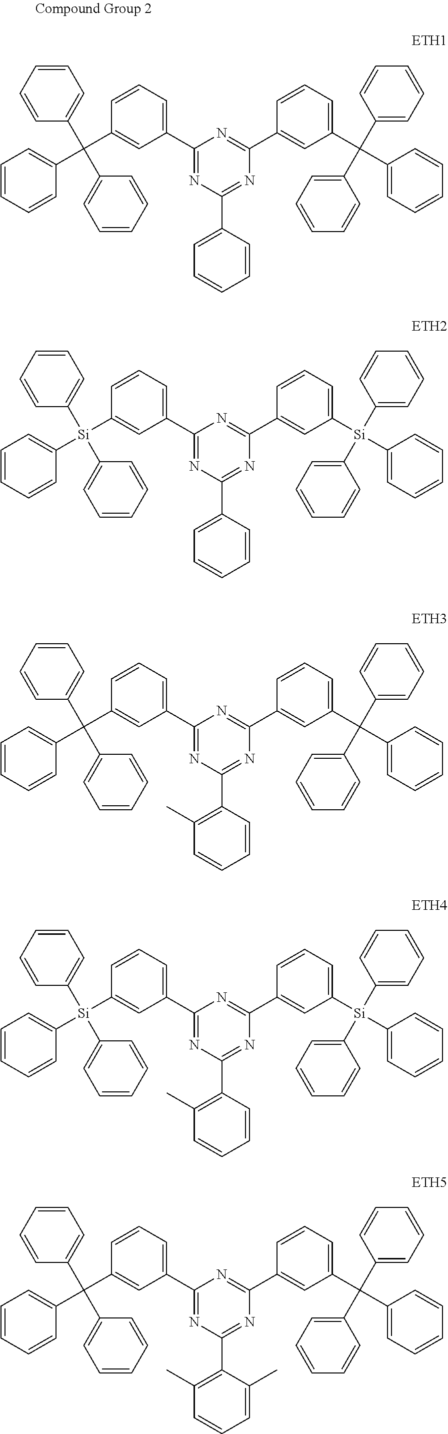

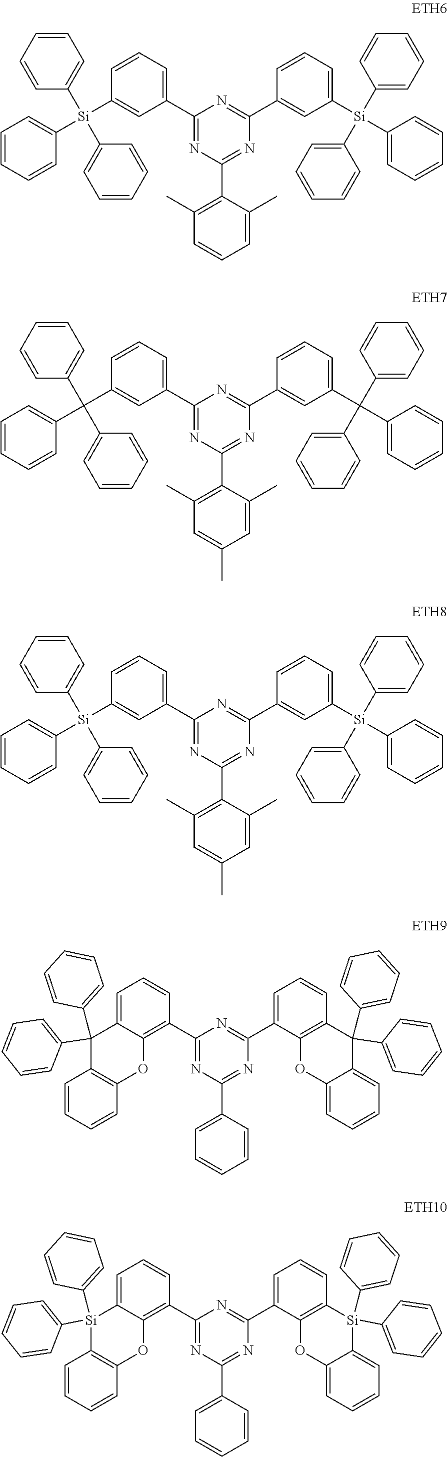

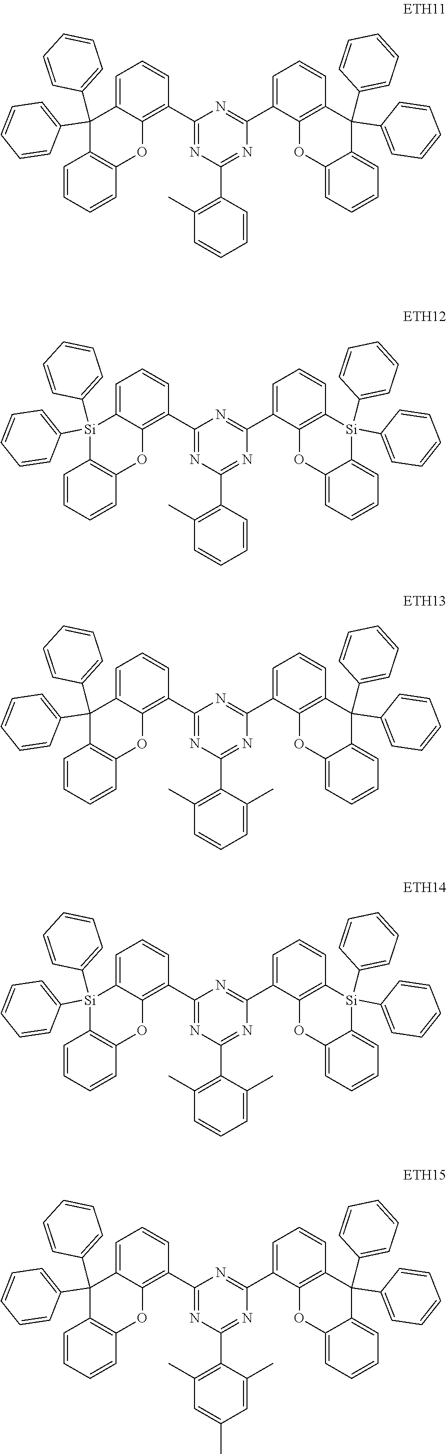

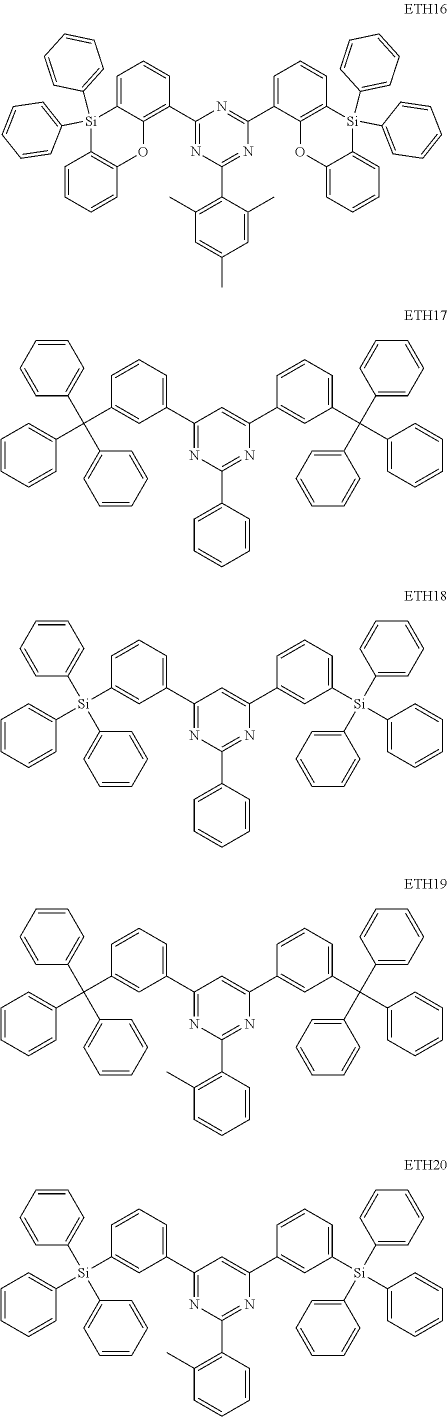

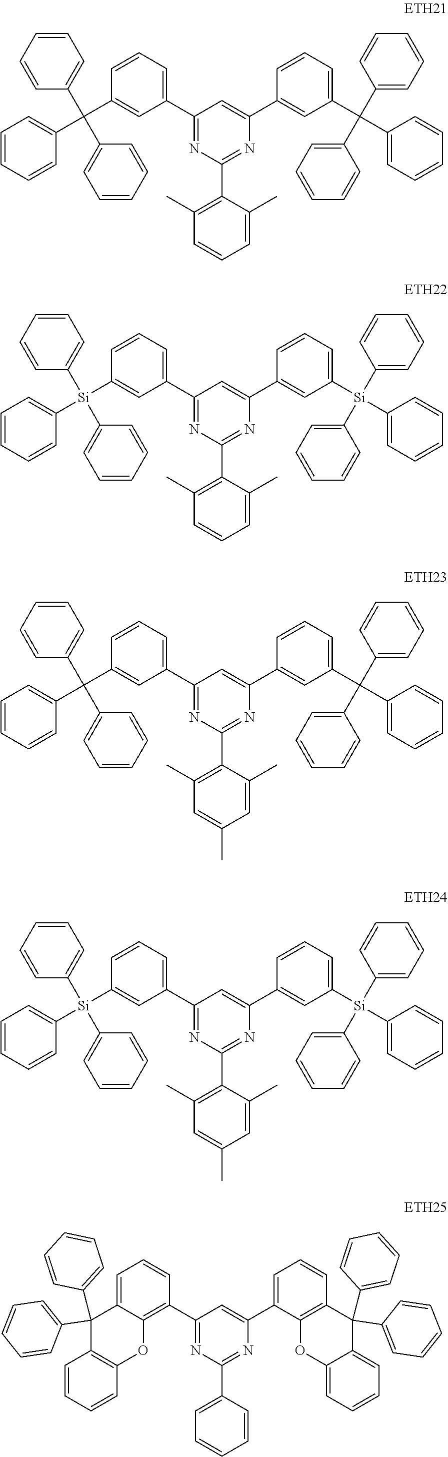

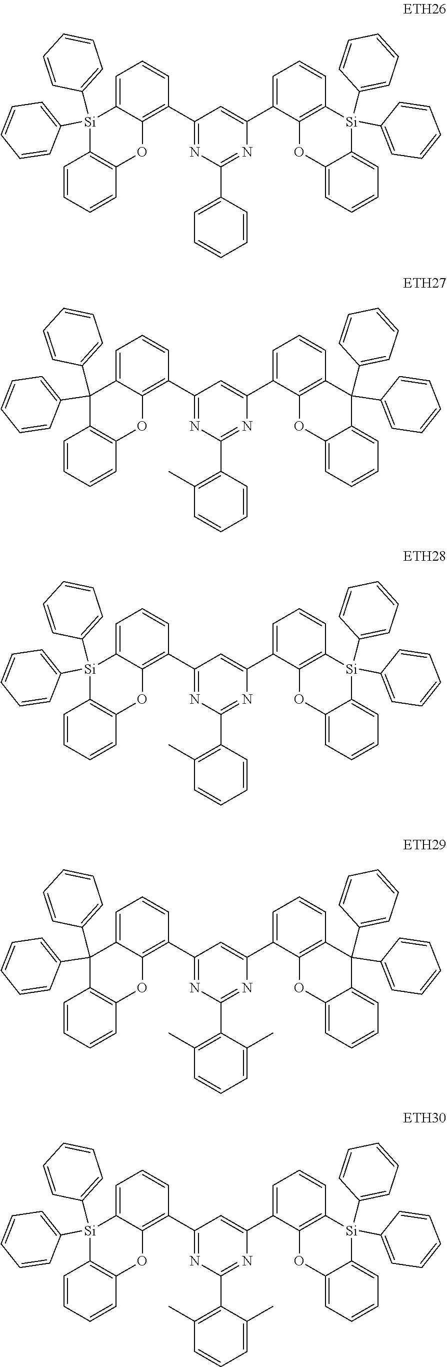

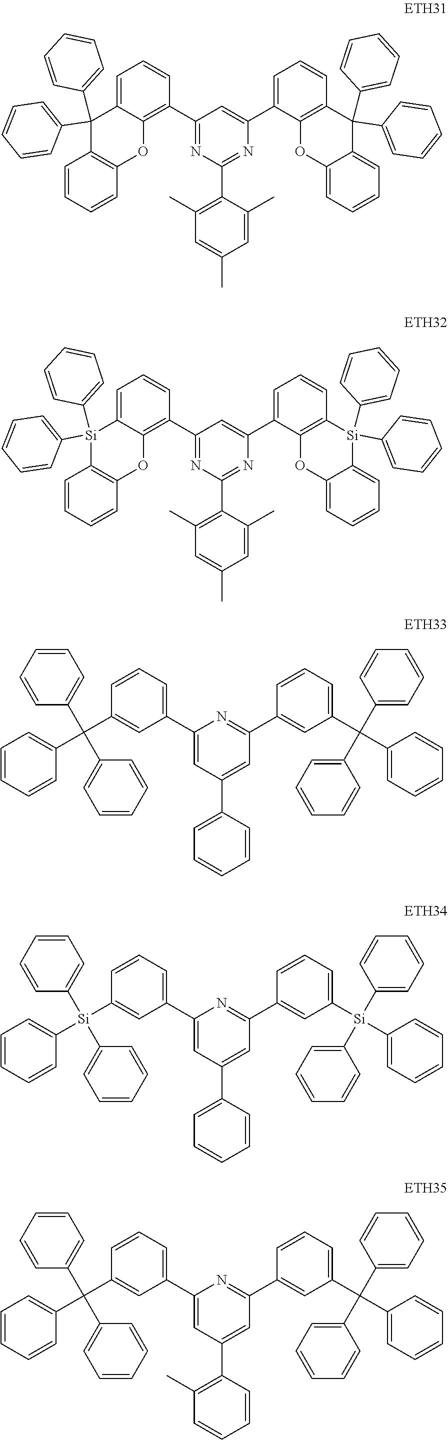

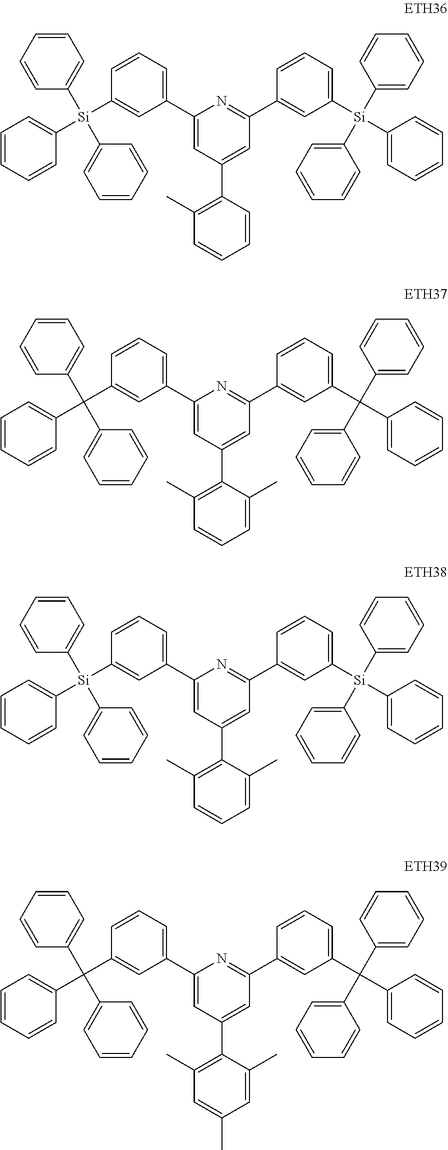 [SMILES: Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1]

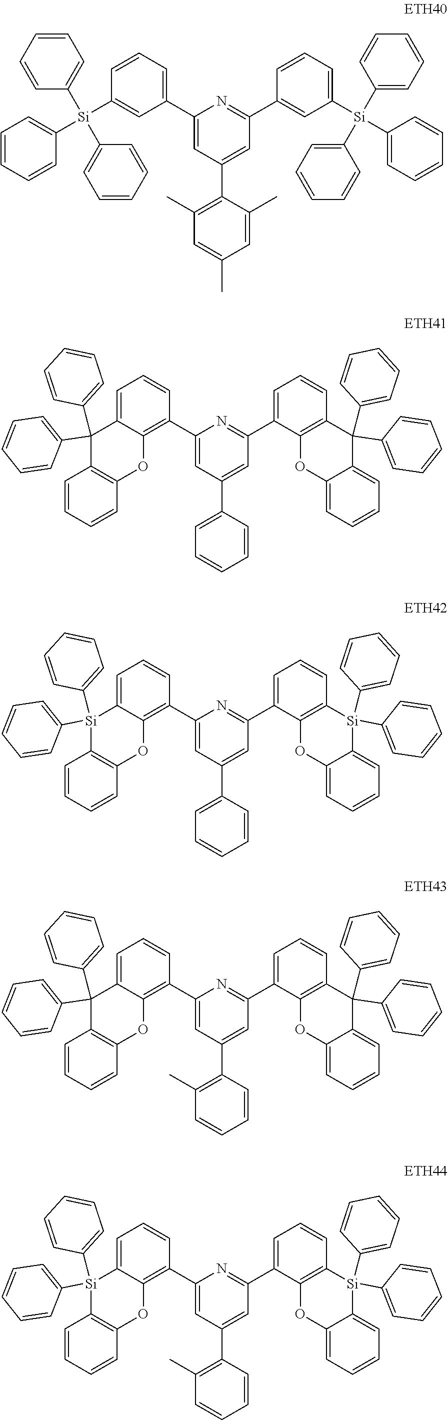

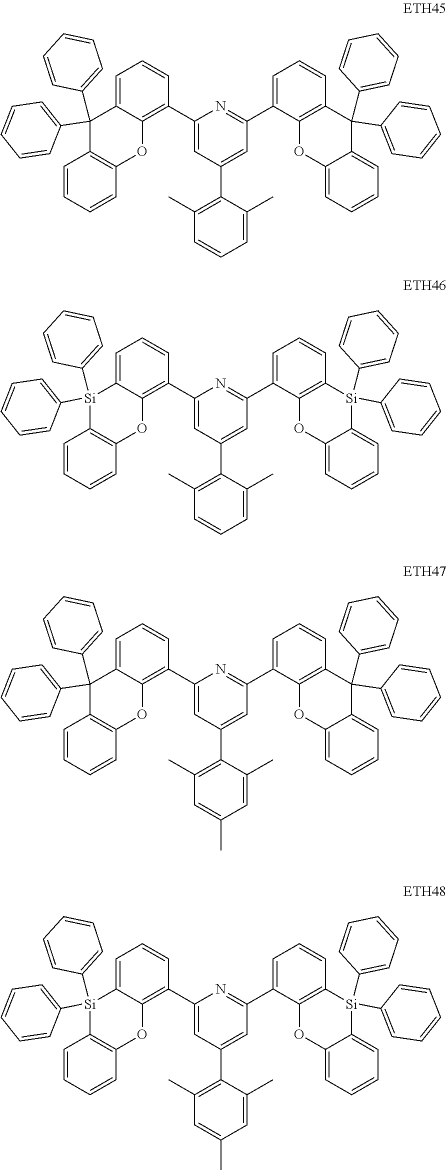 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

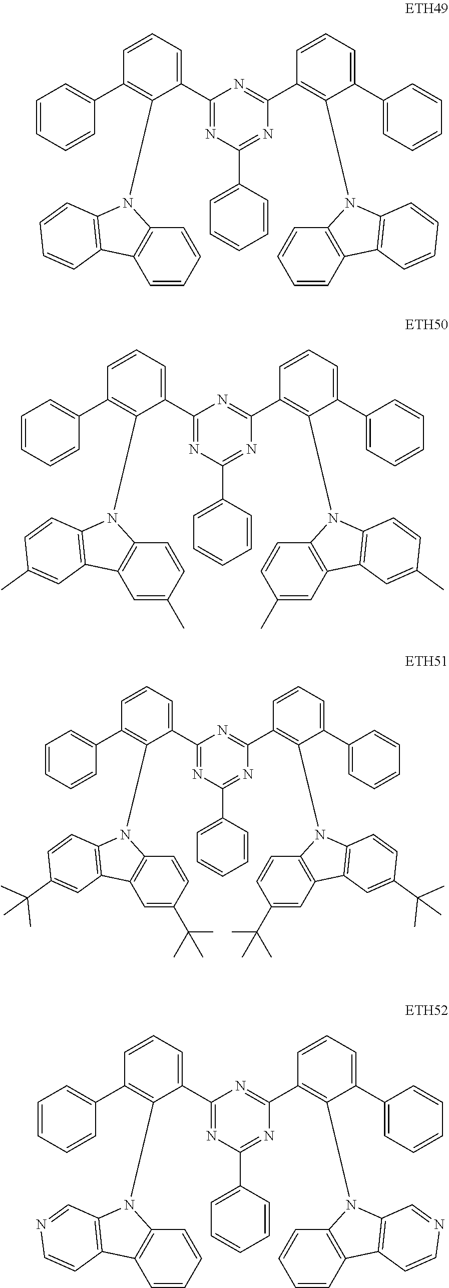

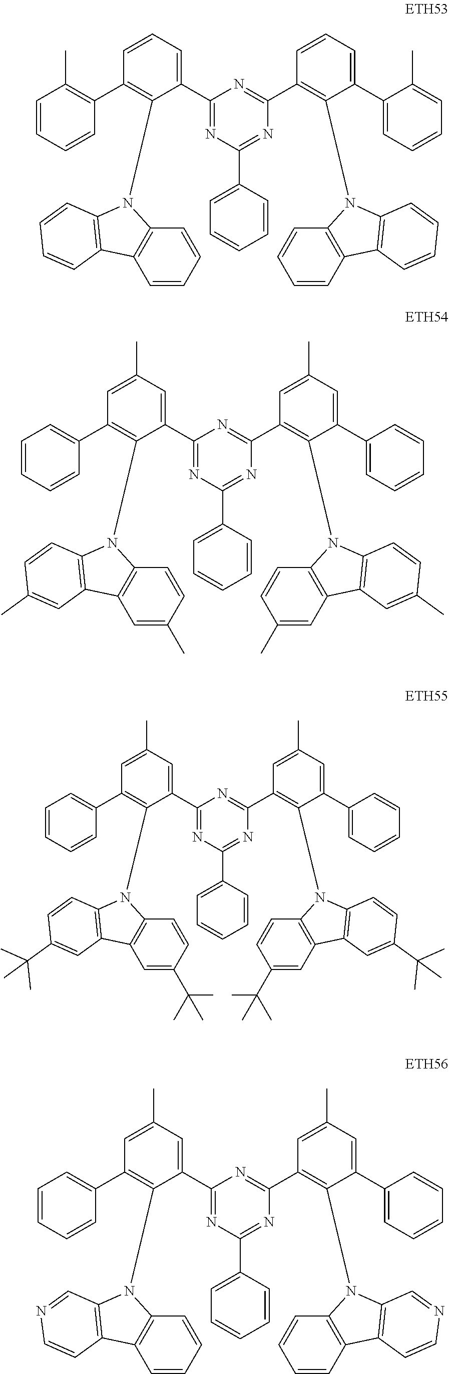

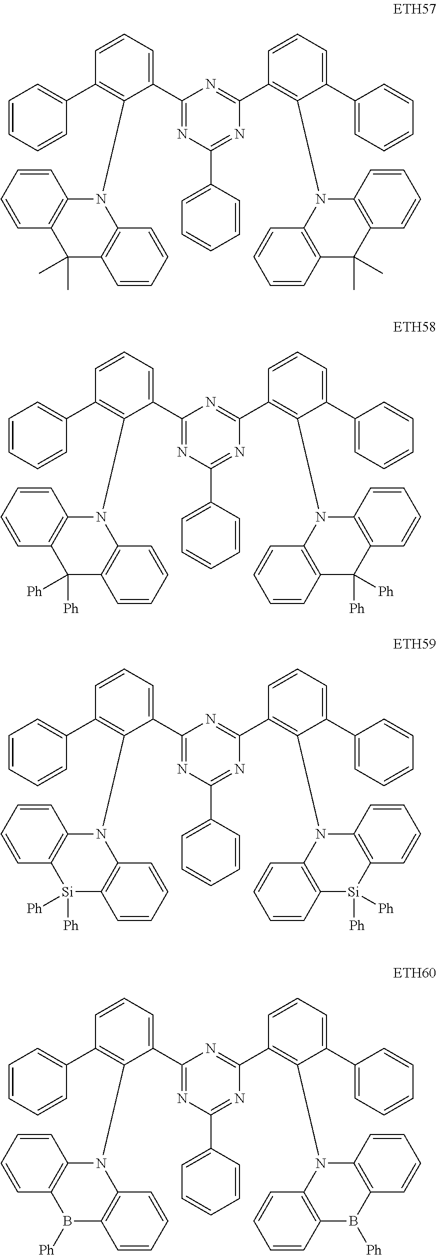

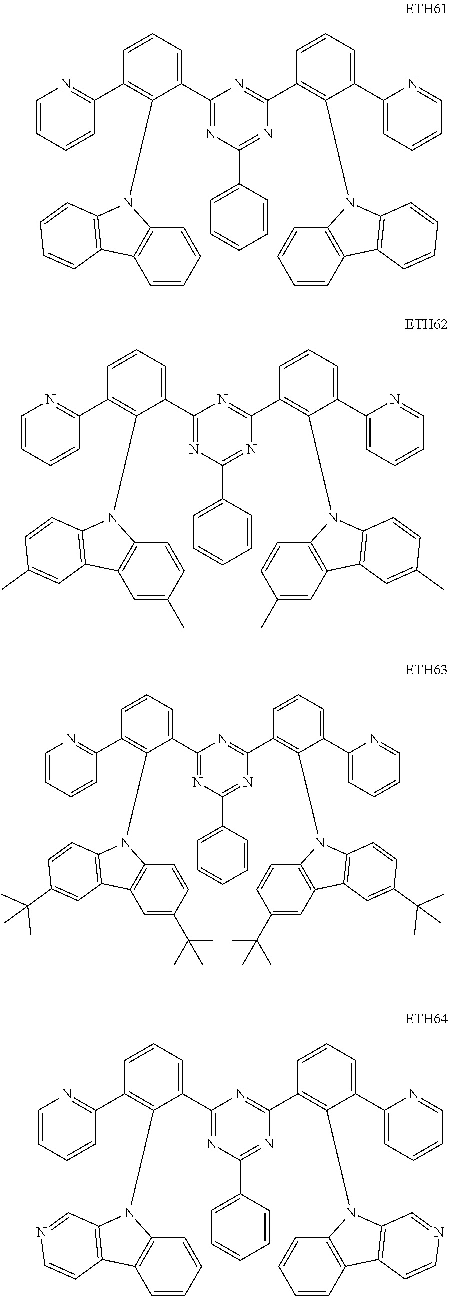

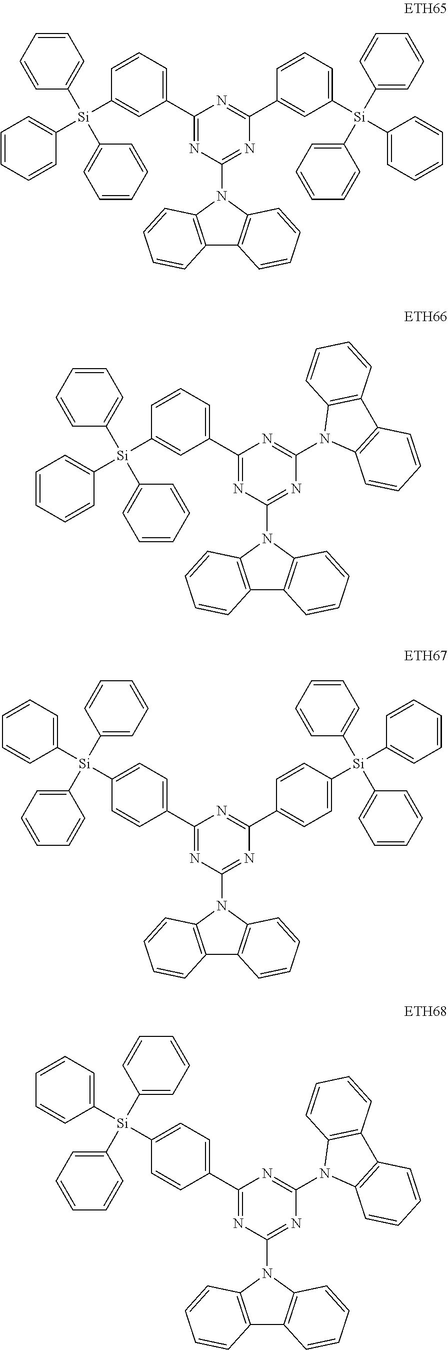 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

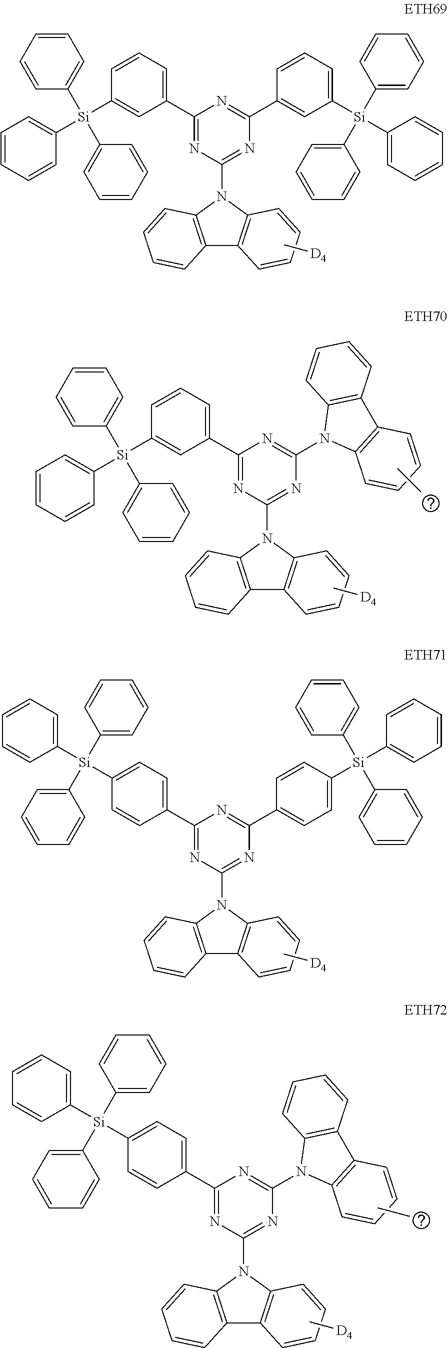

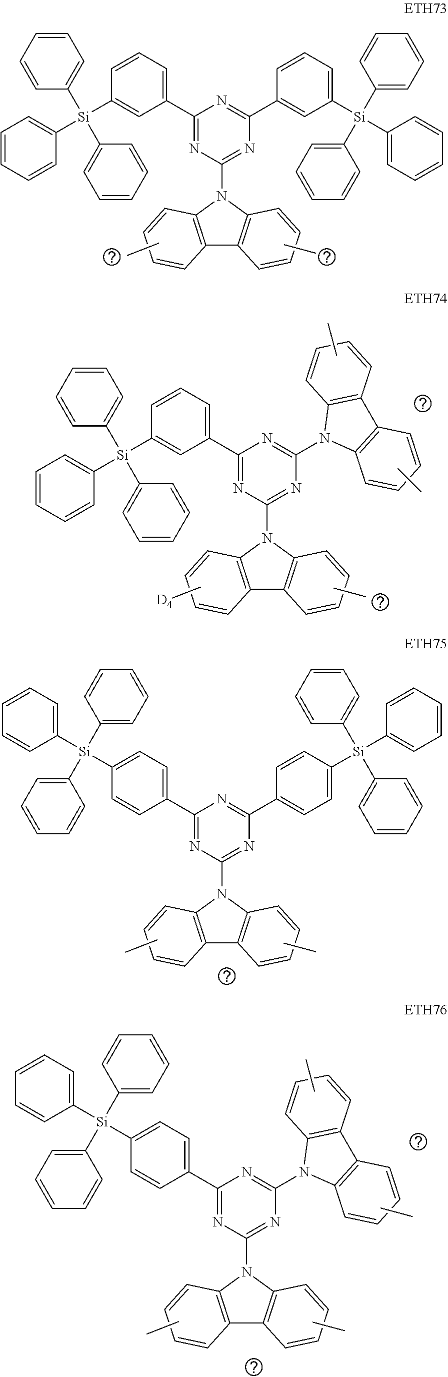

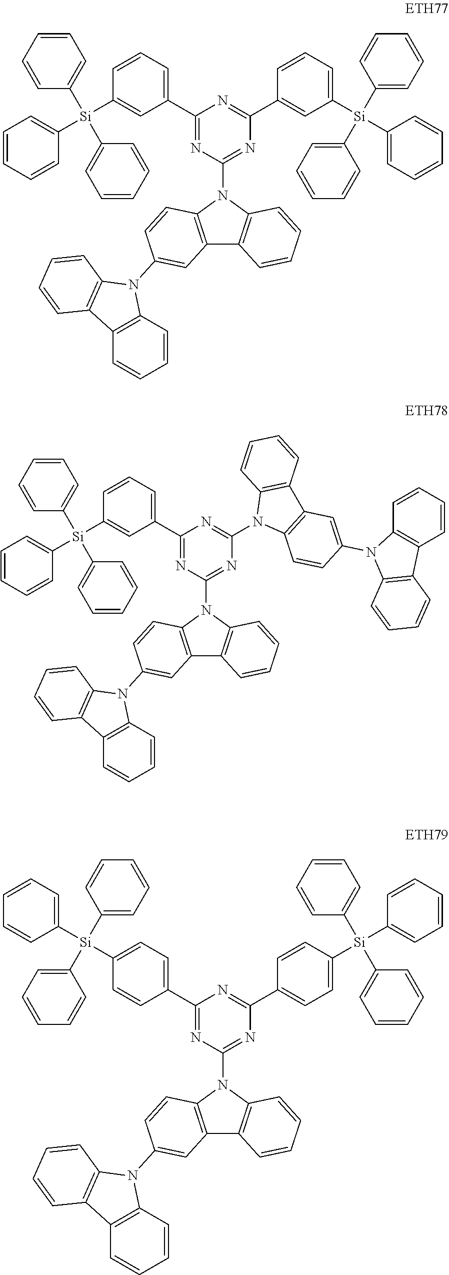 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

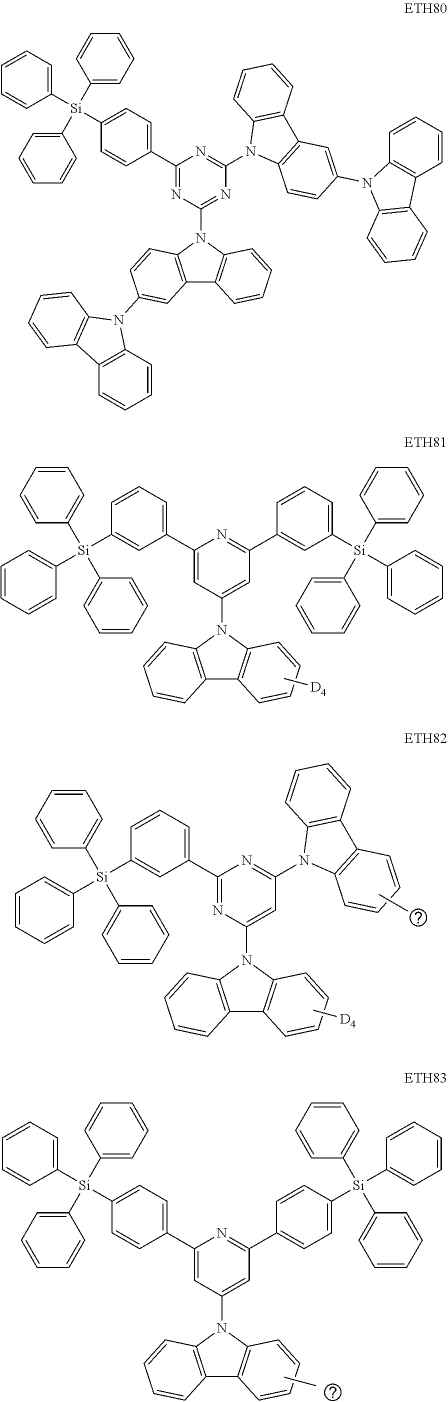

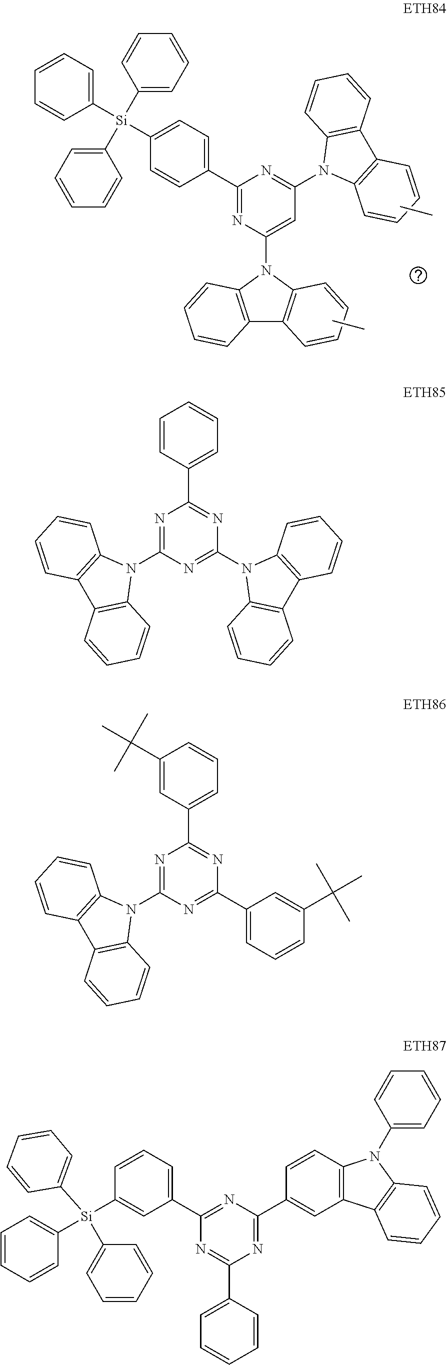

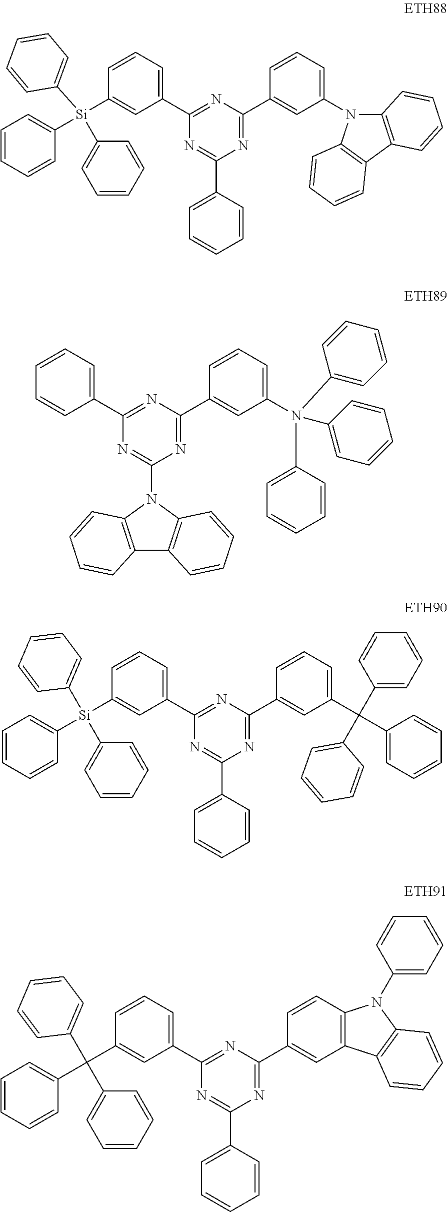

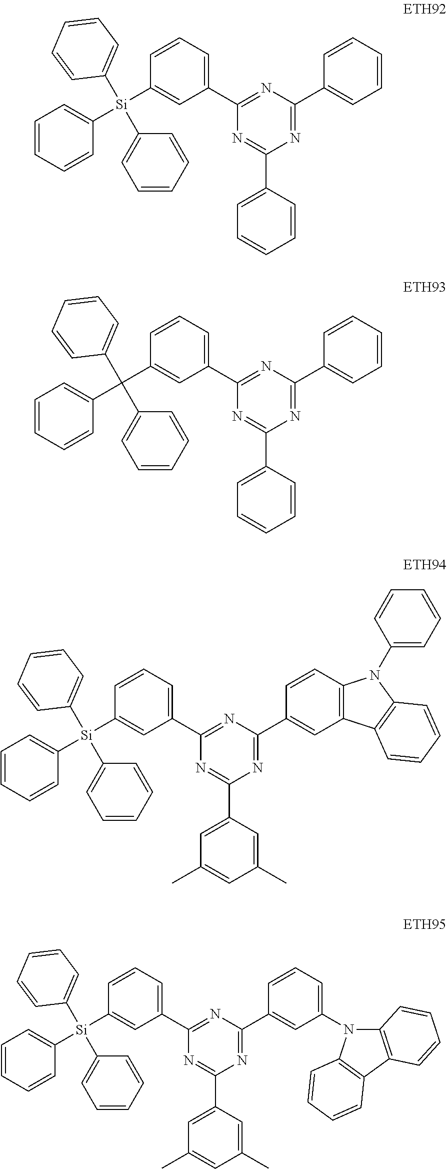 [SMILES: c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1]

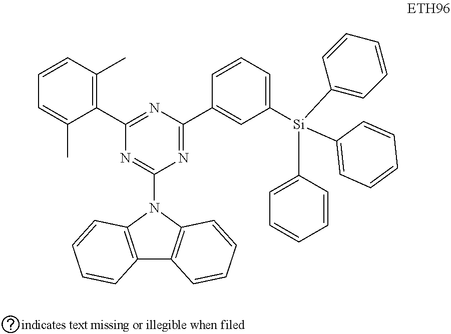 [SMILES: Cc1cccc(C)c1-c1nc(-c2cccc([Si](c3ccccc3)(c3ccccc3)c3ccccc3)c2)nc(-n2c3ccccc3c3ccccc32)n1]

In the compounds included in Compound Group 2, “D” means a deuterium atom.

In an embodiment, the first host may include Compound HT6 as the hole transport host and Compound ETH66 as the electron transport host. For example, the first host may be a mixture of Compound HT6 and Compound ETH66 in a weight ratio of about 6:4 to about 8:2. However, this is only an illustration, and an embodiment of the present disclosure is not limited thereto. The phosphorescence sensitizer may be an auxiliary dopant playing the role of transferring energy from the host to the first fluorescence dopant. The phosphorescence sensitizer may promote the energy transfer from the host to the first fluorescence dopant. Accordingly, in an embodiment, by including the phosphorescence sensitizer in the first emission layer EML1, an emission ratio by the first fluorescence dopant may increase to improve the emission efficiency of the first emission layer EML1. In addition, energy transfer to the first fluorescence dopant may be facilitated, excitons formed in the first emission layer EML1 may not be accumulated in the first emission layer EML1 to reduce the deterioration of a device. Accordingly, the device lifetime of the light emitting device ED of an embodiment, including the first light emitting unit OL1 may increase.

The phosphorescence sensitizer may be represented by Formula D-1.

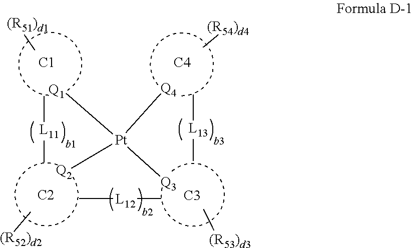

In Formula D-1, Q₁ to Q₄ may be each independently C or N.

In Formula D-1, C1 to C4 may be each independently a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may be each independently a direct linkage,

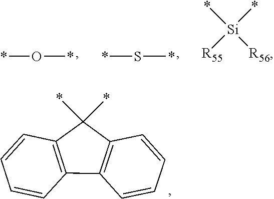

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “___* ” means a part connected with C1 to C4.

In Formula D-1, b1 to b3 may be each independently 0 or 1. If b1 is 0, C1 and C2 may not be connected with each other. If b2 is 0, C2 and C3 may not be connected with each other. If b3 is 0, C3 and C4 may not be connected with each other.

In Formula D-1, R₅₁ to R₅₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. Otherwise, each of R₅₁ to R₅₆ may be combined with an adjacent group from each other to form a ring. R₅₁ to R₅₆ may be each independently a substituted or unsubstituted methyl group or a substituted or unsubstituted t-butyl group.

In Formula D-1, d1 to d4 may be each independently an integer of 0 to 4. In Formula D-1, if d1 to d4 are 0, the fourth compound may be unsubstituted with R₅₁ to R₅₄. Cases where d1 to d4 are 4, and R₅₁ to R₅₄ are hydrogen atoms, may be the same as cases where d1 to d4 are integers of 0, respectively. If d1 to d4 are integers of 2 or more, each of a plurality of R₅₁ to R₅₄ may be all the same, or at least one selected from among a plurality of R₅₁ to R₅₄ may be different.

In Formula D-1, C1 to C4 may be each independently a substituted or unsubstituted hydrocarbon ring or a substituted or unsubstituted heterocycle, represented by any one selected from among C-1 to C-4.

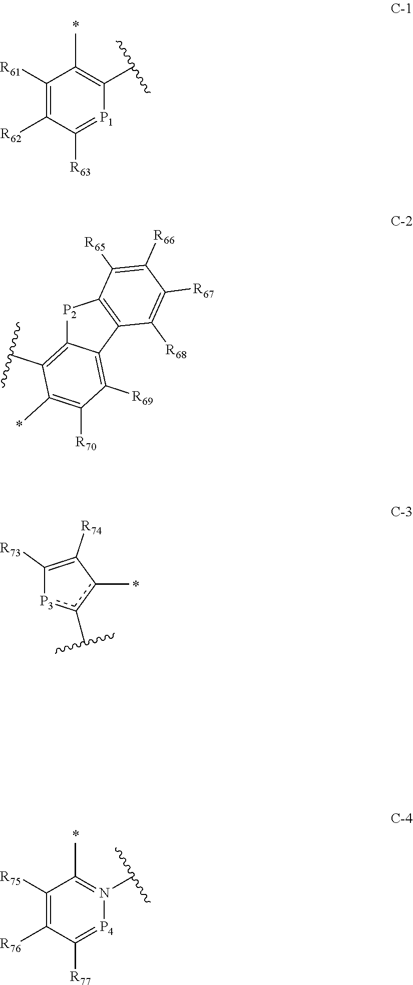

In C-1 to C-4, P₁ may be C—* or CR₆₄, P₂ may be N—* or NR₇₁, P₃ may be N—* or NR₇₂, and P₄ may be C—* or CR₇₈. R₆₁ to R₇₈ may be each independently a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In addition, in C-1 to C-4,

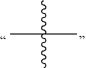

is a part connected with a central metal element of Pt, and “—*” corresponds to a part connected with an adjacent ring group (C1 to C4) or a linker (L₁₁ to L₁₃).

At least one selected from among the compounds in Compound Group 3 may be included. For example, the phosphorescence sensitizer may include Compound AD-05. However, this is only an illustration, and an embodiment of the present disclosure is not limited thereto.

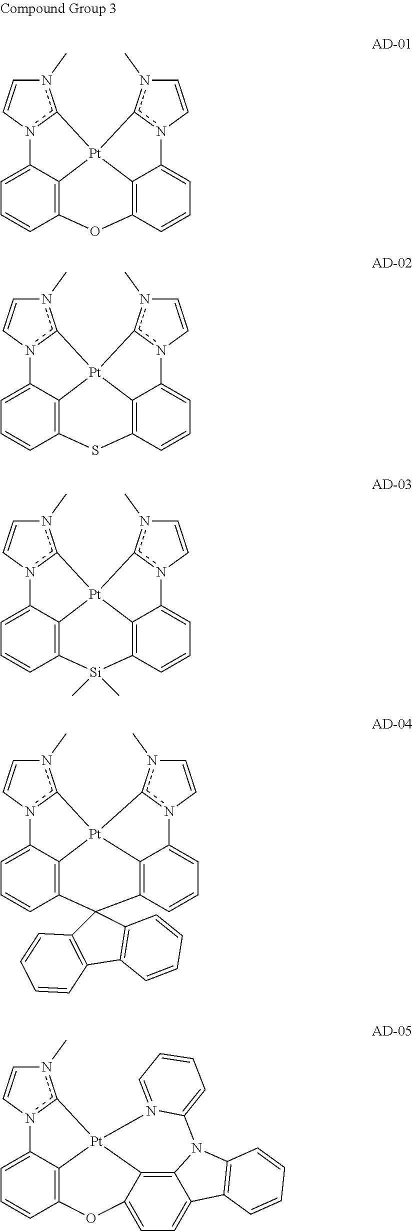

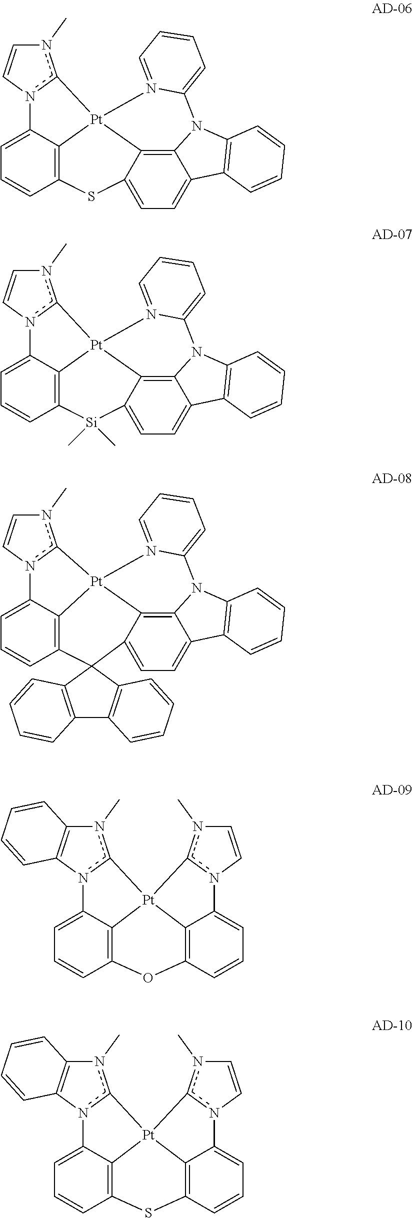

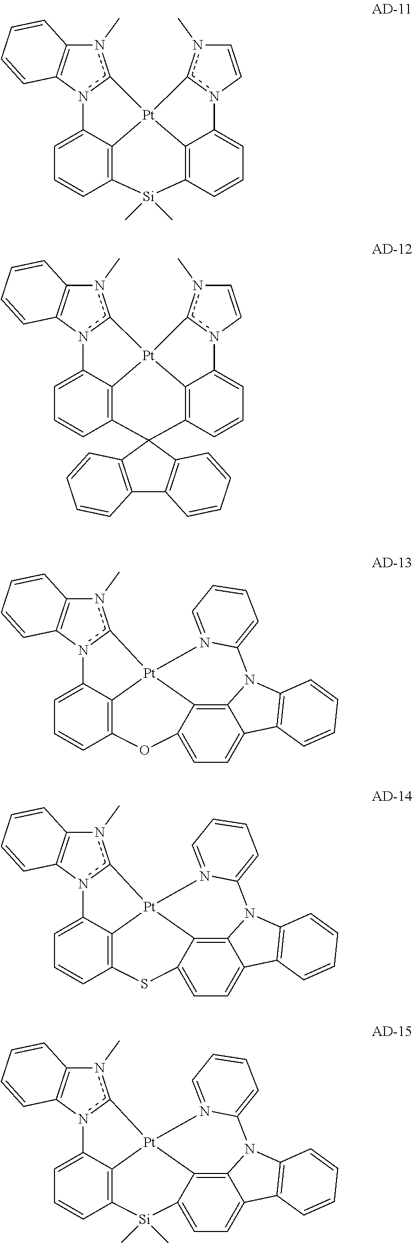

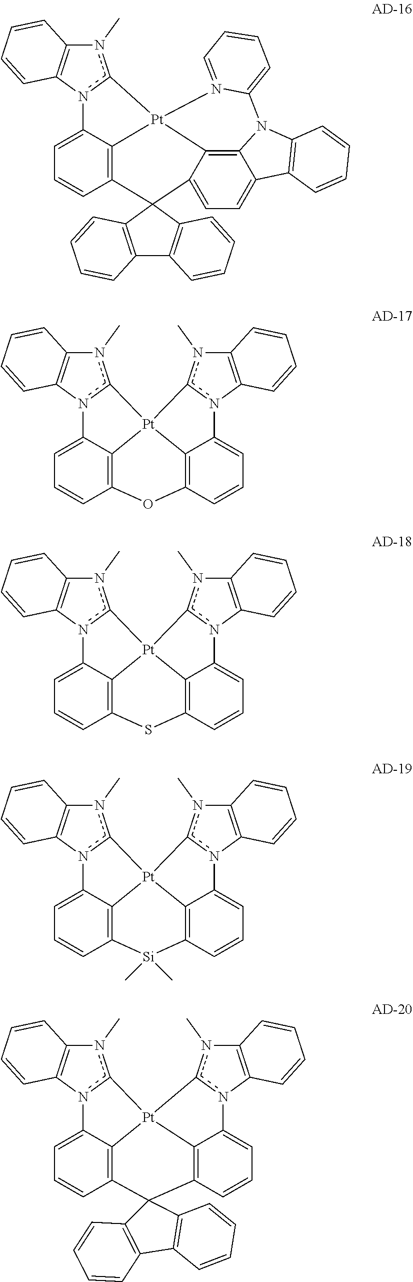

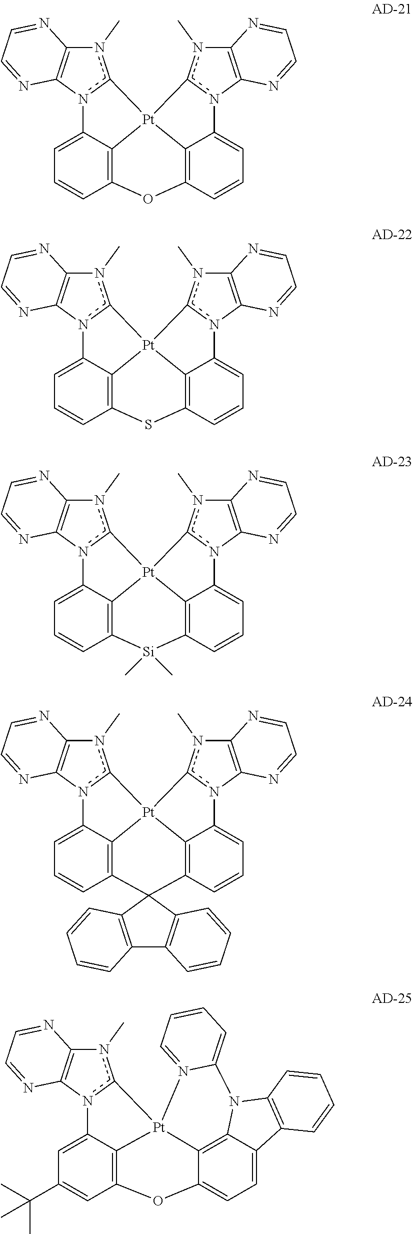

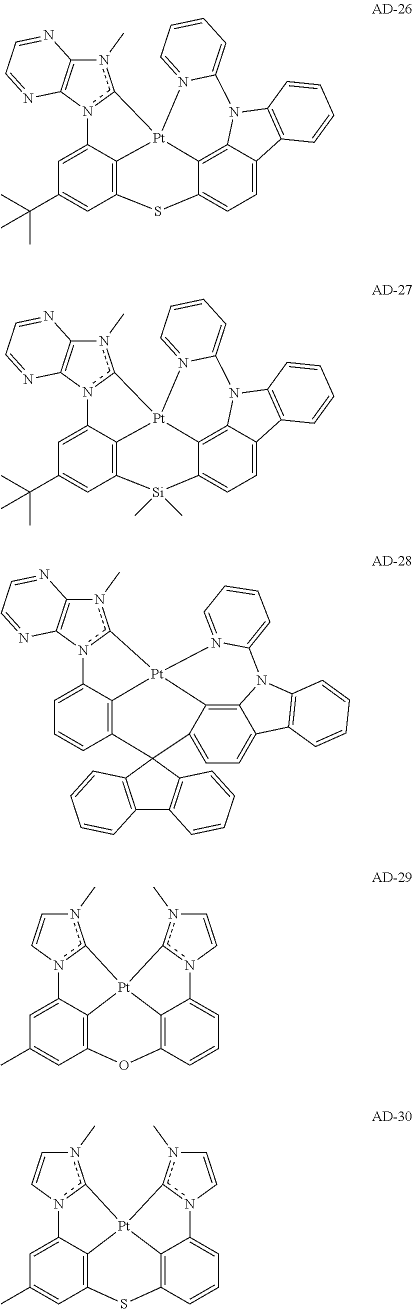

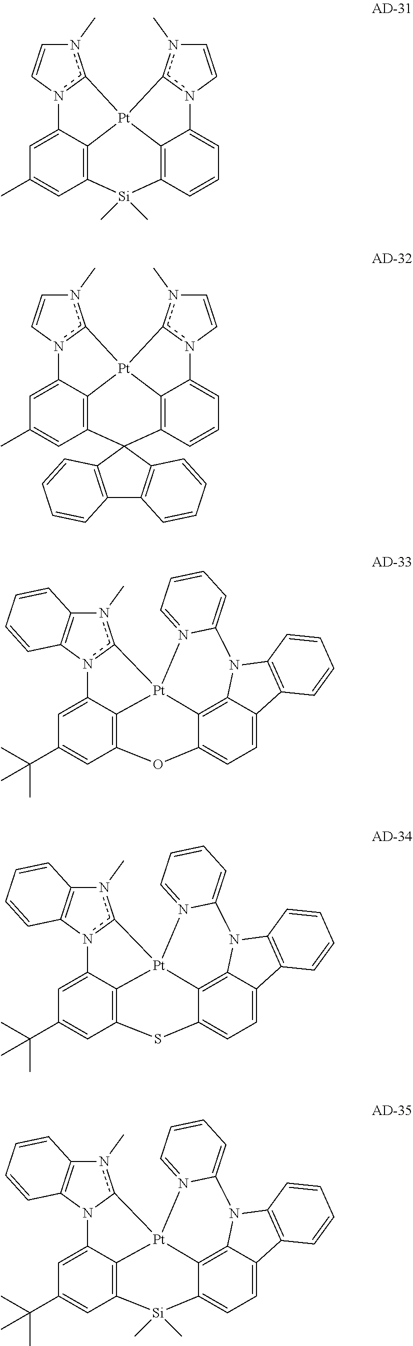

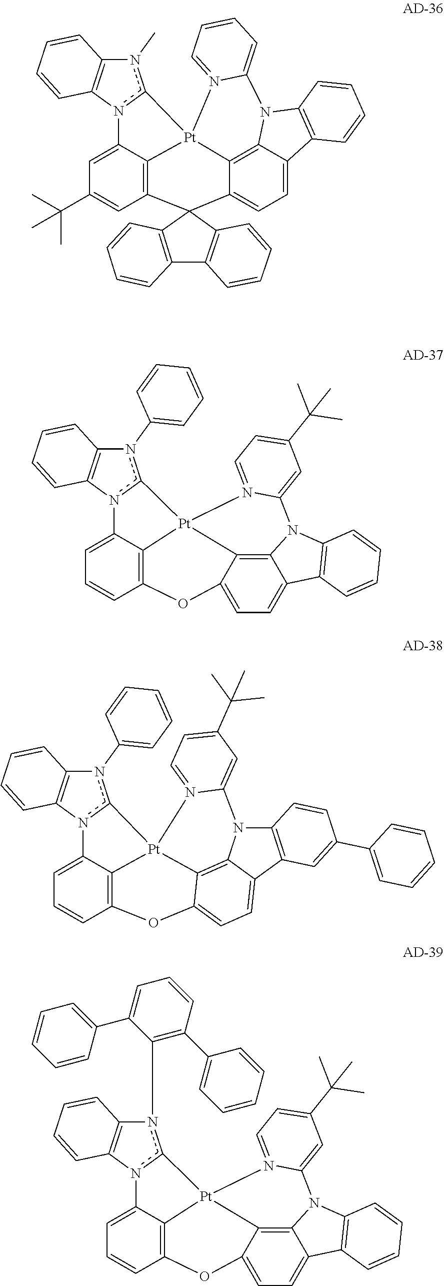

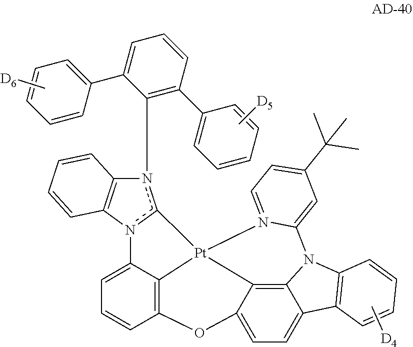

In the compounds included in Compound Group 3, “D” means a deuterium atom.

The first fluorescence dopant may receive energy from the phosphorescence sensitizer and emit fluorescence. The first fluorescence dopant may have a HOMO energy level of about −5.2 eV or less. For example, the HOMO energy level of the first fluorescence dopant may be about −5.3 eV. Because the first fluorescence dopant has the HOMO energy level of about −5.2 eV or less, energy transfer from the phosphorescence sensitizer to the first fluorescence dopant may occur easily. In addition, the first fluorescence dopant may show thermally activated delayed fluorescence (TADF) properties. Hole trap to or at the first fluorescence dopant may be suppressed or reduced, and the device lifetime may be improved.

The first fluorescence dopant may include a bulky substituent having a large volume. Because the first fluorescence dopant includes the bulky substituent having a large volume, dexter energy transfer may be prevented or reduced, and a light emitting device including the first fluorescence dopant may achieve excellent light efficiency. For example, the first fluorescence dopant may include at least one selected from among the compounds in Compound Group 4. In some embodiments, the first fluorescence dopant may include Compound D-13. However, this is only an illustration, and an embodiment of the present disclosure is not limited thereto.

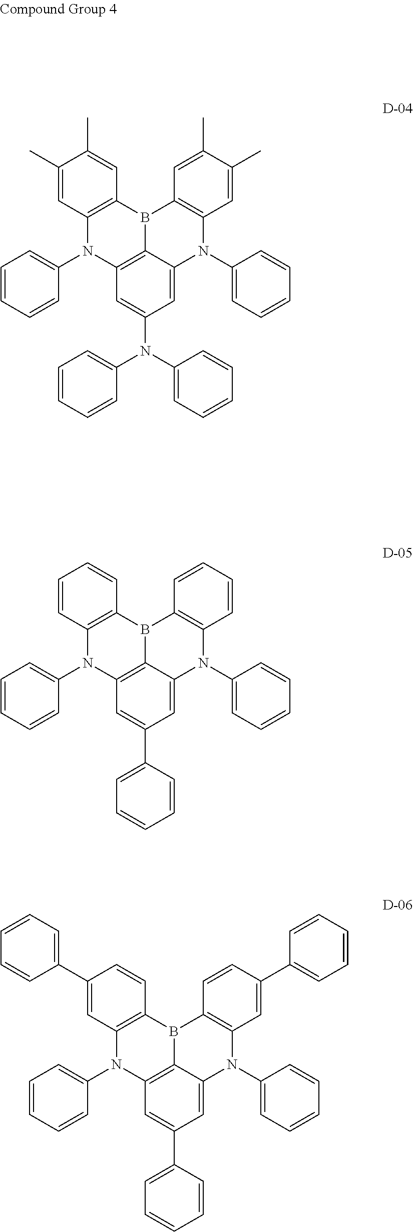 [SMILES: Cc1cc2c(cc1C)N(c1ccccc1)c1cc(N(c3ccccc3)c3ccccc3)cc3c1B2c1cc(C)c(C)cc1N3c1ccccc1 ; c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1]

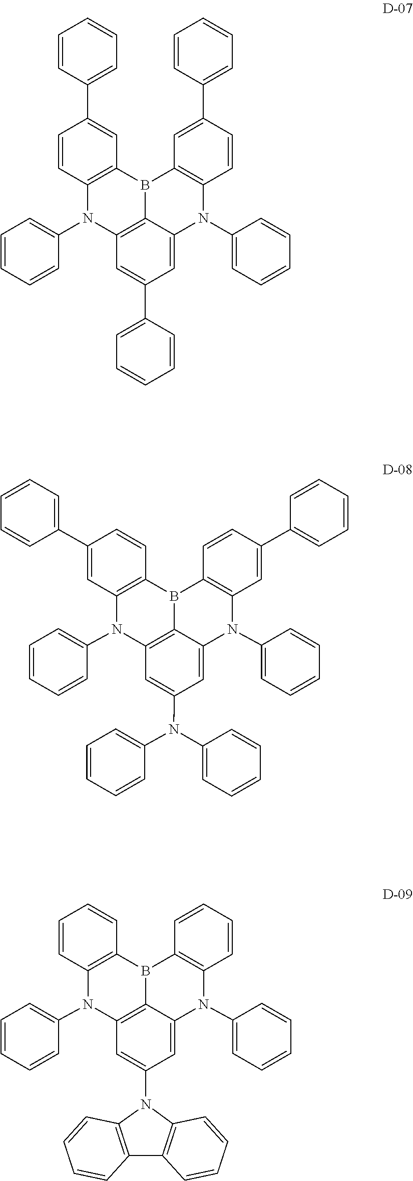 [SMILES: c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1 ; c1ccc(N2c3ccccc3B3c4ccccc4N(c4ccccc4)c4cc(-n5c6ccccc6c6ccccc65)cc2c43)cc1]

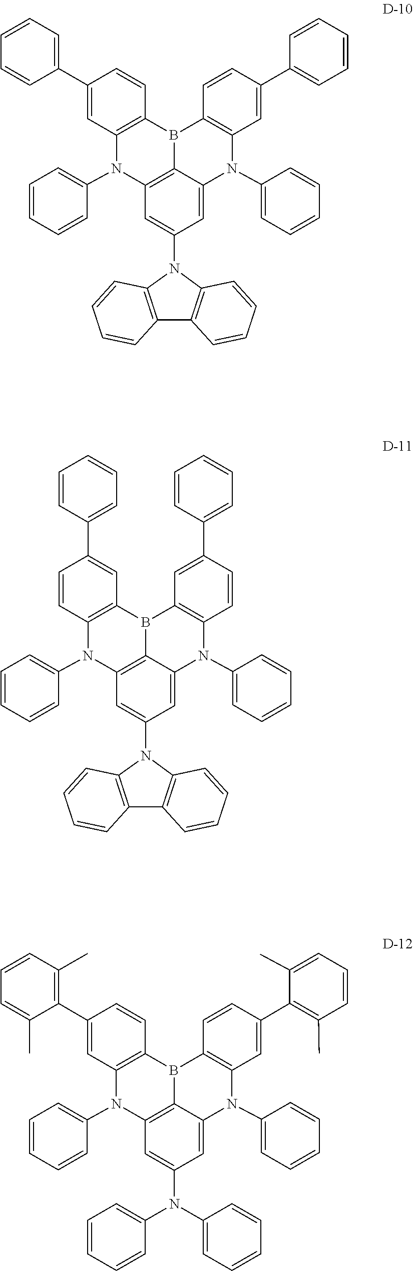 [SMILES: c1ccc(-c2ccc3c(c2)N(c2ccccc2)c2cc(-n4c5ccccc5c5ccccc54)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1]

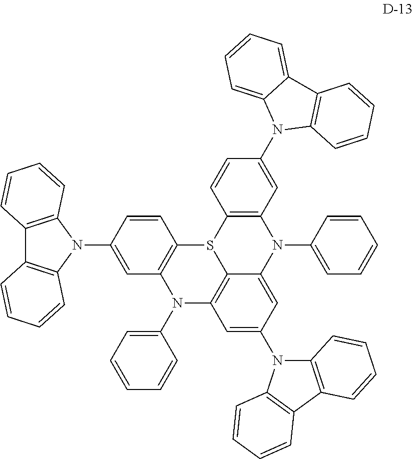

The first fluorescence dopant may have a molar extinction coefficient of about 2×10⁵ Mcm⁻¹ or more. In cases where the first fluorescence dopant has a molar extinction coefficient of about 2×10⁵ Mcm⁻¹ or more, Förster energy transfer from the phosphorescence sensitizer to the first fluorescence dopant may be improved or increased, an device lifetime may be increased.

In addition, the energy level (T1_{P}) of the triplet state of the phosphorescence sensitizer and the energy level (T1_{F1}) of the triplet state of the first fluorescence dopant may satisfy Equation 1 below. If the energy level (T1_{P}) of the triplet state of the phosphorescence sensitizer and the energy level (T1_{F1}) of the triplet state of the first fluorescence dopant satisfy Equation 1, Förster energy transfer from the phosphorescence sensitizer to the first fluorescence dopant may occur easily.

T1_{P}≥T1_{F1}−0.02 eV Equation 1

The second emission layer EML2 may include a second host, and a second fluorescence dopant. In the second emission layer EML2, direct energy transfer from the second host to the second fluorescence dopant may occur. The second emission layer EML2 may emit fluorescence. The second emission layer EML2 may emit blue light.

The second host may include an anthracene-based compound. For example, at least one selected from among the compounds in Compound Group 5 may be included. In some embodiments, the second host may include Compound E1. However, this is only an illustration, and an embodiment of the present disclosure is not limited thereto.

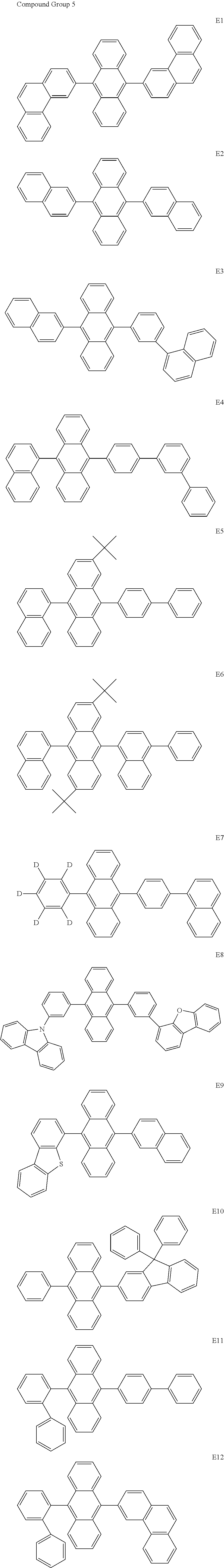

The second fluorescence dopant may be different from the first fluorescence dopant. The second fluorescence dopant may have a HOMO energy level of about −5.2 eV or more. For example, the HOMO energy level of the second fluorescence dopant may be about −5.1 eV.

The second fluorescence dopant may include a compound containing boron. For example, at least one selected from among the compounds in Compound Group 4 may be included. However, this is only an illustration, and an embodiment of the present disclosure is not limited thereto. In an embodiment, the second fluorescence dopant may include at least one selected from among the compounds in Compound Group 5.

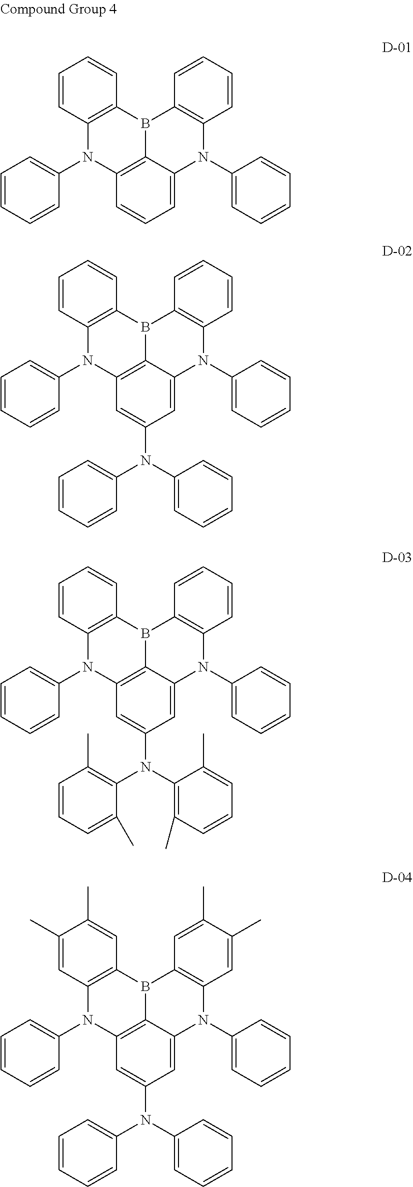

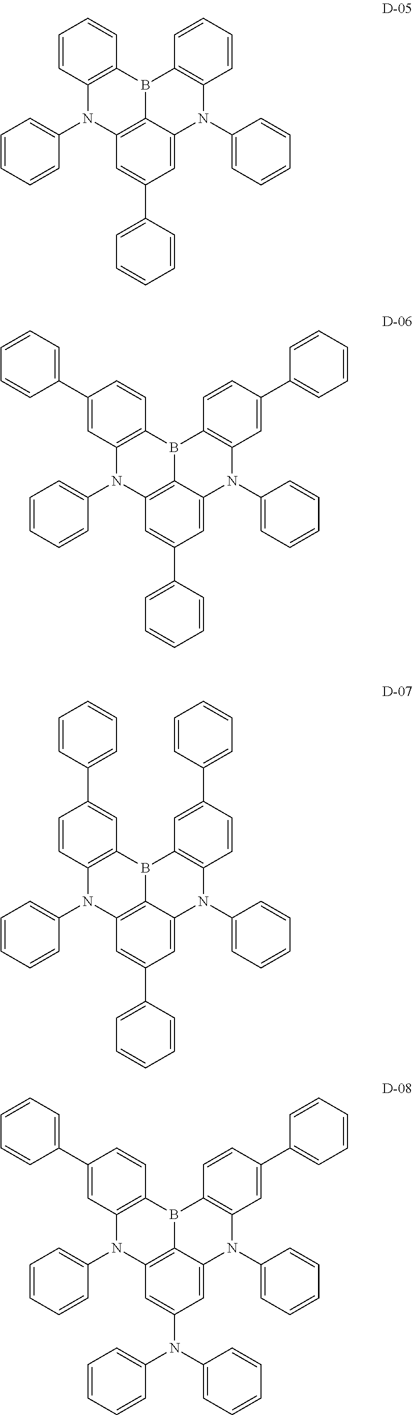 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1]

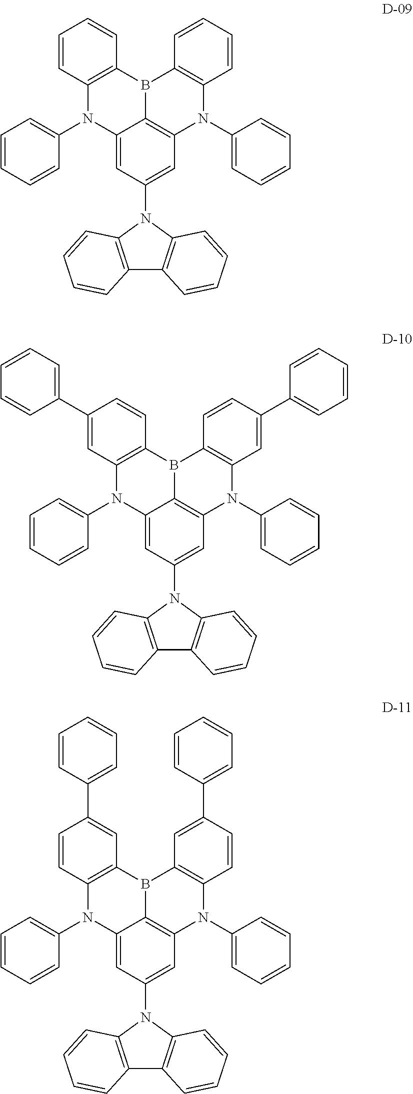

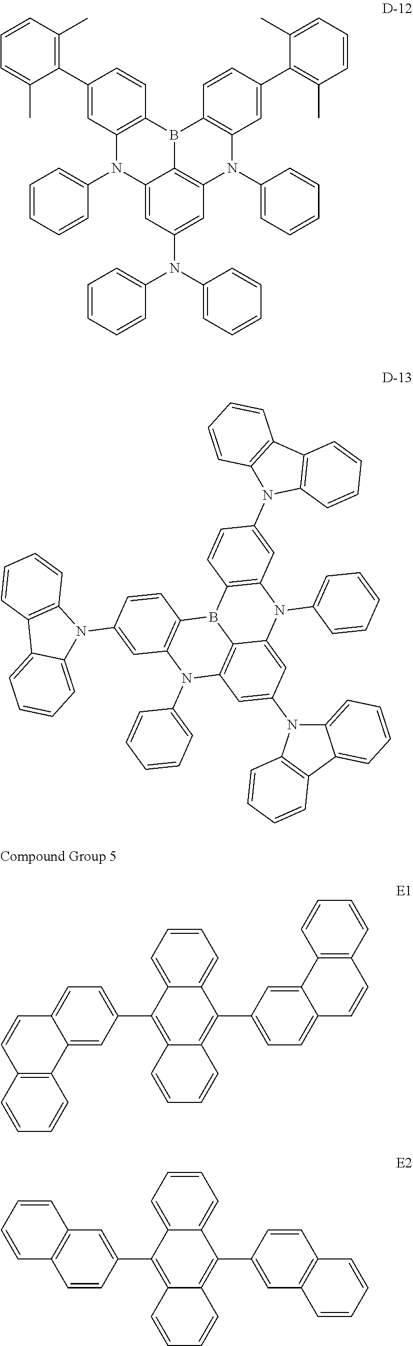

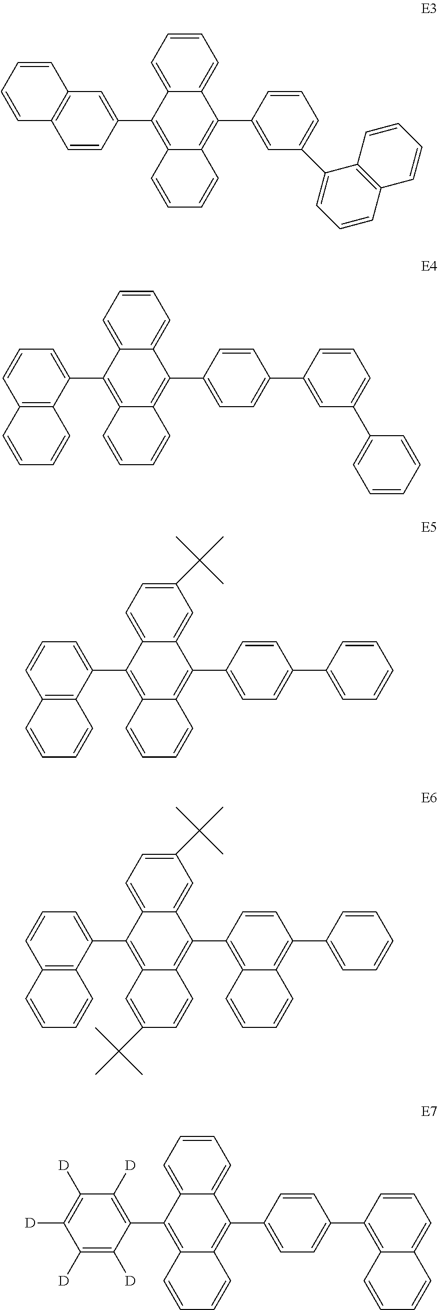

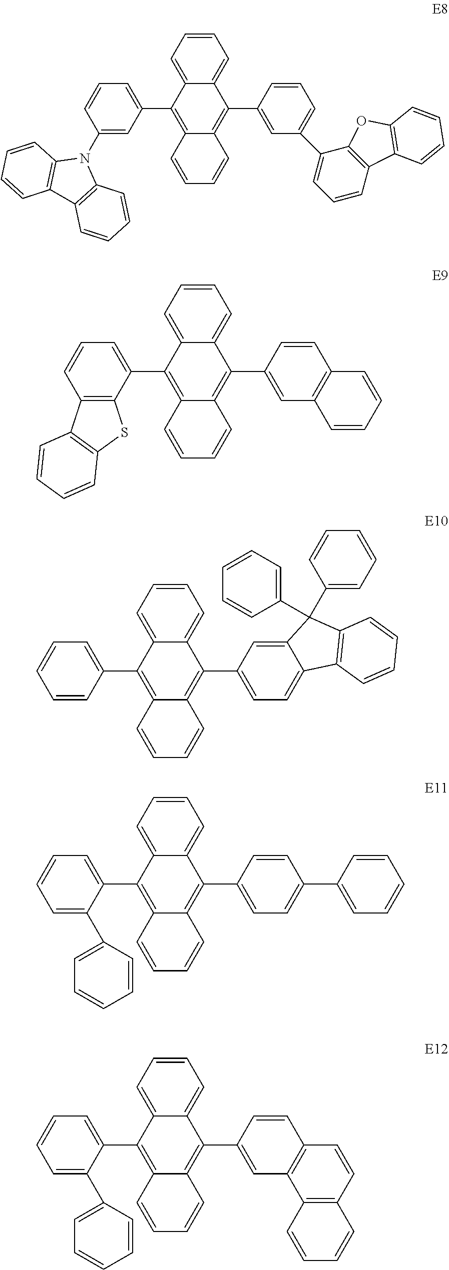

In the light emitting device ED, the emission layers EML1 and EML2 may further include any suitable hosts and dopants generally used in the art in addition to the above-described host and dopant. In some embodiments, the emission layers EML1 and EML2 may include a compound represented by Formula E-1 below. The compound represented by Formula E-1 below may be used as a fluorescence dopant material.

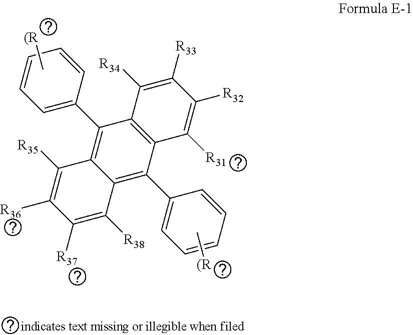

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may be each independently an integer of 0 to 5.

Formula E-1 may be represented by any one selected from among Compound E1 to Compound E19 below.

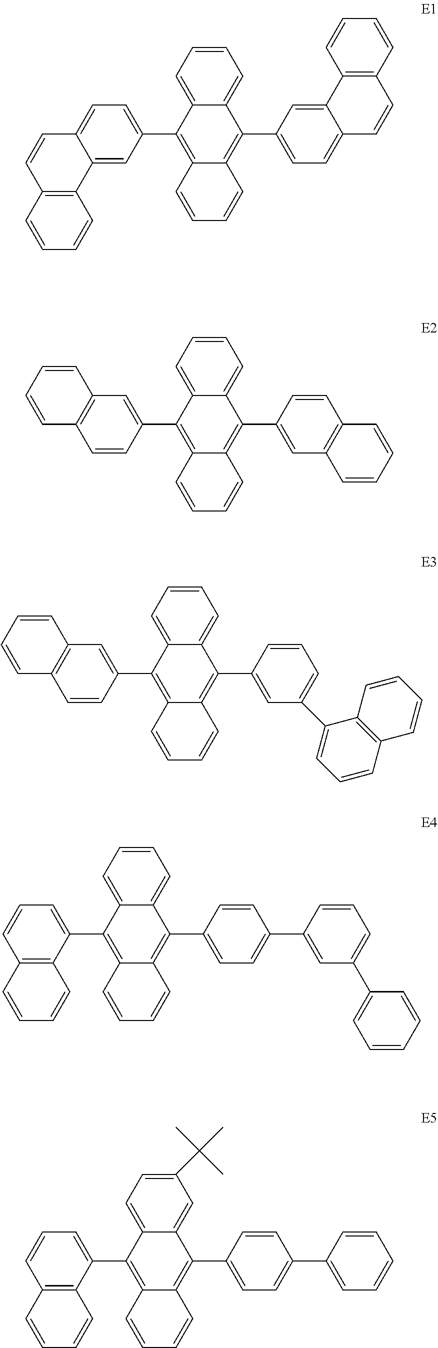

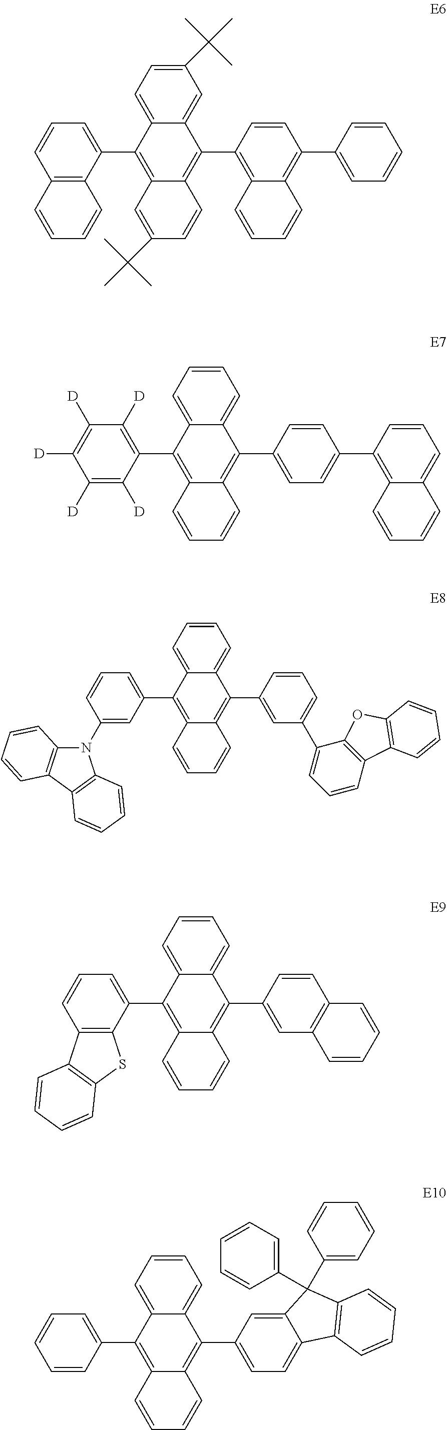

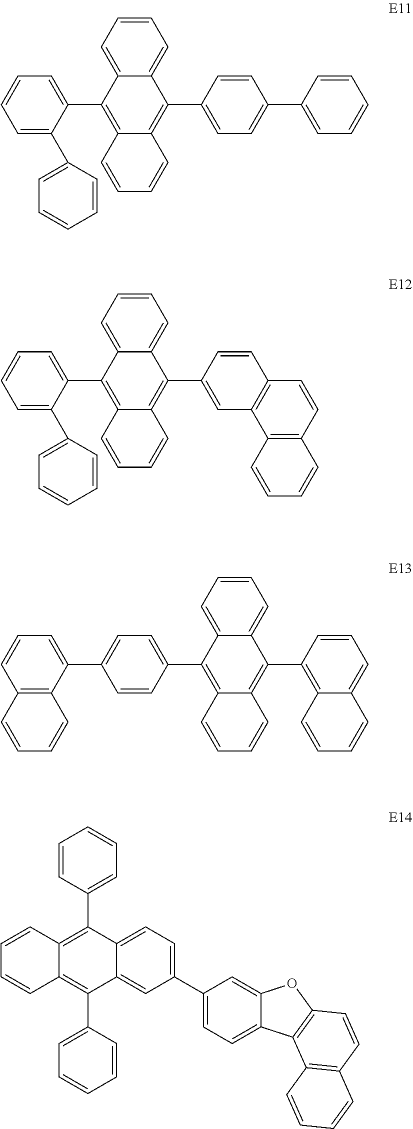

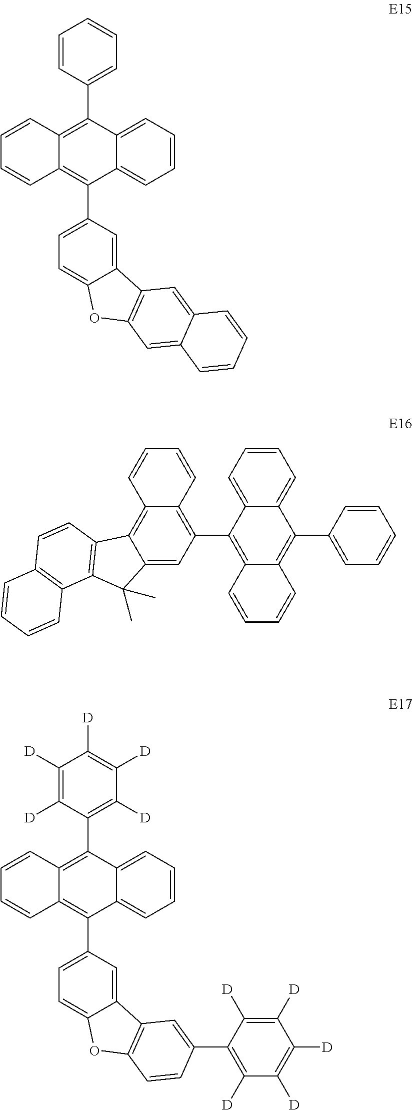

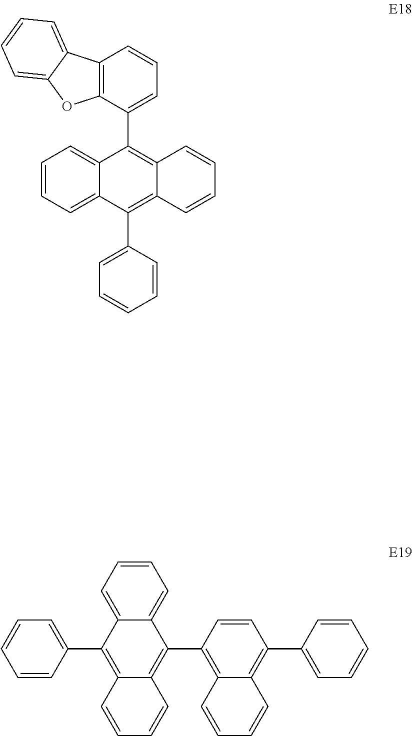

In an embodiment, the emission layers EML1 and EMI-2 may include a compound represented by Formula E-2a or Formula E-2b below. The compound represented by Formula E-2a or Formula E-2b may be used as a phosphorescence host material.

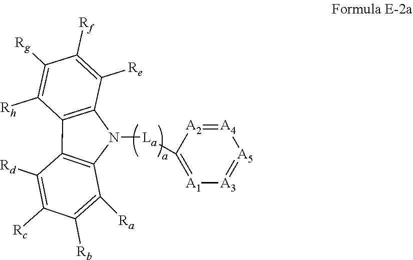

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. If “a” is an integer of 2 or more, a plurality of La may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A1 to A5 may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as ring-forming atoms.

In Formula E-2a, two or three selected from A1 to A5 may be N, and the remainder may be CRᵢ.

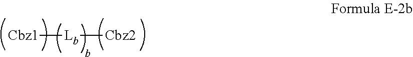

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2 below. However, the compounds listed in Compound Group E-2 below are only illustrations, and the compound represented by Formula E-2a or Formula E-2b is not limited to the compounds represented in Compound Group E-2 below.

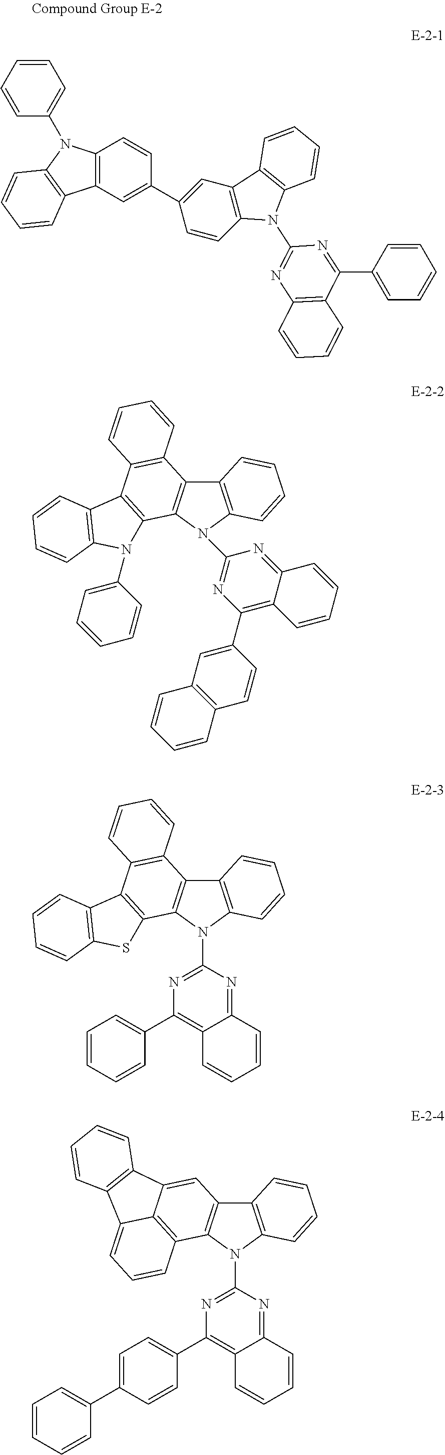 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

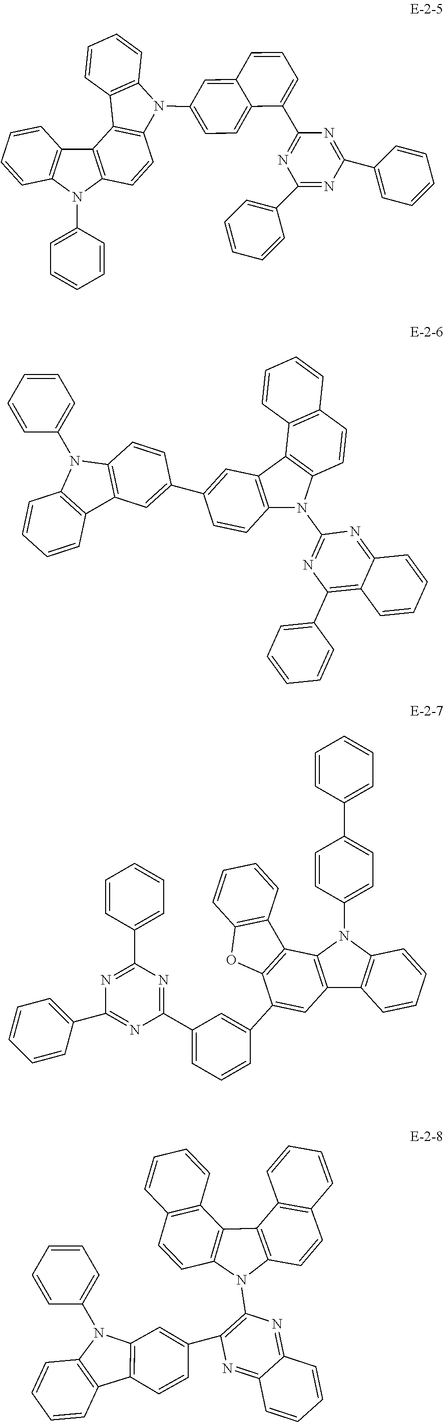 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

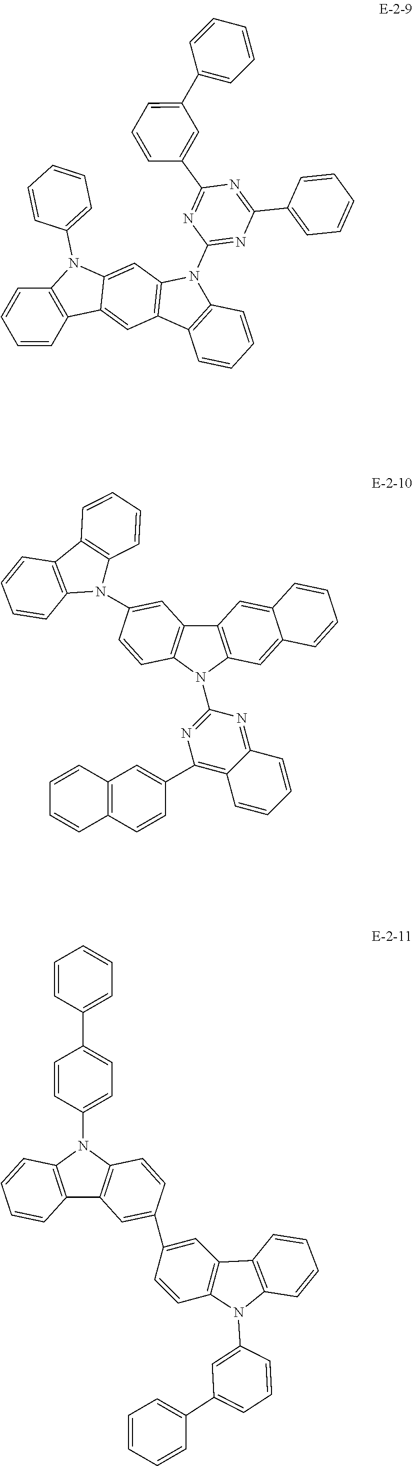 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

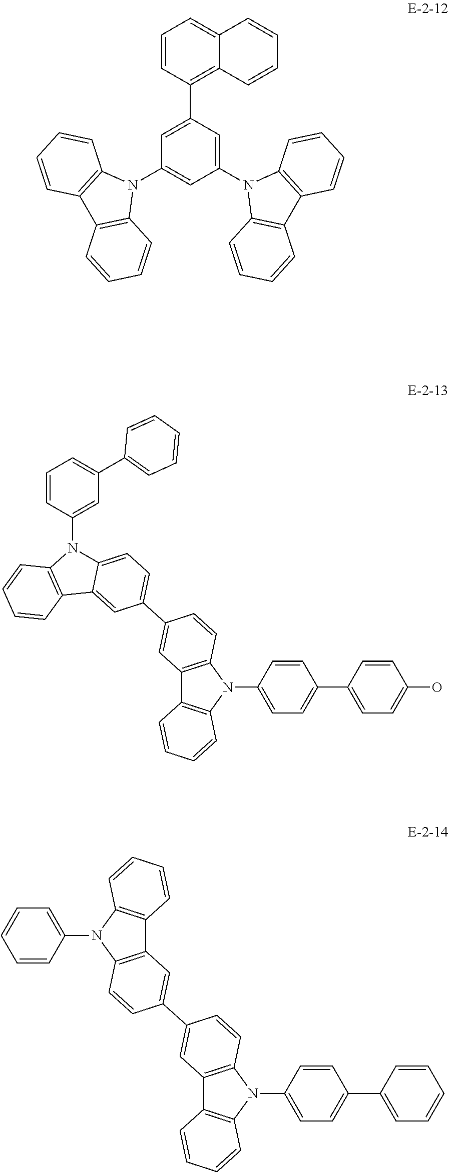 [SMILES: c1ccc2c(-c3cc(-n4c5ccccc5c5ccccc54)cc(-n4c5ccccc5c5ccccc54)c3)cccc2c1 ; Oc1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1]

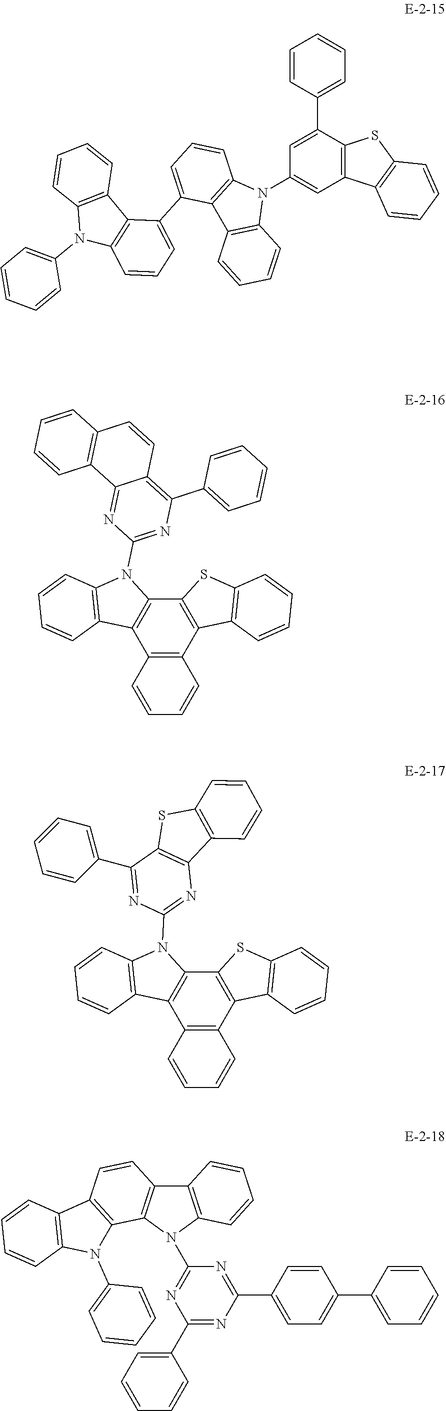 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

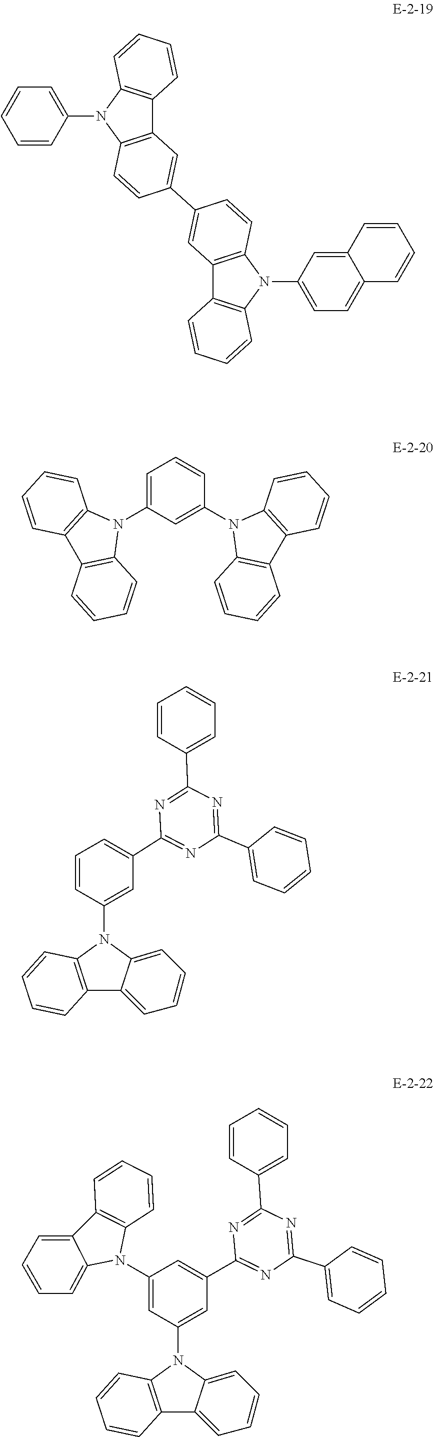 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

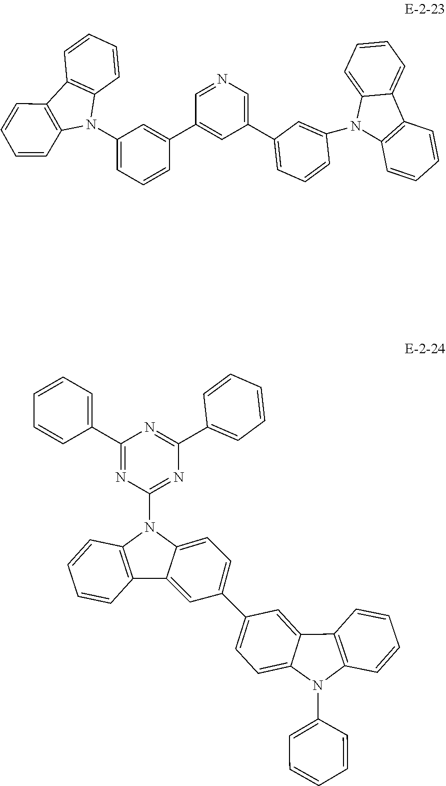 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layers EML1 and EML-2 may further include any suitable material generally used in the art as a host material. In some embodiments, the emission layers EML1 and EML-2 may include as a host material, at least one selected from bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layers EML1 and EML2 may include a compound represented by Formula M-a. The compound represented by Formula M-a may be used as a phosphorescence dopant material.

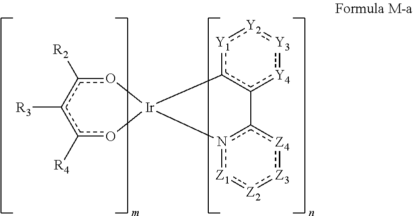

In Formula M-a, Y₁ to Y₄, and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” may be 0 or 1, and “n” may be 2 or 3. In Formula M-a, if “m” is 0, “n” may be 3, and if “m” is 1, “n” may be 2.

The compound represented by Formula M-a may be used as a phosphorescence dopant.

The compound represented by Formula M-a may be represented by any one selected from among Compounds M-a1 to M-a25 below. However, Compounds M-a1 to M-a25 are illustrations, and the compound represented by Formula M-a is not limited to those represented by Compounds M-a1 to M-a25 below.

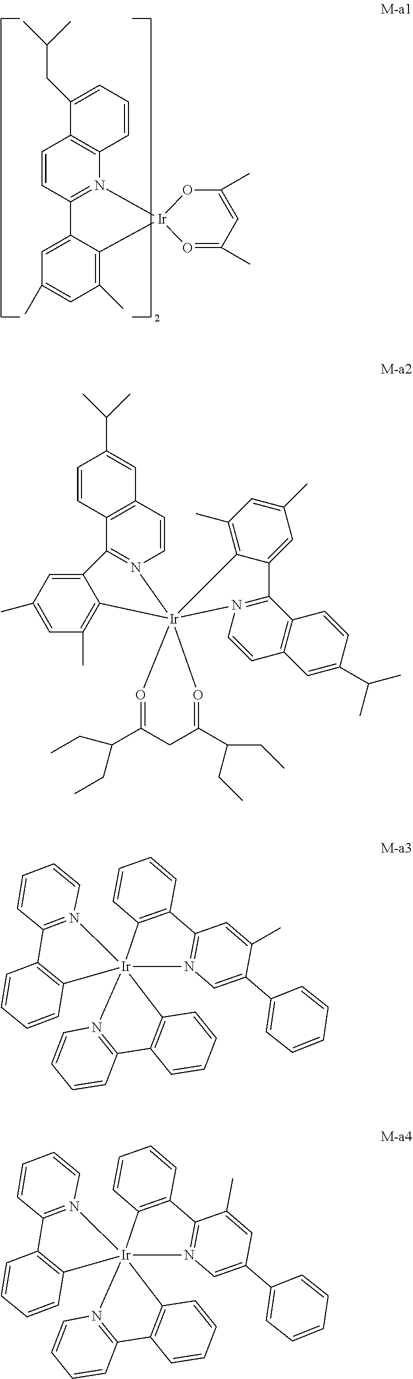

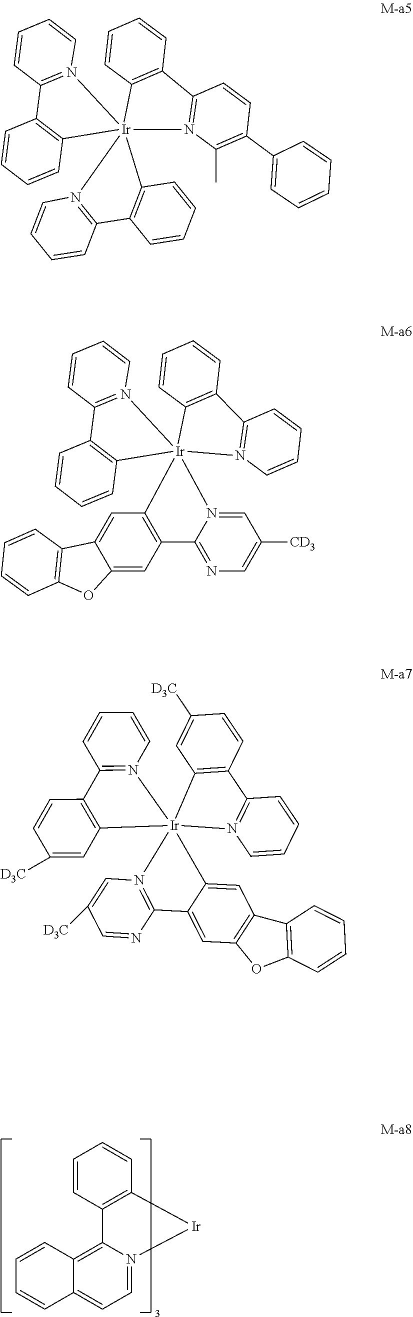

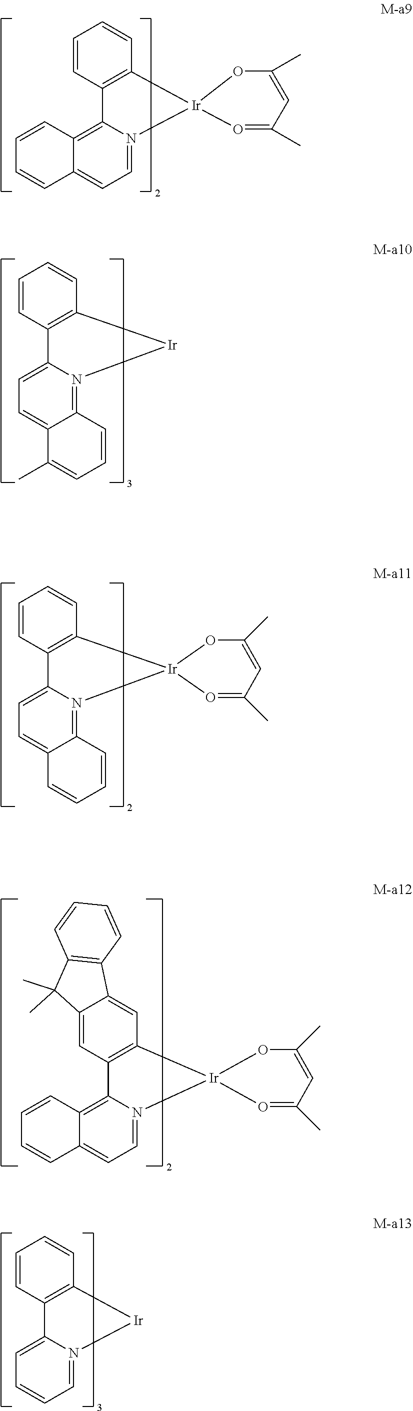

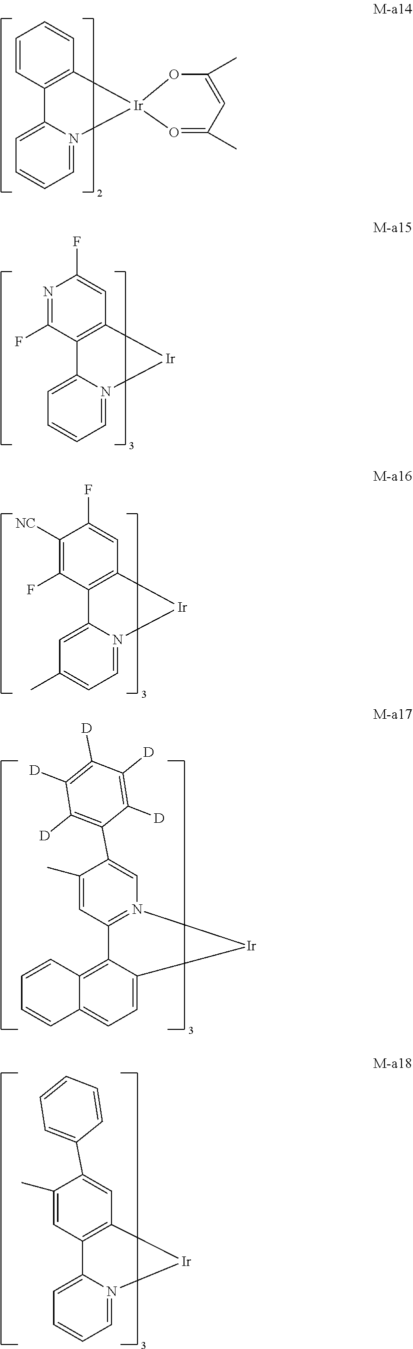

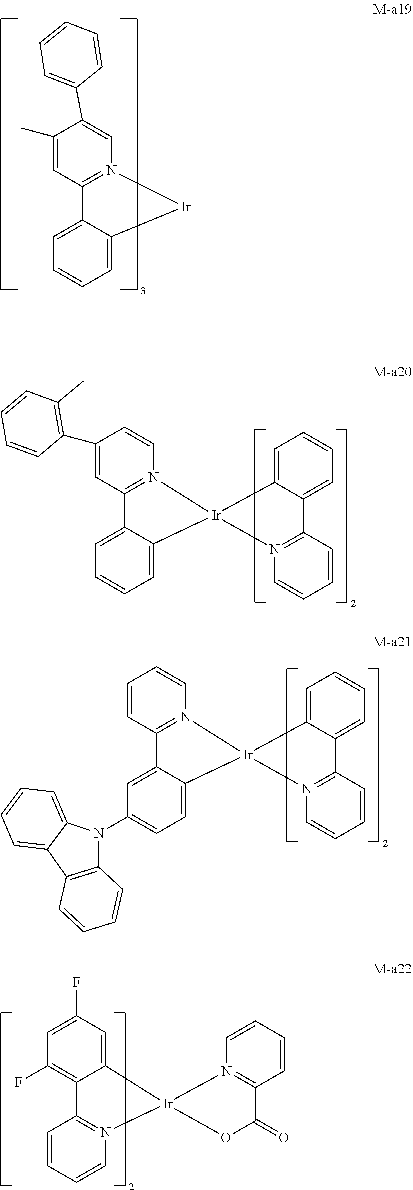

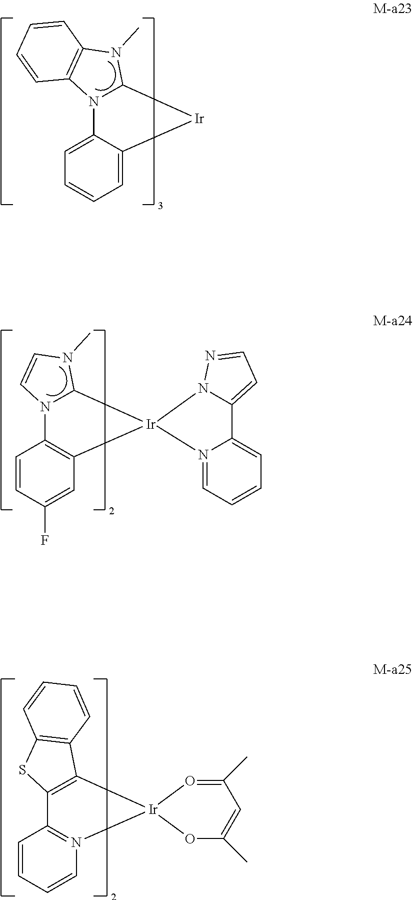

The emission layers EML1 and EML2 may include a compound represented by any one selected from among Formula F-a to Formula F-c below. The compounds represented by Formula F-a to Formula F-c may be used as fluorescence dopant materials.

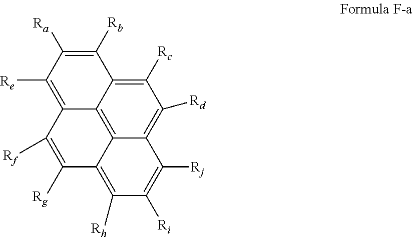

In Formula F-a, two selected from Rₐ to Rⱼ may be each independently substituted with *—NAr₁Ar₂. The remainder not substituted with *—NAr₁Ar₂ selected from among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

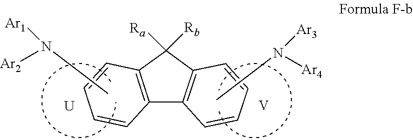

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. At least one selected from among Ar₁ to Ar₄ may be a heteroaryl group containing O or S as a ring-forming heteroatom.

In Formula F-b, the number of rings represented by U and V may be each independently 0 or 1. For example, in Formula F-b, if the number of U or V is 1, one ring forms a fused ring at the designated part by U or V, and if the number of U or V is 0, a ring is not present at the designated part by U or V. In some embodiments, if the number of U is 0, and the number of V is 1, or if the number of U is 1, and the number of V is 0, a fused ring having a fluorene core of Formula F-b may be a ring compound with four rings. In addition, if the number of both U and V is 0, the fused ring having a fluorene core of Formula F-b may be a ring compound with three rings. In addition, if the number of both U and V is 1, a fused ring having a fluorene core of Formula F-b may be a ring compound with five rings.

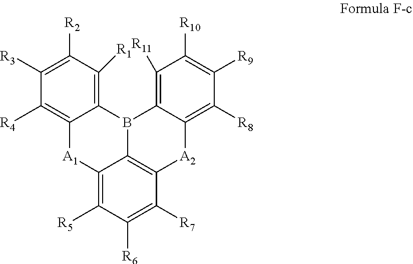

In Formula F-c, A1 and A2 may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may be each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ are each independently NRₘ, A₁ may be combined with R₄ or R₅ to form a ring. In addition, A2 may be combined with R₇ or R₈ to form a ring.

In an embodiment, the emission layers EML1 and EML2 may include as a dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layers EML1 and EML2 may include any suitable phosphorescence dopant material generally used in the art. In some embodiments, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be used as the phosphorescence dopant. However, an embodiment of the present disclosure is not limited thereto.

The emission layers EML1 and EML2 may include a quantum dot material.

In the description, the quantum dot means the crystal of a semiconductor compound. The quantum dot may emit light in various suitable emission wavelengths according to the size of the crystal. The quantum dot may emit light in various suitable emission wavelengths by controlling the element ratio in a quantum dot compound.

The diameter of the quantum dot may be, for example, about 1 nm to about 10 nm.

The quantum dot may be synthesized by a chemical bath deposition, a metal organic chemical vapor deposition, a molecular beam epitaxy and/or any suitable similar process therewith.

The chemical bath deposition is a method of mixing an organic solvent and a precursor material together and then, growing quantum dot particle crystals. During growing the crystals, the organic solvent may naturally play the role of a dispersant that is coordinated with the quantum dot crystal surface, and may control the growth of the crystals. Accordingly, the chemical bath deposition is beneficial or advantageous when compared to the metal organic chemical vapor deposition (MOCVD) or the molecular beam epitaxy (MBE), and may control the growth of quantum dot particles through a low-cost process.

The core of the quantum dot may be selected from II-VI group compounds, III-VI group compounds, I-III-VI group compounds, III-V group compounds, III-II-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-V group compound may include a binary compound such as In₂S₃, and/or In₂Se₃, a ternary compound such as InGaS₃ and/or InGaSe₃, or optional combinations thereof.

The I-III-VI group compound may be selected from a ternary compound selected from the group consisting of AgInS, AgInS₂, CuInS, CulnS₂, AgGaS₂, CuGaS₂, CuGaO₂, AgGaO₂, AgAlO₂ and mixtures thereof, and/or a quaternary compound such as AgInGaS₂ and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound and/or the quaternary compound may be present at a uniform (e.g., substantially uniform) concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell is decreased along a direction toward the center of the core.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal and/or non-metal oxide, a semiconductor compound, or combinations thereof.

For example, the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or, for example, about 30 nm or less. Within this range, color purity and/or color reproducibility may be improved. In addition, light emitted via such quantum dot is emitted in all (e.g., substantially all) directions, and light view angle properties may be improved.

In addition, the shape of the quantum dot may be any suitable shape generally used in the art, without specific limitation. In some embodiments, the shape of spherical, pyramidal, multi-arm, and/or cubic nanoparticle, nanotube, nanowire, nanofiber, nanoplate particle, etc. may be used.

Because an energy band gap may be controlled by controlling the size of the quantum dot and/or by controlling an element ratio in a quantum dot compound, and light in various suitable wavelength bands may be obtained from the quantum dot emission layer. Accordingly, by using such quantum dots (by using quantum dots having different sizes and/or by changing an element ratio in a quantum dot compound), a light emitting device emitting light in many wavelengths may be accomplished. In some embodiments, the control of the size of the quantum dot or the element ratio in the quantum dot compound may be selected to emit red, green and/or blue light. In addition, the quantum dots may be constituted of combined light with various suitable colors to emit white light.

The electron transport region ETR may have a single layer formed using a single material, a single layer formed using a plurality of different materials, or a multilayer structure having a plurality of layers formed using a plurality of different materials.

For example, each of the first electron transport region ETR1 and the second electron transport region ETR2 may have a single layer structure of an electron injection layer EIL1 and EIL2 or an electron transport layer ETL1 and ETL2, or a single layer structure formed using an electron injection material and an electron transport material. Further, each of the first electron transport region ETR1 and the second electron transport region ETR2 may have a single layer structure formed using a plurality of different materials, or a structure stacked in order in a thickness direction of electron transport layer ETL1 and ETL2/electron injection layer EIL1 and EIL2, or hole blocking layer/electron transport layer ETL1 and ETL2/electron injection layer EIL1 and EIL2, without limitation. The thickness of each of the first electron transport region ETR1 and the second electron transport region ETR2 may be, for example, about 1,000 Å to about 1,500 Å.

For example, each of the first electron transport region ETR1 and the second electron transport region ETR2 may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

Each of the first electron transport region ETR1 and the second electron transport region ETR2 may include a compound represented by Formula ET-2.

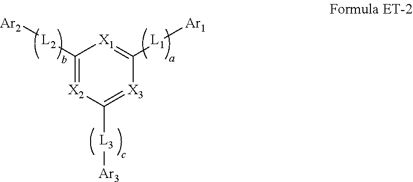

In Formula ET-2, at least one selected from among X₁ to X₃ is N, and the remainder are CRₐ. Rₐ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may be each independently an integer of 0 to 10. In Formula ET-2, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. If “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto. The electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), 1,3-bis[3,5-di(pyridin-3-yl)phenyl]benzene (BmPyPhB), and/or mixtures thereof, without limitation.

Each of the first electron transport region ETR1 and the second electron transport region ETR2 may include at least one selected from among the compounds of ET1 to ET36 below.

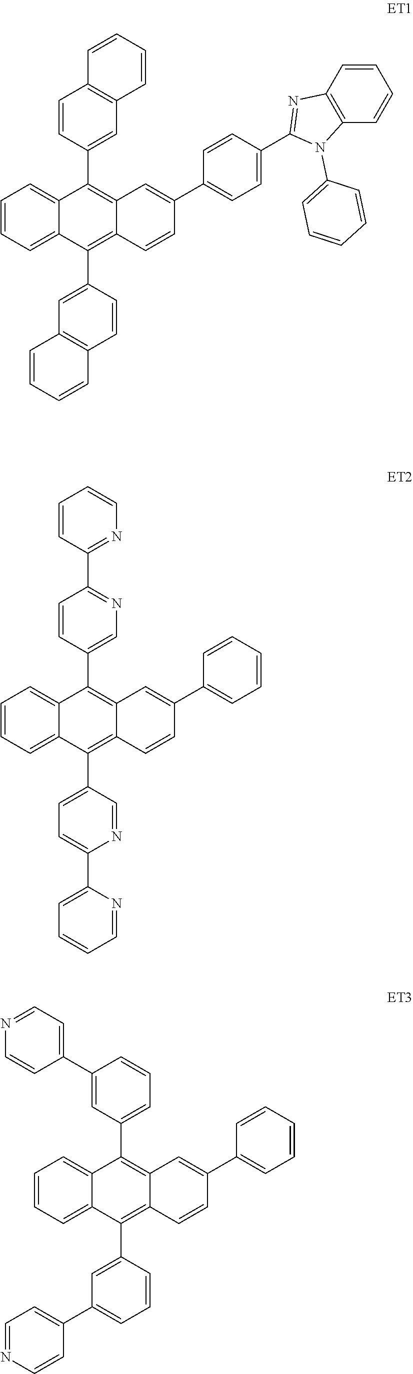 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

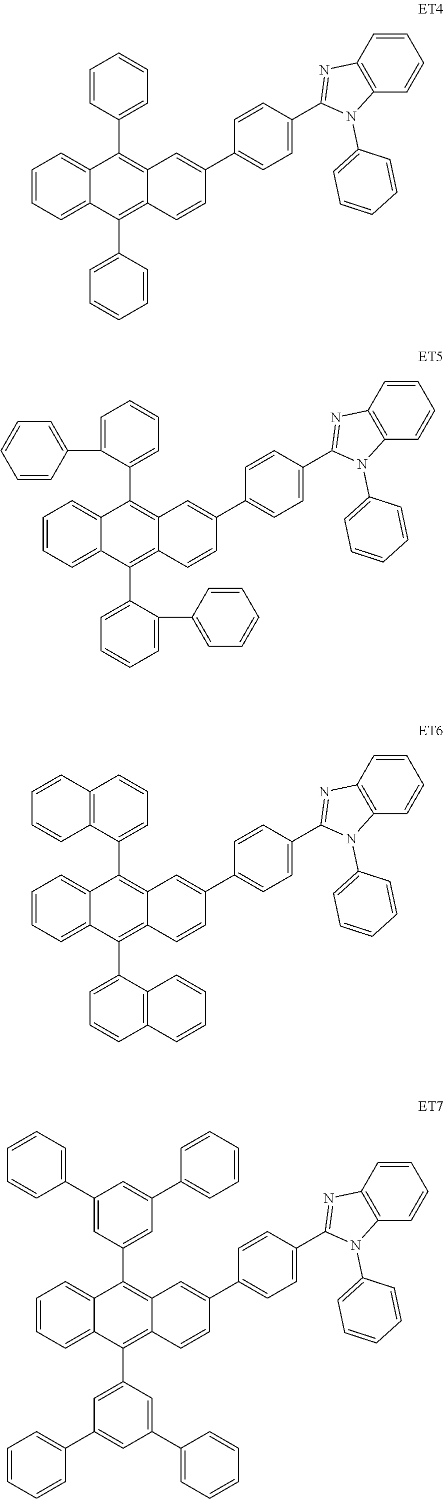 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

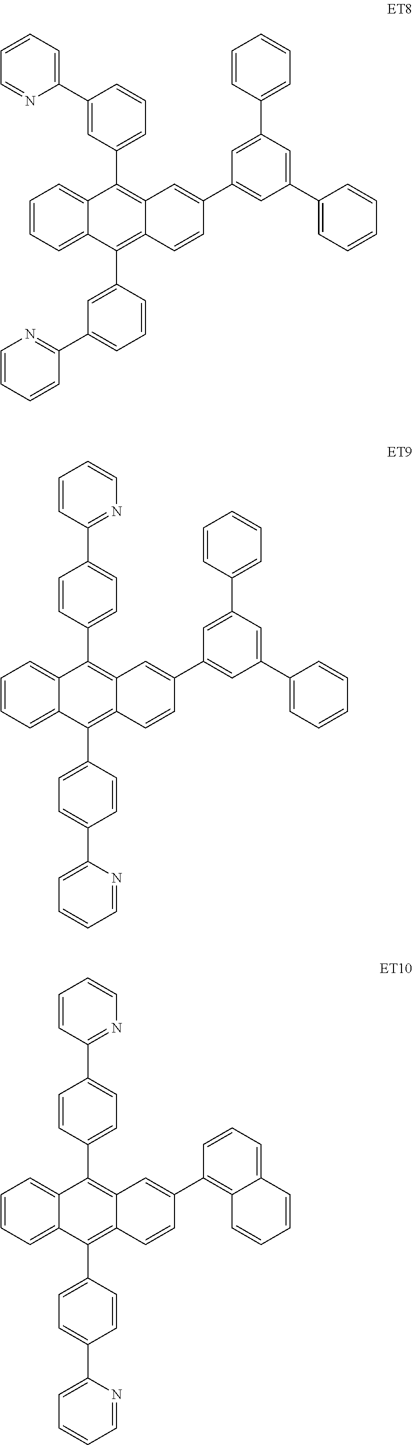 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

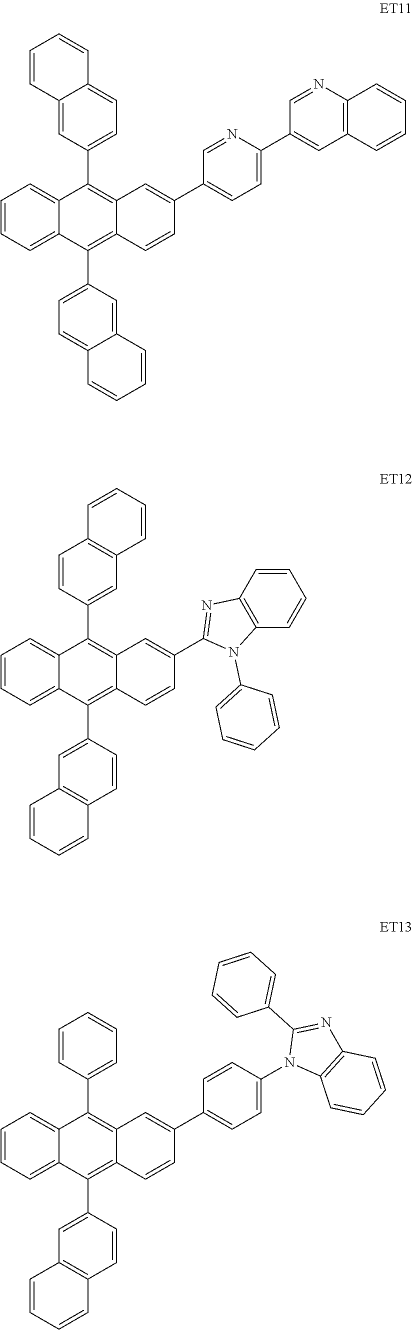 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

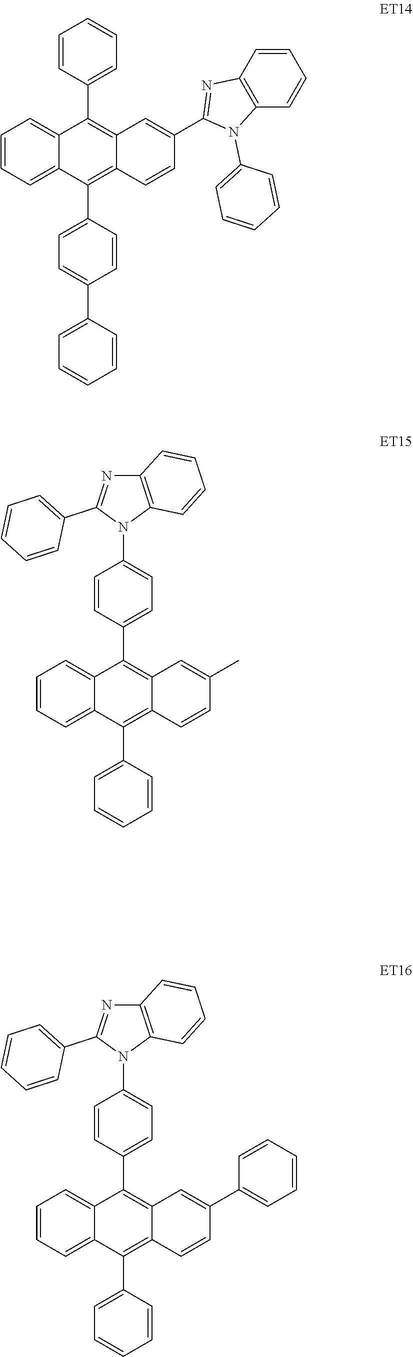 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

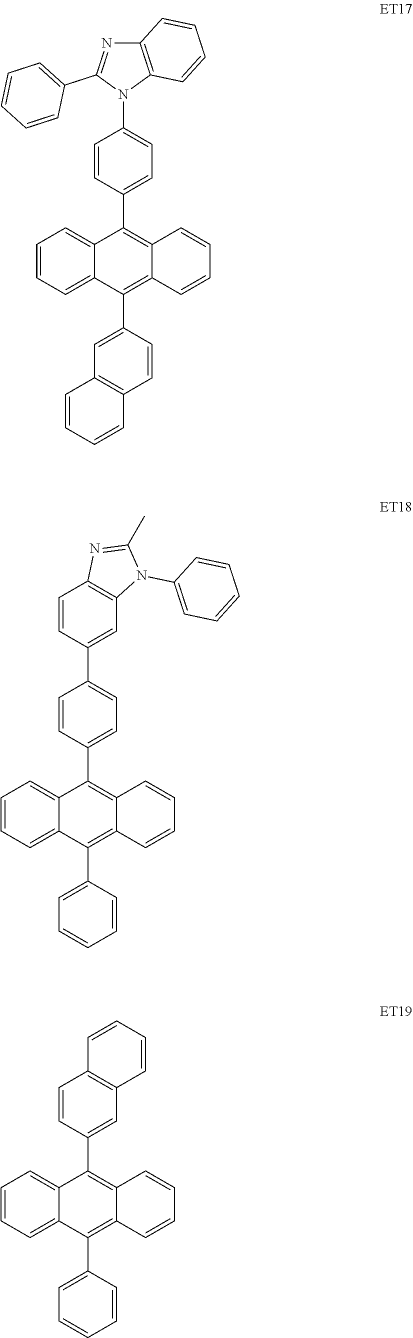

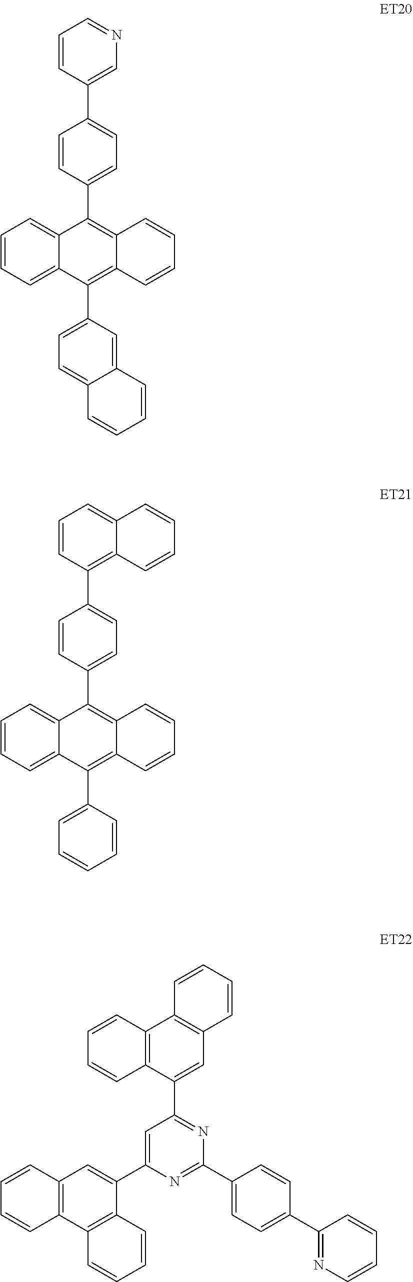

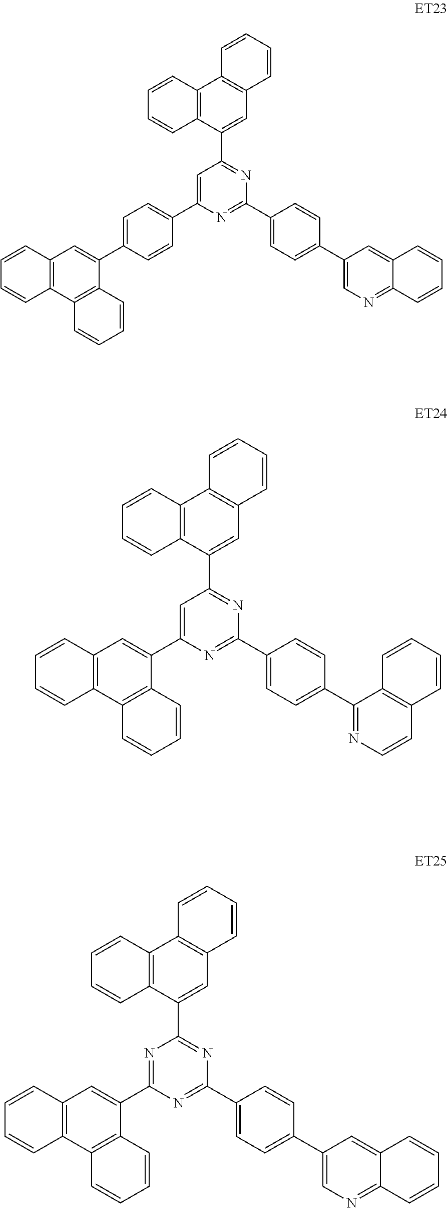 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

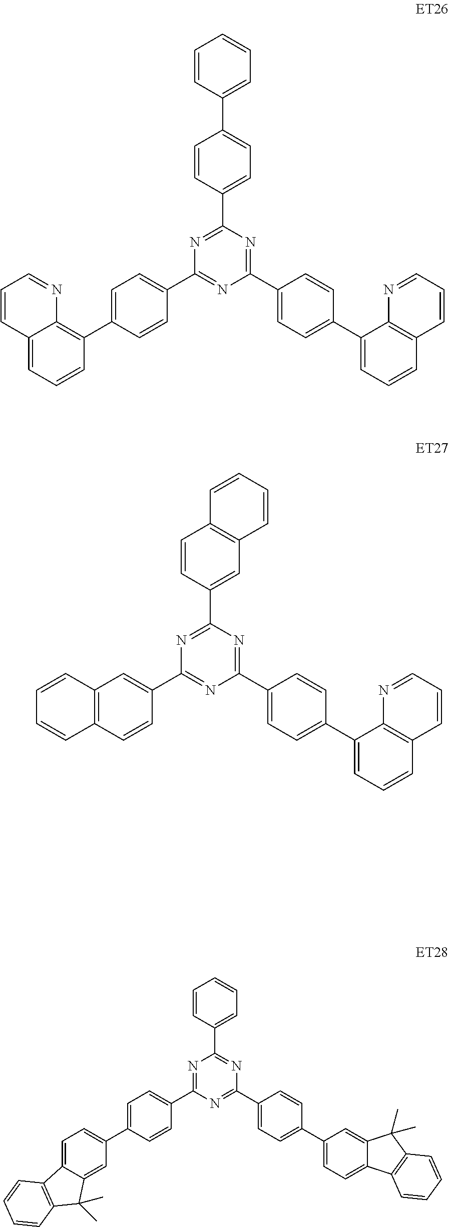 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

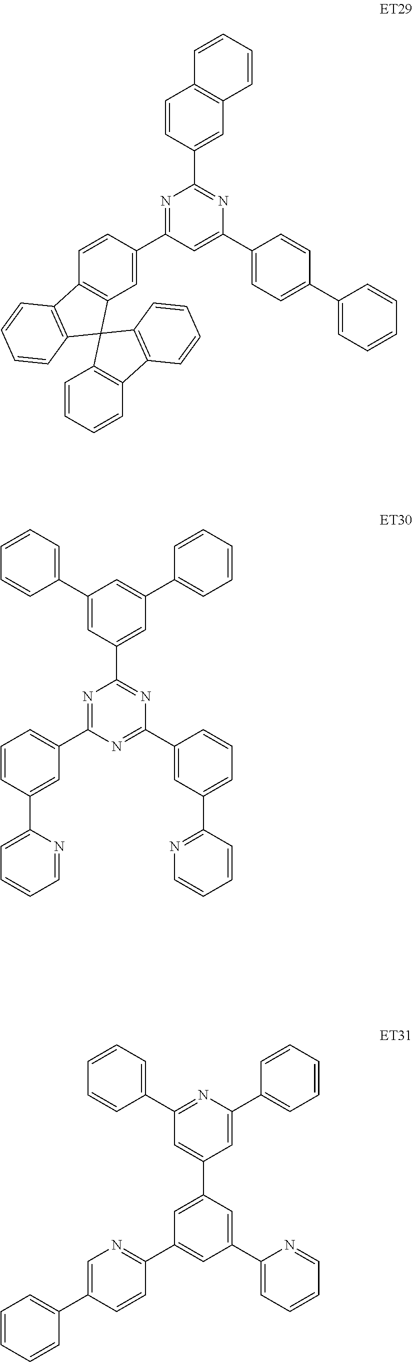 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

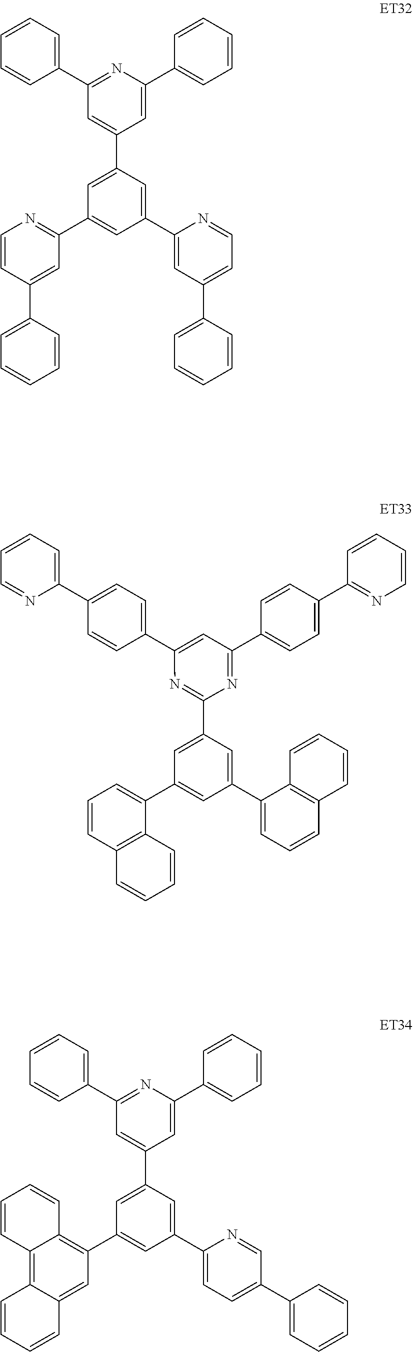 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

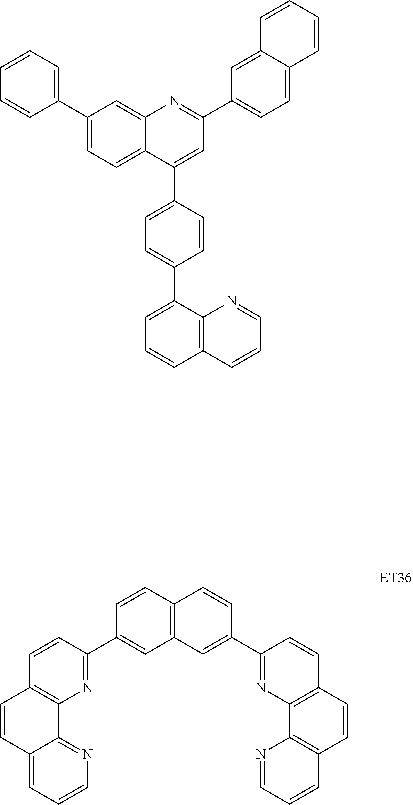 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, each of the first electron transport region ETR1 and the second electron transport region ETR2 may include a metal halide such as LiF, NaCl, CsF, RbCl, RbI, CuI, and/or KI, a metal in lanthanoides such as Yb, and/or a co-depositing material of the metal halide and the metal in lanthanoides. For example, the first electron transport region ETR1 and the second electron transport region ETR2 may include KI:Yb, RbI:Yb, LiF:Yb, etc., as the co-depositing materials. The first electron transport region ETR1 and the second electron transport region ETR2 may use a metal oxide such as Li₂O and/or BaO, and/or 8-hydroxy-lithium quinolate (Liq). However, an embodiment of the present disclosure is not limited thereto. The first electron transport region ETR1 and the second electron transport region ETR2 may also be formed using a mixture material of an electron transport material and an insulating organo metal salt. The organo metal salt may be a material having an energy band gap of about 4 eV or more. In some embodiments, the organo metal salt may include, for example, metal acetates, metal benzoates, metal acetoacetates, metal acetylacetonates, and/or metal stearates.

Each of the first electron transport region ETR1 and the second electron transport region ETR2 may include at least one selected from 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the aforementioned materials. However, an embodiment of the present disclosure is not limited thereto.

Each of the first electron transport region ETR1 and the second electron transport region ETR2 may include the compounds of the above-described electron transport region in at least one selected from among an electron injection layer EIL1 and EIL2, an electron transport layer ETL1 and ETL2, and a hole blocking layer.

If each of the first electron transport region ETR1 and the second electron transport region ETR2 includes the electron transport layer ETL1 and ETL2, the thickness of the electron transport layer ETL1 and ETL2 may be from about 100 Å to about 1,000 Å, for example, from about 150 Å to about 500 Å. If the thickness of the electron transport layer ETL1 and ETL2 satisfies the above-described range, suitable or satisfactory electron transport properties may be obtained without substantial increase of a driving voltage. If each of the first electron transport region ETR1 and the second electron transport region ETR2 includes the electron injection layer EIL1 and EIL2, the thickness of the electron injection layer EIL1 and EIL2 may be from about 1 Å to about 100 Å, and from about 3 Å to about 90 Å. If the thickness of the electron injection layer EIL1 and EIL2 satisfies the above described range, suitable or satisfactory electron injection properties may be obtained without inducing substantial increase of a driving voltage.

If a voltage is applied, a charge generation layer CGL-1 may form a complex through oxidation-reduction reaction and may produce charges (electrons and holes). Also, the charge generation layer CGL-1 may provide each of adjacent light emitting units OL1 and OL2 with the charges produced. The charge generation layer CGL-1 may improve the efficiency of current produced in each of adjacent light emitting units OL1 and OL2 and may play the role of controlling charge balance between adjacent light emitting units OL1 and OL2.

The charge generation layer CGL-1 may include a p-type charge generation layer CGLp−1 and/or an n-type charge generation layer CGLn−1. The charge generation layer CGL-1 may have a stacked structure in which an n-type charge generation layer CGLn−1 and a p-type charge generation layer CGLp−1 are joined together.

The n-type charge generation layer CGLn−1 may be a charge generation layer providing adjacent light emitting units OL1 and OL2 with electrons. The n-type charge generation layer CGLn−1 may include an n-dopant. The n-type charge generation layer CGLn−1 may be a layer of a base material doped with an n-dopant. The p-type charge generation layer CGLp−1 may be a charge generation layer providing adjacent light emitting units OL1 and OL2 with holes. The p-type charge generation layer CGLp−1 may include a p-dopant. The p-type charge generation layer CGLp−1 may be a layer of a base material doped with a p-dopant. In some embodiments, a buffer layer may be further between the n-type charge generation layer CGLn−1 and the p-type charge generation layer CGLp−1.

Each charge generation layer CGL-1 may include an n-type aryl amine-based material or a p-type metal oxide. For example, each charge generation layer CGL-1 may include a charge generating compound including or consisting of an aryl amine-based organic compound, a carbazole-based compound, a metal, a metal oxide, a carbide, a fluoride, or mixtures thereof.

For example, the aryl amine-based organic compound may be N,N′-di(naphthalene-I-yl)-N,N′-diphenyl-benzidine (α-NPD), 4,4′,4″-tris[N(2-naphthyl)-N-phenylamino]-triphenylamine (2-TNATA), 4,4′4″-tris(N,N-diphenylamino)triphenylamine (TDATA), 4,4′,4″-[tris(3-methylphenyl)phenylamino] triphenylamine (m-TDATA), spiro-TAD, and/or spiro-NPB, and the carbazole-based compound may be 4,4′-bis(carbazol-9-yl)biphenyl (CBP). For example, the metal may be cesium (Cs), molybdenum (Mo), vanadium (V), titanium (Ti), tungsten (W), barium (Ba), or lithium (Li). Also, the metal oxide, the carbide and the fluoride may be Re₂O₇, MoO₃, V₂O₅, WO₃, TiO₂, Cs₂CO₃, BaF, LiF, and/or CsF.

The second electrode EL2 is provided on the second light emitting unit OL2. The second electrode EL2 may be provided on the electron transport region ETR2. The second electrode EL2 may be a common electrode. The second electrode EL2 may be a cathode or an anode, but an embodiment of the present disclosure is not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, indium tin oxide (ITO), indium zinc oxide (IZO), zinc oxide (ZnO), indium tin zinc oxide (ITZO), etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, and/or MgYb). Otherwise, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In some embodiments, the second electrode EL2 may be connected with an auxiliary electrode. If the second electrode EL2 is connected with the auxiliary electrode, the resistance of the second electrode EL2 may be reduced.

On the second electrode EL2 in the light emitting device ED of an embodiment, a capping layer may be further provided. The capping layer may include a multilayer or a single layer.

In an embodiment, the capping layer may be an organic layer and/or an inorganic layer. For example, if the capping layer includes an inorganic material, the inorganic material may include an alkali metal compound such as LiF, an alkaline earth metal compound such as MgF₂, SiON, SiNₓ, SiO_{y}, etc.

For example, if the capping layer includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or includes an epoxy resin, and/or acrylate such as methacrylate. The capping layer may include at least one selected from among Compounds P1 to P5 below, but an embodiment of the present disclosure is not limited thereto.

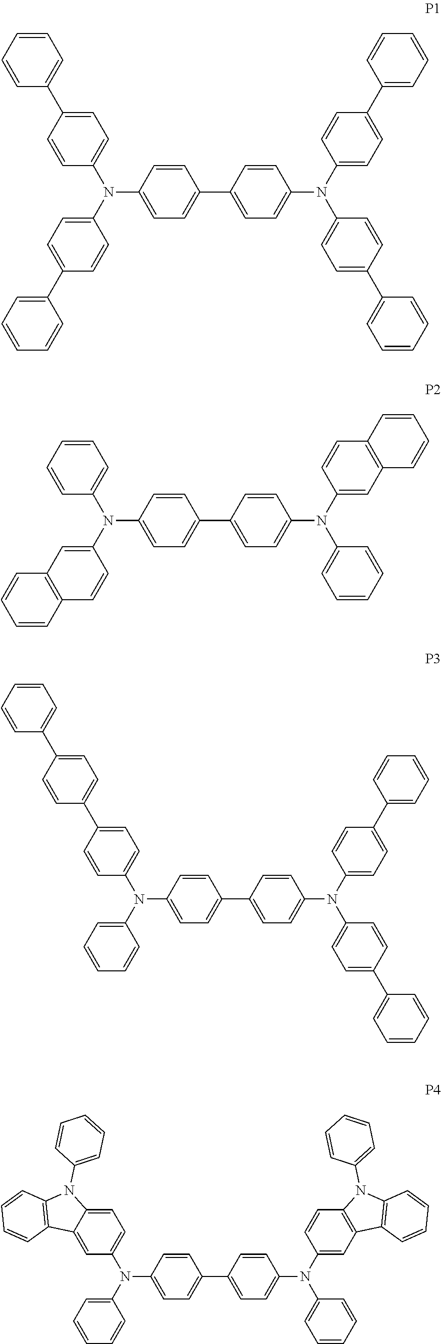 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

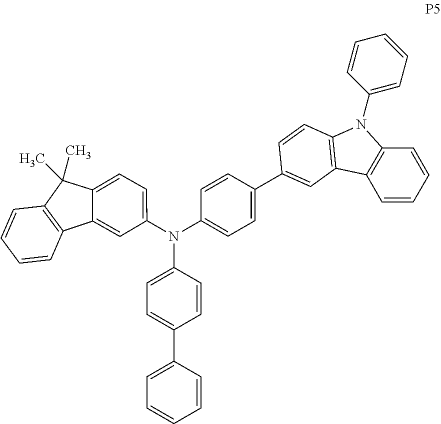 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer may be about 1.6 or more. In some embodiments, the refractive index of the capping layer with respect to light in a wavelength range of about 550 nm to about 660 nm may be about 1.6 or more. The light emitting device of an embodiment includes a first light emitting unit that emits hyper fluorescence, and a second light emitting unit that emits fluorescence. A first emission layer included in the first light emitting unit includes a first host, a phosphorescence sensitizer, and a first fluorescence dopant, and a second emission layer included in the second light emitting unit includes a second host, and a second fluorescence dopant. The first emission layer emits fluorescence by the energy transfer in the order of the first host, the phosphorescence sensitizer, and the first fluorescence dopant and through the first fluorescence dopant, and the second emission layer emits fluorescence by the direct transfer of energy from the second host to the second fluorescence dopant and through the second fluorescence dopant.

The light emitting device of an embodiment and the display device including the same include a first light emitting unit including a first emission layer emitting hyper fluorescence, and a second light emitting unit including a second emission layer emitting fluorescence, and may show a low driving voltage, large emission efficiency, and long-life characteristics.

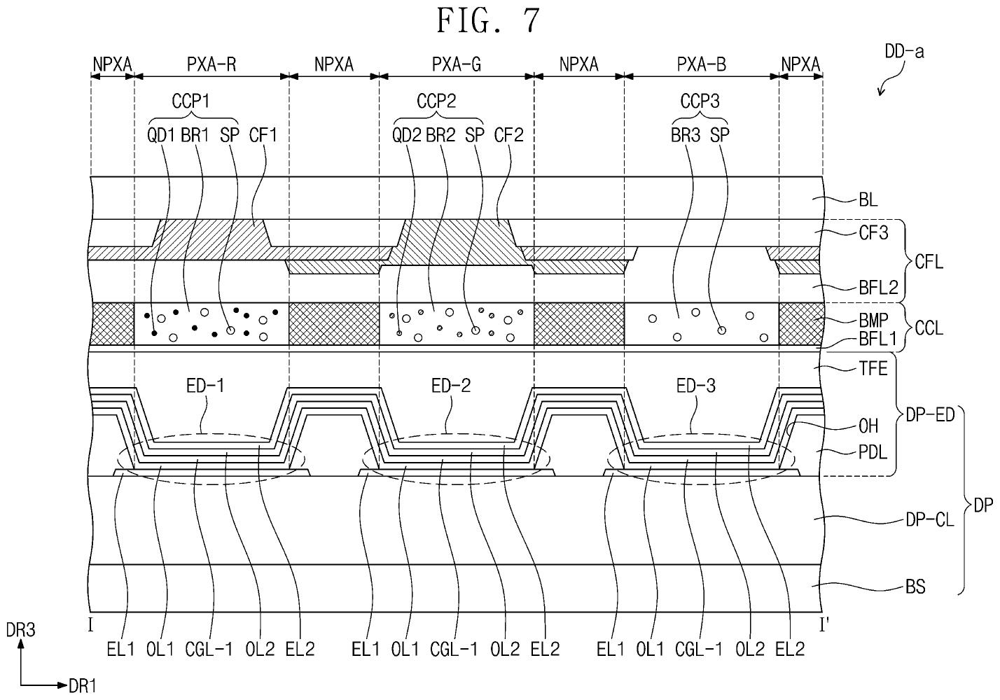

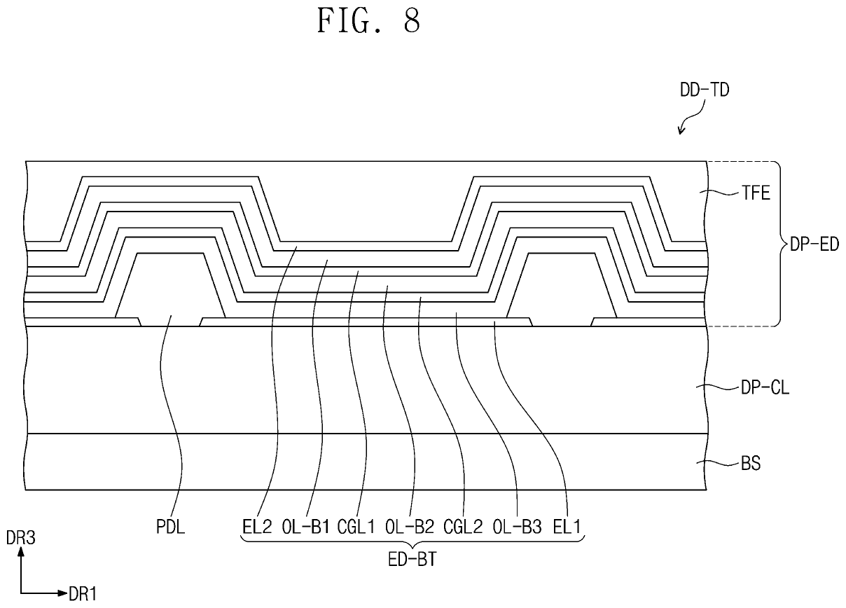

FIG. 7 and FIG. 8 are cross-sectional views of display devices according to embodiments. Hereinafter, in the explanation of the display devices of embodiments, referring to FIG. 7 and FIG. 8, the overlapping parts with the explanation of FIG. 1 to FIG. 6 will not be repeated here, and the different features will be explained chiefly.

Referring to FIG. 7, a display device DD-a according to an embodiment may include a display panel DP including a display device layer DP-ED, a light controlling layer CCL on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The same structures as the light emitting devices of FIG. 3 to FIG. 6 may be applied to the structure of the light emitting device ED shown in FIG. 7.

Referring to FIG. 7, the emission layer EML may be in an opening part OH defined in a pixel definition layer PDL. For example, the emission layer EML divided by the pixel definition layer PDL and correspondingly provided to each of luminous areas PXA-R, PXA-G and PXA-B may emit light in the same wavelength region. In the display device DD-a of an embodiment, the emission layer EML may emit blue light. Different from the drawings, in an embodiment, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot and/or a phosphor. The light converter may transform the wavelength of light provided and then emit. In some embodiments, the light controlling layer CCL may be a layer including a quantum dot and/or a layer including a phosphor.

The light controlling layer CCL may include a plurality of light controlling parts CCP1, CCP2 and CCP3. The light controlling parts CCP1, CCP2 and CCP3 may be separated (e.g., spaced apart) from one another.

Referring to FIG. 7, a partition pattern BMP may be between the separated light controlling parts CCP1, CCP2 and CCP3, but an embodiment of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 that converts a first color light provided from the light emitting device ED into a second color light, a second light controlling part CCP2 including a second quantum dot QD2 that converts the first color light into a third color light, and a third light controlling part CCP3 that transmits the first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents as those described above may be applied.

In addition, the light controlling layer CCL may further include a scatterer SP (e.g., a light scatterer SP). The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 that disperse the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of various suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, may be referred to as “humidity/oxygen”). The barrier layer BFL1 may be on the light controlling parts CCP1, CCP2 and CCP3 and may block or reduce the exposure of the light controlling parts CCP1, CCP2 and CCP3 to humidity/oxygen. The barrier layer BFL1 may cover the light controlling parts CCP1, CCP2 and CCP3. In addition, the barrier layer BFL2 may be provided between the light controlling parts CCP1, CCP2 and CCP3 and a color filter layer CFL.

The barrier layers BFL1 and BFL2 may include at least one inorganic layer. In some embodiments, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a metal thin film that secures or provides light transmittance. The barrier layers BFL1 and BFL2 may further include an organic layer. The barrier layers BFL1 and BFL2 may be composed of a single layer of a plurality of layers.

In the display device DD-a of an embodiment, the color filter layer CFL may be on the light controlling layer CCL. For example, the color filter layer CFL may be directly on the light controlling layer CCL. In this case, the barrier layer BFL2 may be omitted.

The color filter layer CFL may include filters CF1, CF2 and CF3. The color filter layer CFL may include a first filter CF1 that transmits a second color light, a second filter CF2 that transmits a third color light, and a third filter CF3 that transmits a first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. An embodiment of the present disclosure is not limited thereto, but the third filter CF3 may not include the pigment and/or dye. The third filter CF3 may include a polymer photosensitive resin and not include a pigment and/or dye. The third filter CF3 may be transparent. The third filter CF3 may be formed using a transparent photosensitive resin.

In addition, in an embodiment, the first filter CF1 and the second filter CF2 may be yellow filters. The first filter CF1 and the second filter CF2 may be provided in one body without distinction (e.g., may be provided as a monolith or single or sole body).

The color filter layer CFL may include may further include a light blocking part. The light blocking part may be a black matrix. The light blocking part may be formed by including an organic light blocking material and/or an inorganic light blocking material, including a black pigment and/or black dye. The light blocking part may prevent or reduce light leakage and may divide the boundaries among adjacent filters CF1, CF2 and CF3. In addition, in an embodiment, the light blocking part may be formed as a blue filter.

The first to third filters CF1, CF2 and CF3 may be provided correspondingly to the red luminous area PXA-R, green luminous area PXA-G and blue luminous area PXA-B, respectively.

On the color filter layer CFL, a base substrate BL may be provided. The base substrate BL may be a member that provides a base surface on which the color filter layer CFL, the light controlling layer CCL, etc. are provided. The base substrate BL may be a glass substrate, a metal substrate, a plastic substrate, etc. However, an embodiment of the present disclosure is not limited thereto, and the base substrate BL may be an inorganic layer, an organic layer or a composite material layer. In addition, different from the drawing, the base substrate BL may be omitted in an embodiment.

FIG. 8 is a cross-sectional view showing a part of the display device according to an embodiment. In a display device DD-TD of an embodiment, the light emitting device ED-BT may include a plurality of light emitting units OL-B1, OL-B2 and OL-B3. The light emitting device ED-BT may include oppositely provided first electrode EL1 and second electrode EL2, and the plurality of light emitting units OL-B1, OL-B2 and OL-B3 stacked in order in a thickness direction and provided between the first electrode EL1 and the second electrode EL2. Each of the light emitting units OL-B1, OL-B2 and OL-B3 may include an emission layer EML (FIG. 7) a hole transport region HTR and an electron transport region ETR having the emission layer EML (FIG. 7) therebetween.

In some embodiments, the light emitting device ED-BT included in the display device DD-TD of an embodiment may be a light emitting device of a tandem structure including a plurality of emission layers.

In an embodiment shown in FIG. 8, light emitted from the light emitting units OL-B1, OL-B2 and OL-B3 may be all blue light. However, an embodiment of the present disclosure is not limited thereto, and the wavelength regions of light emitted from the light emitting units OL-B1, OL-B2 and OL-B3 may be different from each other. For example, the light emitting device ED-BT including the plurality of light emitting units OL-B1, OL-B2 and OL-B3 emitting light in different wavelength regions may emit white light.

Between neighboring light emitting structures OL-B1, OL-B2 and OL-B3, charge generation layers CGL1 and CGL2 may be provided. The charge generation layers CGL1 and CGL2 may include a p-type charge generation layer and/or an n-type charge generation layer.

At least one selected from among the light emitting units OL-B1, OL-B2 and OL-B3 included in the display device DD-TD of an embodiment may include a first host, a first fluorescence dopant, and a phosphorescence dopant, and another at least one may include a second host, and a second fluorescence dopant. For example, at least one selected from among the first light emitting unit OL-B1 and the second light emitting unit OL-B2 may include a first host, a first fluorescence dopant, and a phosphorescence dopant, and the remaining one may include a second host, and a second fluorescence dopant.

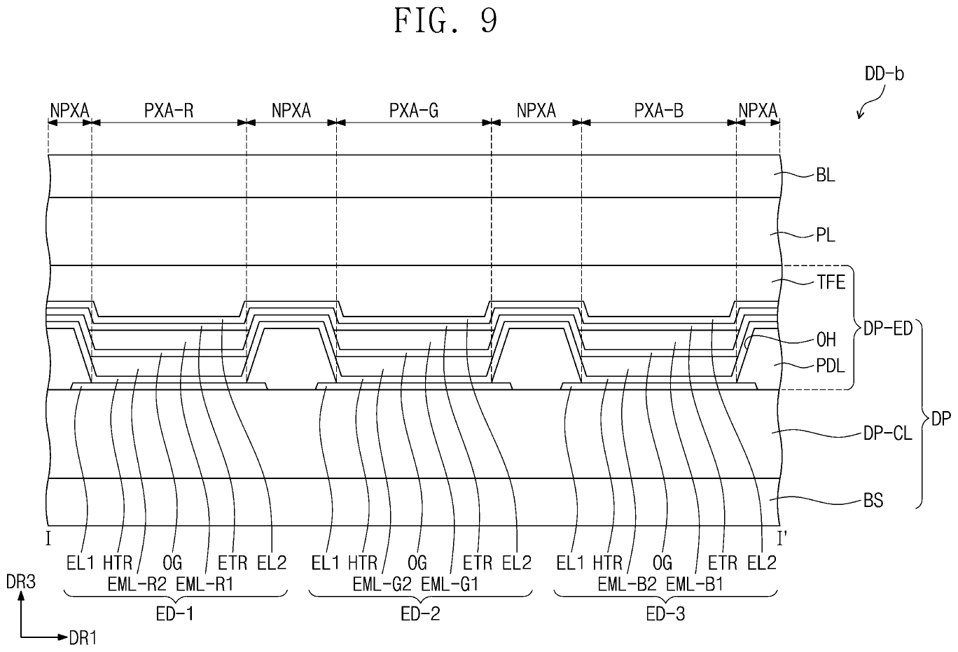

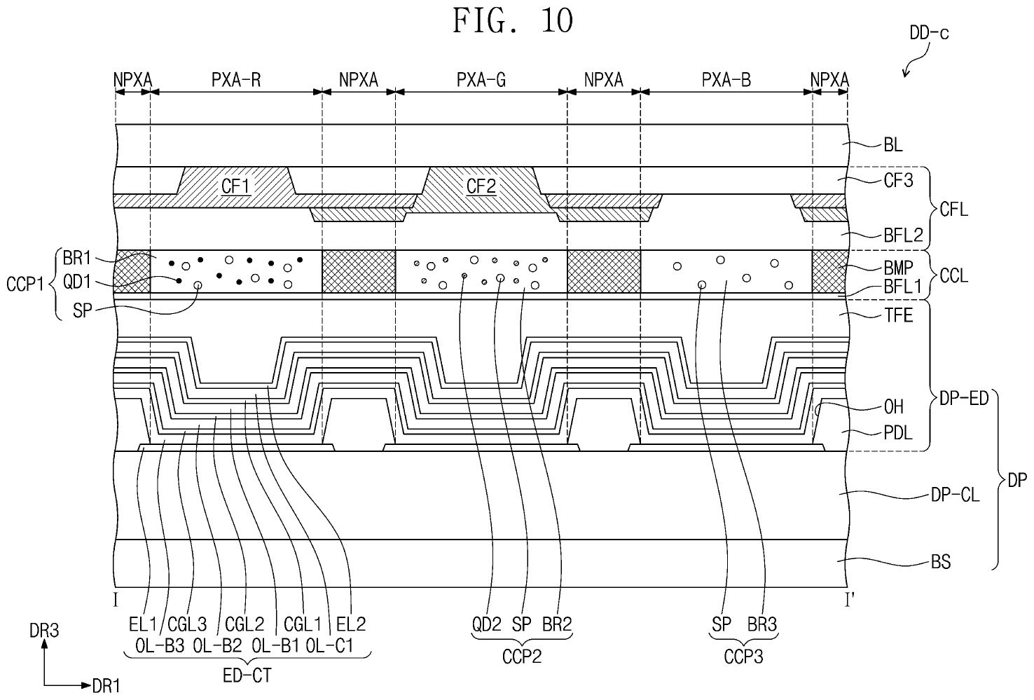

FIG. 9 is a cross-sectional view showing a display device according to an embodiment of the present disclosure. FIG. 10 is a cross-sectional view showing a display device according to an embodiment of the present disclosure.

Referring to FIG. 9, a display device DD-b according to an embodiment may include light emitting devices ED-1, ED-2 and ED-3, formed by stacking two emission layers. Compared to the display device DD of an embodiment, shown in FIG. 2, an embodiment shown in FIG. 9 is different in that first to third light emitting devices ED-1, ED-2 and ED-3 include two emission layers stacked in a thickness direction, each. In the first to third light emitting devices ED-1, ED-2 and ED-3, two emission layers may emit light in the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be provided.

The emission auxiliary part OG may include a single layer or a multilayer. The emission auxiliary part OG may include a charge generation layer. In some embodiments, the emission auxiliary part OG may include an electron transport region, a charge generation layer, and a hole transport region stacked in order. The emission auxiliary part OG may be provided as a common layer in all of the first to third light emitting devices ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be between the electron transport region ETR and the emission auxiliary part OG. The second red emission layer EML-R2, the second green emission layer EML-G2 and the second blue emission layer EML-B2 may be between the emission auxiliary part OG and the hole transport region HTR.

In some embodiments, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2, stacked in order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2, stacked in order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2, stacked in order.

An optical auxiliary layer PL (e.g., an optical layer PL) may be on a display device layer DP-ED. The optical auxiliary layer PL may include a polarization layer. The optical auxiliary layer PL may be on a display panel DP and may control reflected light at the display panel DP by external light. Different from the drawings, the optical auxiliary layer PL may be omitted from the display device according to an embodiment.

At least one selected from among the first light emitting device to the third light emitting device ED-1, ED-2 and ED-3, included in the display device DD-b of an embodiment, shown in FIG. 9, may have the same structure as the light emitting device ED, ED-a, and ED-b explained in FIG. 3 to FIG. 6. For example, in the third light emitting device ED-3, at least one selected from among a first blue emission layer EML-B1 and a second blue emission layer EML-B2 may include a first host, a first fluorescence dopant, and a phosphorescence sensitizer, and the remaining one may include a second host, and a second fluorescence dopant.

Different from FIG. 8 and FIG. 9, a display device DD-c in FIG. 10 is shown to include four light emitting units OL-B1, OL-B2, OL-B3 and OL-C1. A light emitting device ED-CT may include oppositely provided first electrode EL1 and second electrode EL2, and first to fourth light emitting units OL-B1, OL-B2, OL-B3 and OL-C1 stacked in order in a thickness direction between the first electrode EL1 and the second electrode EL2. Light emitting structures OL-C1, OL-B1, OL-B2, and OL-B3 are stacked successively, and the charge generation layer CGL1 is disposed between light emitting structures OL-B1 and OL-C1, the charge generation layer CGL2 is disposed between light emitting structures OL-B1 and OL-B2, and the charge generation layer CGL3 is disposed between light emitting structures OL-B2 and OL-B3. Among the four light emitting structures, the first to third light emitting units OL-B1, OL-B2 and OL-B3 may emit blue light, and the fourth light emitting unit OL-C1 may emit green light. However, an embodiment of the present disclosure is not limited thereto, and the first to fourth light emitting units OL-B1, OL-B2, OL-B3 and OL-C1 may emit different wavelengths of light.

The charge generation layers CGL1, CGL2 and CGL3 between neighboring light emitting units OL-B1, OL-B2, OL-B3, OL-C1 may include a p-type charge generation layer and/or an n-type charge generation layer.

At least one selected from among the light emitting units OL-B1, OL-B2, OL-B3 and OL-C1, included in the display device DD-c of an embodiment may include a first host, a first fluorescence dopant, and a phosphorescence sensitizer, and the remaining at least one may include a second host, and a second fluorescence dopant. For example, at least one selected from among the first light emitting unit OL-B1 and the fourth light emitting unit OL-C1 may include a first host, a first fluorescence dopant, and a phosphorescence sensitizer, and the remainder may include a second host, and a second fluorescence dopant.

In an embodiment, an electronic device may include a display device including a plurality of light emitting devices, and a controller controlling the display device. The electronic device of an embodiment may be a device activated according to electrical signals. The electronic device may include various suitable embodiments of display devices. For example, the electronic device may include small- and medium-sized display devices such as personal computers, laptop computers, personal digital terminals, display devices for automobiles, game consoles, and portable electronic devices, as well as large-sized display devices such as televisions, monitors, and external billboards.

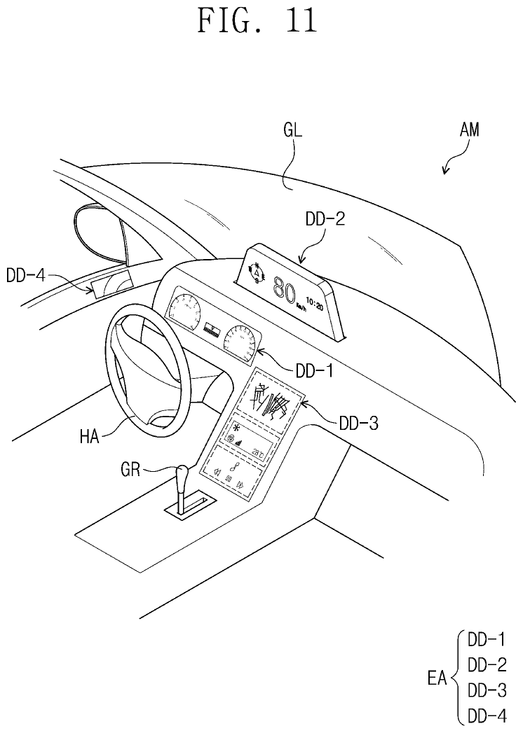

FIG. 11 is a perspective view schematically showing an electronic device including the display device according to an embodiment. In FIG. 11, an electronic device including a display device for an automobile is shown as an embodiment.

Referring to FIG. 11, an electronic device EA of an embodiment may include display devices DD-1, DD-2, DD-3 and DD-4 for an automobile AM. In FIG. 11, first to fourth display devices DD-1, DD-2, DD-3 and DD-4 are shown, as the display devices of an automobile, provided in the automobile AM. In FIG. 11, an automobile is shown, but this is an illustration, and the first to fourth display devices DD-1, DD-2, DD-3 and DD-4 may be on other transport means such as bicycles, motorcycles, trains, ships and airplanes. At least one selected from among the first to fourth display devices DD-1, DD-2, DD-3 and DD-4 may include the same configurations as those of the display devices DD, DD-a, DD-b and DD-c, explained referring to FIG. 1, FIG. 2, and FIG. 7 to FIG. 10.

In an embodiment, at least one selected from among the first to fourth display devices DD-1, DD-2, DD-3 and DD-4 may include the light emitting devices ED, ED-a and ED-b of embodiments, explained referring to FIG. 3 to FIG. 6. The first to fourth display devices DD-1, DD-2, DD-3 and DD-4 may each independently include a plurality of light emitting devices ED, ED-a and ED-b. Each of the light emitting devices ED, ED-a and ED-b may include a first electrode EL1, a first light emitting unit OL1 on the first electrode EL1, a charge generation layer CGL-1 on the first light emitting unit OL1, a second light emitting unit OL2 on the charge generation layer CGL-1, and a second electrode EL2 on the second light emitting unit OL2. Accordingly, the electronic device EA of an embodiment may show improved image quality.

Referring to FIG. 11, an automobile AM may include a steering wheel HA and a gear GR for the operation of the automobile AM, and a front window GL may face a driver.

A first display device DD-1 may be in a first region overlapping with the steering wheel HA. For example, the first display device DD-1 may be a digital cluster displaying the first information of the automobile AM. The first information may include a graduation (e.g., a speedometer) showing the running speed of the automobile AM, a graduation (e.g., a tachometer) showing the number of revolution of an engine (e.g., revolutions per minute (RPM)), and images showing a fuel state. A graduation may be represented by digital images.

A second display device DD-2 may be in a second region facing a driver's seat and overlapping with the front window GL. The driver's seat may be a seat where the steering wheel HA is provided. For example, the second display device DD-2 may be a head up display (HUD) showing the second information of the automobile AM. The second display device DD-2 may be optically clear. The second information may include digital numbers DN showing the running speed of the automobile AM and may further include information including the current time.

A third display device DD-3 may be in a third region adjacent to the gear GR. For example, the third display device DD-3 may be a center information display (CID) for an automobile, between a driver's seat and a passenger seat and showing third information. The passenger seat may be a seat separated (e.g., spaced apart) from the driver's seat with the gear GR therebetween. The third information may include information on road conditions (for example, navigation information), on playing music or radio, on playing a dynamic image, on the temperature in the automobile AM, and/or the like.

A fourth display device DD-4 may be in a fourth region separated from the steering wheel HA and the gear GR and adjacent to the side of the automobile AM. For example, the fourth display device DD-4 may be a digital wing mirror displaying fourth information. The fourth display device DD-4 may display the external image of the automobile AM, taken by a camera module CM at the outside of the automobile AM. The fourth information may include the external image of the automobile AM. The above-described first to fourth information is for illustration, and the first to fourth display devices DD-1, DD-2, DD-3 and DD-4 may further display information on the inside and outside of the automobile. The first to fourth information may include different information from each other. However, an embodiment of the present disclosure is not limited thereto, and a portion of the first to fourth information may include the same information.

Hereinafter, the light emitting device of an embodiment will be further explained referring to example and comparative embodiments. In addition, the embodiments below are only illustrations to assist the understanding of the present disclosure, and the scope of the present disclosure is not limited thereto.

### 1. Method of Manufacturing Light Emitting Device

### (1) Method of Manufacturing Light Emitting Device 1 (EML1: First Resonance Structure, EML2: Second Resonance Structure)

### 1) Method of Manufacturing Light Emitting Device of Example 1

A first electrode having a stacked structure of ITO/Ag/ITO on a glass substrate was formed. On the first electrode, first and second light emitting units were formed in order.

On the first electrode, an organic material including Compound H-1-1 and NDP9 was co-deposited to a thickness of about 100 Å to form a first hole injection layer.

On the first hole injection layer, H-1-11 was deposited to form a first hole transport layer having a thickness of about 110 Å.

On the first hole transport layer, H-1-7 was deposited to a thickness of about 50 Å to form a first electron blocking layer.

On the first electron blocking layer, an organic material of a combination of the compounds described in Table 2 was deposited to a thickness of about 350 Å to form a first emission layer.

On the first emission layer, ET29 was deposited to about 50 Å to form a first hole blocking layer. On the first hole blocking layer, ET29 and Liq were deposited in a weight ratio of about 5:5 to a thickness of about 150 Å to form a first electron transport layer, thereby providing a first light emitting unit.

On the first electron transport layer, ET36 was deposited to a thickness of about 75 Å to form an n-type charge generation layer. On the n-type charge generation layer, an organic material including H-1-1 and NDP9 was deposited to a thickness of about 100 Å to form a p-type charge generation layer.

On the p-type charge generation layer, H-1-11 was deposited to a thickness of about 260 Å to form a second hole transport layer.

On the second hole transport layer, H-1-7 was deposited to a thickness of about 50 Å to form a second electron blocking layer.

On the second electron blocking layer, an organic material of a combination of the compounds described in Table 2 was deposited to a thickness of about 200 Å to form a second emission layer.

On the second emission layer, ET29 was deposited to about 50 Å to form a second hole blocking layer. On the second hole blocking layer, ET29 and Liq were deposited in a weight ratio of about 5:5 to a thickness of about 310 Å, and Yb was deposited to about 13 Å to form a second electron transport layer, thereby providing a second light emitting unit.

On the second light emitting unit, AgMg was provided to a thickness of about 120 Å to form a second electrode. On the second electrode, a capping layer including Compound P4 below was formed to a thickness of about 640 Å.

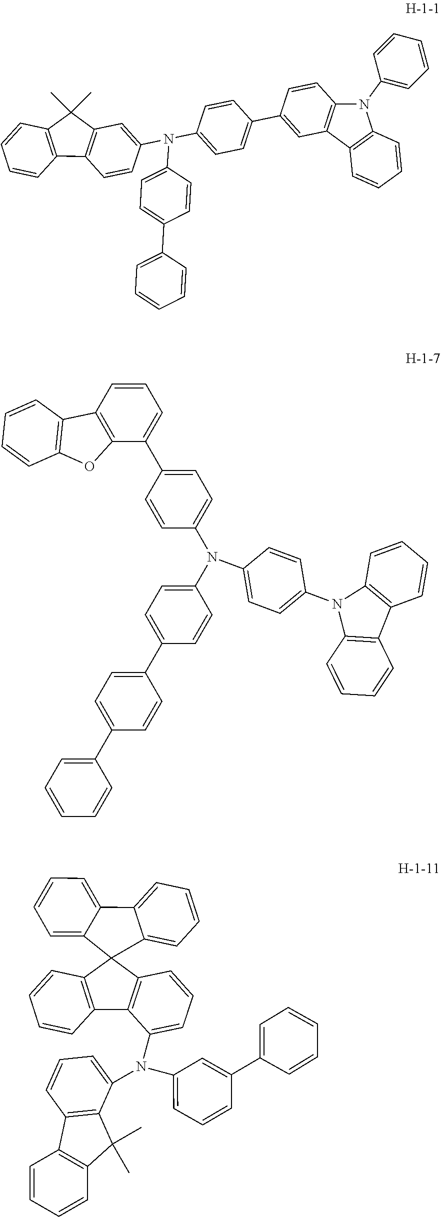 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; CC1(C)c2ccccc2-c2cccc(N(c3cccc(-c4ccccc4)c3)c3cccc4c3-c3ccccc3C43c4ccccc4-c4ccccc43)c21]

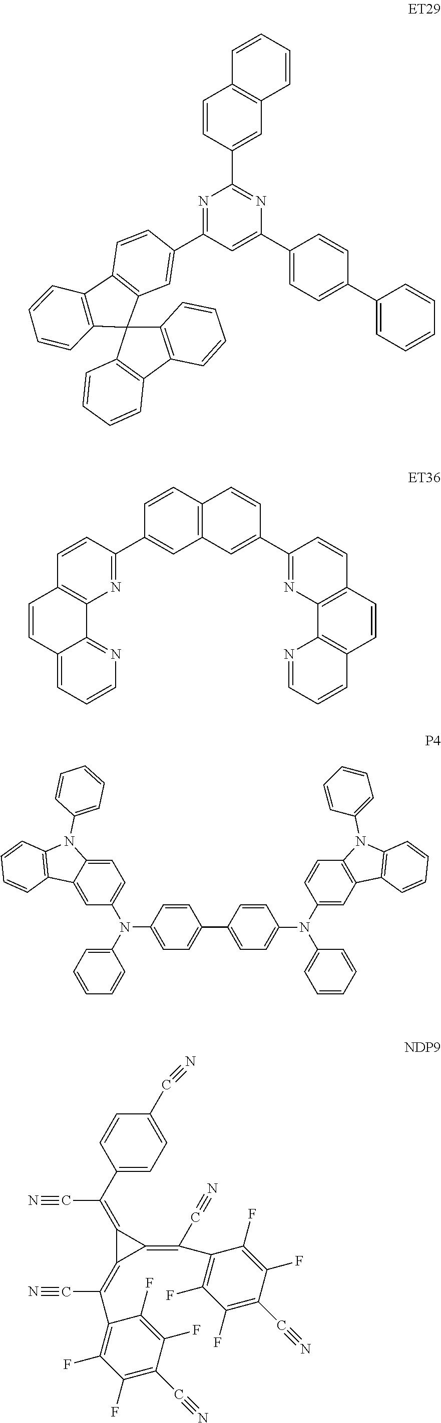 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1cnc2c(c1)ccc1ccc(-c3ccc4ccc(-c5ccc6ccc7cccnc7c6n5)cc4c3)nc12 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; N#CC(=C1C(=C(\C#N)c2c(F)c(F)c(C#N)c(F)c2F)/C1=C(/C#N)c1c(F)c(F)c(C#N)c(F)c1F)c1ccc(C#N)cc1]

### 2) Method of Manufacturing Light Emitting Device of Example 2

A light emitting device was manufactured by substantially the same method as the light emitting device of Example 1 except for forming a first emission layer to a thickness of about 200 Å, and a second emission layer to a thickness of about 350 Å.

### 3) Method of Manufacturing Light Emitting Device of Comparative Example 1

A light emitting device was manufactured by substantially the same method as the light emitting device of Example 1 except for forming a second emission layer to a thickness of about 350 Å.

### 4) Method of Manufacturing Light Emitting Device of Comparative Example 2

A light emitting device was manufactured by substantially the same method as the light emitting device of Example 1 except for forming a first emission layer to a thickness of about 200 Å.

### (2) Method of Manufacturing Light Emitting Device 2 (EML1: Second Resonance Structure, EML2: Third Resonance Structure)

### 1) Method of Manufacturing Light Emitting Device of Example 3

A light emitting device was manufactured by substantially the same method as the light emitting device of Example 1 except for forming a hole transport layer to a thickness of about 1,100 Å.

### 2) Method of Manufacturing Light Emitting Device of Example 4

A light emitting device was manufactured by substantially the same method as the light emitting device of Example 2 except for forming a hole transport layer to a thickness of about 1,100 Å.

### 3) Method of Manufacturing Light Emitting Device of Comparative Example 3

A light emitting device was manufactured by substantially the same method as the light emitting device of Comparative Example 1 except for forming a hole transport layer to a thickness of about 1,100 Å.

### 4) Method of Manufacturing Light Emitting Device of Comparative Example 4

A light emitting device was manufactured by substantially the same method as the light emitting device of Comparative Example 2 except for forming a hole transport layer to a thickness of about 1,100 Å.

### (3) Materials Used for the Manufacture of Light Emitting Devices

The properties of the compounds used for the manufacture of the light emitting devices were evaluated and shown in Table 1 below. In M*cm⁻¹, “*” means the multiplication relation between units.

TABLE 1

| | | Molar extinction | |
|---|---|---|---|
| | HOMO | coefficient | T1 |
| | (eV) | (M*cm⁻¹) | (eV) |
| First host | −5.5 | — | 3.0 |
| Second host | −5.6 | — | 1.6 |
| First fluorescence dopant | −5.3 | 4.4 × 10⁴ | 2.5 |
| Second fluorescence dopant | −5.1 | 1 × 10⁴ | 1.8 |
| Phosphorescence sensitizer | −5.2 | — | 2.6 |

The first host is a mixture of HT6 and ETH95 in a weight ratio of about 7:3, the second host is Compound E1, the first fluorescence dopant is D-01, the second fluorescence dopant is D-13, and the phosphorescence sensitizer is AD-13.

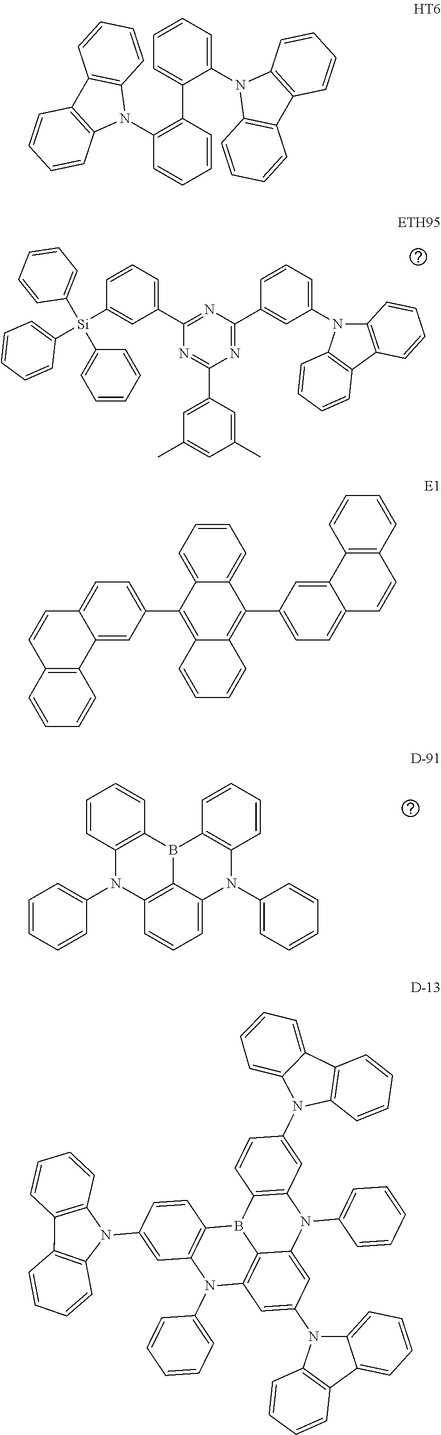

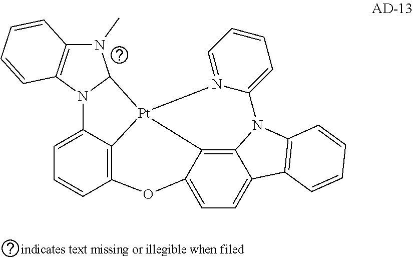

### 2. Evaluation of Light Emitting Devices

### (1) Light Emitting Devices 1

In Table 2, the evaluation results of the color coordinate, driving voltage, relative emission efficiency, and relative device lifetime of each of the light emitting devices 1 according to Examples 1 and 2 and Comparative Examples 1 and 2 are shown. In order to evaluate the properties of the light emitting devices manufactured in Examples 1 to 4 and Comparative Examples 1 to 4, a driving voltage (V) at a current density of about 1000 cd/m², and emission efficiency (cd/A) were measured utilizing Keithley SMU 236 and a luminance meter PR650, a relative emission efficiency was calculated based on the light emitting device of Comparative Example 1. The time consumed to reach about 95% luminance relative to an initial luminance was measured as the device lifetime (T95), a relative device lifetime (e.g., device lifetime ratio (T95)) was calculated based on the light emitting device of Comparative Example 1. The color coordinates were measured at a current of 1 mA. The evaluation results of the color coordinate, driving voltage, relative emission efficiency, and relative device lifetime are shown in Table 2 and 3.

TABLE 2

| | | | Color | Driving | Relative | Relative |
|---|---|---|---|---|---|---|
| | Emission | Emission | coordinate | voltage | emission | device |
| | layer 1 | layer 2 | (CIEy) | (V) | efficiency | lifetime |
| Example 1 | first host/ | second host/ | 0.052 | 7.1 | 150% | 80% |
| | phosphorescence | second | | | | |
| | sensitizer/first | fluorescence | | | | |
| | fluorescence | dopant | | | | |
| | dopant | | | | | |
| Example 2 | second host/ | first host/ | 0.050 | 7.0 | 160% | 75% |
| | second | phosphoresce | | | | |
| | fluorescence | nce sensitizer/ | | | | |
| | dopant | first | | | | |
| | | fluorescence | | | | |
| | | dopant | | | | |
| Comparative | first host/ | first host/ | 0.060 | 7.8 | 220% | 20% |
| Example 1 | phosphorescence | phosphoresce | | | | |
| | nce sensitizer/ | sensitizer/ | | | | |
| | first | first | | | | |
| | fluorescence | fluorescence | | | | |
| | dopant | dopant | | | | |
| Comparative | second host/ | second host/ | 0.040 | 6.2 | 100% | 100% |
| Example 2 | second | second | | | | |
| | fluorescence dopant | fluorescence dopant | | | | |

Referring to Table 2, it can be seen that Example 1 and Example 2 showed low driving voltages, excellent emission efficiency, and long lifetime simultaneously, when compared to Comparative Example 1 and Comparative Example 2. In addition, it could be confirmed that the light emitting devices of Example 1 and Example 2 emitted blue light in the color coordinate of about 0.5. Particularly, as in Comparative Example 1, in a case where both emission layer 1 and emission layer 2 emit hyper fluorescence, relatively high emission efficiency was shown, but device lifetime was short, and a driving voltage was large. As in Comparative Example 2, in a case where both emission layer 1 and emission layer 2 emit fluorescence, a relatively low driving voltage and relatively long device lifetime were achieved, but relatively low emission efficiency was shown.

### (2) Light Emitting Devices 2

In Table 3, the evaluation results of the color coordinate, driving voltage, relative emission efficiency, and relative device lifetime of each of the light emitting devices 2 according to Examples 3 and 4 and Comparative Examples 3 and 4 are shown.

TABLE 3

| | | | | Driving | Relative | Relative |
|---|---|---|---|---|---|---|
| | Emission | Emission | Color | voltage | emission | device |
| | layer 1 | layer 2 | coordinate | (V) | efficiency | lifetime |
| Example 3 | first host | second host | 0.052 | 7.3 | 178% | 100% |
| | phosphorescence | second | | | | |
| | sensitizer | fluorescence | | | | |
| | First | dopant | | | | |
| | fluorescence | | | | | |
| | dopant | | | | | |
| Example 4 | second host | first host | 0.050 | 7.2 | 193% | 95% |
| | second | phosphorescence | | | | |
| | fluorescence | sensitizer | | | | |
| | dopant | First | | | | |
| | | fluorescence | | | | |
| | | dopant | | | | |
| Comparative | first host phosphorescence | first host | 0.060 | 8.0 | 257% | 25% |
| Example 3 | sensitizer | phosphorescence | | | | |
| | first fluorescence | sensitizer | | | | |
| | dopant | first | | | | |
| | | fluorescence | | | | |
| | | dopant | | | | |
| Comparative | second host | second host | 0.040 | 6.3 | 127% | 130% |
| Example 4 | second | second | | | | |
| | fluorescence | fluorescence | | | | |
| | dopant | dopant | | | | |

Referring to Table 3, it can be seen that Example 3 and Example 4 showed low driving voltages, excellent emission efficiency, and long lifetime simultaneously, when compared to Comparative Example 3 and Comparative Example 4. In addition, it can be seen that the light emitting devices of Example 3 and Example 4 emitted blue light in the color coordinate of about 0.5. Particularly, as in Comparative Example 3, in a case where both emission layer 1 and emission layer 2 emit hyper fluorescence, relatively high emission efficiency was shown, but device lifetime was short, and a driving voltage was large. As in Comparative Example 4, in a case where both emission layer 1 and emission layer 2 emit fluorescence, a relatively low driving voltage and relatively long device lifetime were achieved, but relatively low emission efficiency was shown. Through the results, it could be found that a light emitting device including a first light emitting unit including an emission layer that emits hyper fluorescence and a second light emitting unit including an emission layer that emits fluorescence, showed a low driving voltage, excellent emission efficiency, and long device lifetime.

The light emitting device of an embodiment includes a first light emitting unit that emits hyper fluorescence, and a second light emitting unit that emits fluorescence. A first emission layer included in the first light emitting unit includes a first host, a phosphorescence sensitizer, and a first fluorescence dopant, and a second emission layer included in the second light emitting unit includes a second host and a second fluorescence dopant. In the first emission layer, energy may be transferred in the order of the first host, the phosphorescence sensitizer and the first fluorescence dopant, and fluorescence may be emitted through the first fluorescence dopant. In the second emission layer, energy may be directly transferred from the second host to the second fluorescence dopant, and fluorescence may be emitted through the second fluorescence dopant.

A light emitting device of an embodiment and a display device including the same include a first light emitting unit including a first emission layer that emits hyper fluorescence, and a second light emitting unit including a second emission layer that emits fluorescence, and may show a low driving voltage, excellent emission efficiency, and long-life characteristics.

The light emitting device of an embodiment and the display device including the same include a phosphorescence sensitizer and a fluorescence dopant, and include a first emission layer that emits fluorescence, and a second emission layer including the fluorescence dopant, thereby showing a low driving voltage and excellent emission efficiency.

Although embodiments of the present disclosure have been described, it is understood that the present disclosure should not be limited to these embodiments, but various changes and modifications can be made by one ordinary skilled in the art within the spirit and scope of the present disclosure as defined by the appended claims, and equivalents thereof.

What is claimed is:

1. A light emitting device comprising:
a first electrode;
a first light emitting unit on the first electrode;
a second light emitting unit on the first light emitting unit;
a second electrode on the second light emitting unit; and
a charge generation layer between the first light emitting unit and the second light emitting unit, wherein:
the first light emitting unit comprises:
a first hole transport region;
a first electron transport region on the first hole transport region; and
a first emission layer between the first hole transport region and the first electron transport region, and comprising a first host, a phosphorescence sensitizer, and a first fluorescence dopant,
the second light emitting unit comprises:
a second hole transport region;
a second electron transport region on the second hole transport region; and
a second emission layer between the second hole transport region and the second electron transport region, and comprising a second host which is different from the first host, and a second fluorescence dopant,
the first fluorescence dopant has a highest occupied molecular orbital (HOMO) energy level of about −5.2 eV or less, and
the second fluorescence dopant has a HOMO energy level of about −5.2 eV or more.

2. The light emitting device of claim 1, wherein:
the first host comprises a hole transport host and an electron transport host which is different from the hole transport host,
an energy level of a triplet state of the hole transport host is lower than an energy level of a triplet state of the first fluorescence dopant, and
an energy level of a singlet state of the electron transport host is lower than an energy level of a singlet state of the first fluorescence dopant.

3. The light emitting device of claim 2, wherein the hole transport host is represented by the following Formula HT-1: 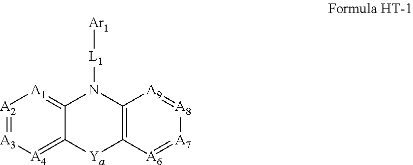
in Formula HT-1,
A₁ to A₄, and A₆ to A₉ are each independently N or CR₄₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₄₂R₄₃, or SiR₄₄R₄₅,
Ar₁ is a substituted or unsubstituted aryl group of 6 to 30 ring-forming carbon atoms, or a substituted or unsubstituted heteroaryl group of 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, R₄₁ to R₄₅ are each independently combined with an adjacent group to form a ring.

4. The light emitting device of claim 2, wherein the electron transport host is represented by the following Formula ET-1: 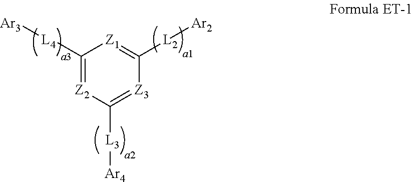
in Formula ET-1,
at least one selected from among Z₁ to Z₃ is N, and the remainder are CRₐ₃, where Rₐ₃ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
a₁ to a₃ are each independently an integer of 0 to 10,
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms, and
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

5. The light emitting device of claim 2, wherein the hole transport host and the electron transport host form an exciplex.

6. The light emitting device of claim 5, wherein an energy level of a triplet state of the exciplex is higher than an energy level of a triplet state of the phosphorescence sensitizer, and an energy level of a triplet state of the phosphorescence sensitizer is higher than an energy level of a triplet state of the first fluorescence dopant.

7. The light emitting device of claim 1, wherein the phosphorescence sensitizer is represented by the following Formula D-1: 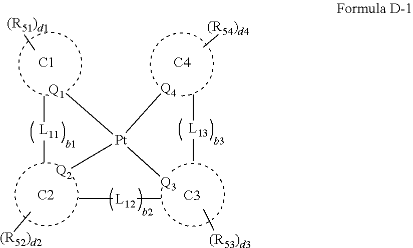
in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, 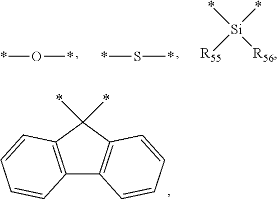
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
in L₁₁ to L₁₃, “—*” is a position connected with C1 to C4,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring, and
d1 to d4 are each independently an integer of 0 to 4.

8. The light emitting device of claim 1, wherein the first fluorescence dopant comprises boron.

9. The light emitting device of claim 1, wherein the second host is an anthracene-based compound.

10. The light emitting device of claim 1, wherein the first emission layer emits blue light, and the second emission layer emits blue light.

11. The light emitting device of claim 1, wherein the first fluorescence dopant has a molar extinction coefficient of about 2×10⁵ M*cm⁻¹ or more.

12. The light emitting device of claim 1, wherein an energy level (T1_{P}) of a triplet state of the phosphorescence sensitizer and an energy level (T1_{F1}) of a triplet state of the first fluorescence dopant satisfy the following Equation 1:
T1_{P}≥T1_{F1}−0.02 eV. [Equation 1]

13. A display device comprising a plurality of light emitting devices which emit light in different wavelength regions, wherein:
at least one selected from among the light emitting devices comprises:
a first electrode;
a first light emitting unit on the first electrode;
a second light emitting unit on the first light emitting unit;
a second electrode on the second light emitting unit; and
a charge generation layer between the first light emitting unit and the second light emitting unit,
the first light emitting unit comprises:
a first hole transport region;
a first electron transport region on the first hole transport region; and
a first emission layer between the first hole transport region and the first electron transport region, and comprising a first host, a phosphorescence sensitizer, and a first fluorescence dopant,
the second light emitting unit comprises:
a second hole transport region;
a second electron transport region on the second hole transport region; and
a second emission layer between the second hole transport region and the second electron transport region, and comprising a second host which is different from the first host, and a second fluorescence dopant,
the first fluorescence dopant has a highest occupied molecular orbital (HOMO) energy of about −5.2 eV or less, and
the second fluorescence dopant has a HOMO energy of about −5.2 eV or more.

14. The display device of claim 13, wherein the light emitting devices comprise:
a first light emitting device that emits red light;
a second light emitting device that emits green light; and
a third light emitting device that emits blue light.

15. The display device of claim 13, wherein the first emission layer and the second layer emit blue light, respectively.

16. The display device of claim 13, wherein:
the first host comprises a hole transport host and an electron transport host which is different from the hole transport host,
triplet energy of the hole transport host is lower than triplet energy of the first fluorescence dopant, and
singlet energy of the electron transport host is lower than singlet energy of the first fluorescence dopant.

17. The display device of claim 16, wherein the hole transport host is represented by the following Formula HT-1: 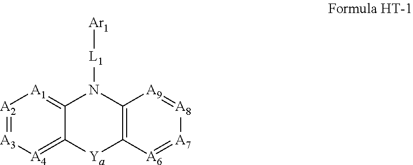
in Formula HT-1,
A₁ to A₄, and A₆ to A₉ are each independently N or CR₄₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₄₂R₄₃, or SiR₄₄R₄₅,
Ar₁ is a substituted or unsubstituted aryl group of 6 to 30 ring-forming carbon atoms, or a substituted or unsubstituted heteroaryl group of 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, R₄₁ to R₄₅ are each independently combined with an adjacent group to form a ring.

18. The display device of claim 16, wherein the electron transport host is represented by the following Formula ET-1: 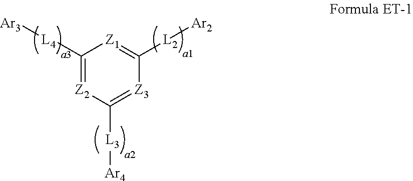
in Formula ET-1,
at least one selected from among Z₁ to Z₃ is N, and the remainder are CRₐ₃, where Rₐ₃ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
a₁ to a₃ are each independently an integer of 0 to 10,
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms, and
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

19. The display device of claim 16, wherein the hole transport host and the electron transport host form an exciplex.

20. The display device of claim 19, wherein an energy level of a triplet state of the exciplex is higher than an energy level of a triplet state of the phosphorescence sensitizer, and an energy level of a triplet state of the phosphorescence sensitizer is higher than an energy level of a triplet state of the first fluorescence dopant.

21. The display device of claim 13, wherein the phosphorescence sensitizer is represented by the following Formula D-1: 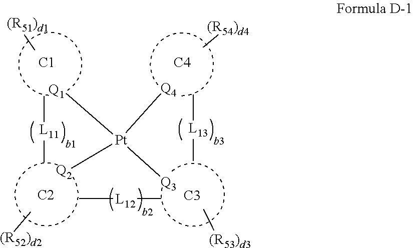
in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, 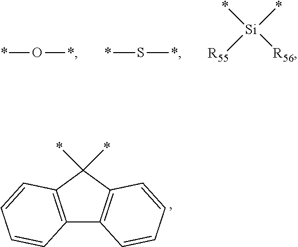
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
in L₁₁ to L₁₃, “—*” is a position connected with C1 to C4,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group from each other to form a ring, and
d1 to d4 are each independently an integer of 0 to 4.

22. The display device of claim 13, wherein the first fluorescence dopant comprises boron.

23. The display device of claim 13, wherein the second host is an anthracene-based compound.
